(19) United States
(12) Patent Application Publication
(10) Pub. No.: US 2021/0191265 A1
(43) Pub. Date: Jun. 24, 2021

(54) ACTINIC RAY-SENSITIVE OR RADIATION-SENSITIVE RESIN COMPOSITION, RESIST FILM, PATTERN FORMING METHOD, AND METHOD FOR MANUFACTURING ELECTRONIC DEVICE

(71) Applicant: FUJIFILM Corporation, Tokyo (JP)

(72) Inventors: Kazunari YAGI, Haibara-gun (JP); Michihiro OGAWA, Haibara-gun (JP); Akiyoshi GOTO, Haibara-gun (JP); Daisuke ASAKAWA, Haibara-gun (JP)

(73) Assignee: FUJIFILM Corporation, Tokyo (JP)

(21) Appl. No.: 17/193,007

(22) Filed: Mar. 5, 2021

Related U.S. Application Data
(63) Continuation of application No. PCT/JP2019/034503, filed on Sep. 3, 2019.

(30) Foreign Application Priority Data
Sep. 26, 2018 (JP) 2018-179998
Feb. 26, 2019 (JP) 2019-033157

(51) Int. Cl. G03F 7/039; G03F 7/038; G03F 7/004; C08F 220/28; C08F 212/14

(52) U.S. Cl. CPC G03F 7/039; G03F 7/038; C08F 220/283; C08F 220/281; C08F 212/24; G03F 7/0045

(57) ABSTRACT

The present invention provides an actinic ray-sensitive or radiation-sensitive resin composition which is excellent in the sensitivity of a resist film to be formed to EUV and excellent in the LER of a positive tone pattern to be formed upon EUV exposure. In addition, the present invention provides a resist film, a pattern forming method, and a method for manufacturing an electronic device, each of which uses the actinic ray-sensitive or radiation-sensitive resin composition.

The actinic ray-sensitive or radiation-sensitive resin composition of an embodiment of the present invention includes a compound that generates an acid upon irradiation with actinic rays or radiation, and a resin having a polarity that increases by an action of an acid, in which the resin includes a repeating unit represented by General Formula (B-1).

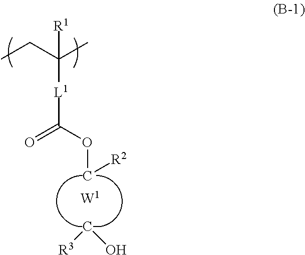

### CROSS-REFERENCE TO RELATED APPLICATIONS

This application is a Continuation of PCT International Application No. PCT/JP2019/034503 filed on Sep. 3, 2019, which claims priority under 35 U.S.C. § 119(a) to Japanese Patent Application No. 2018-179998 filed on Sep. 26, 2018 and Japanese Patent Application No. 2019-033157 filed on Feb. 26, 2019. Each of the above applications is hereby expressly incorporated by reference, in its entirety, into the present application.

### BACKGROUND OF THE INVENTION

### 1. Field of the Invention

The present invention relates to an actinic ray-sensitive or radiation-sensitive resin composition, a resist film, a pattern forming method, a method for manufacturing an electronic device, and a resin.

### 2. Description of the Related Art

In processes for manufacturing semiconductor devices such as an integrated circuit (IC) and a large scale integrated circuit (LSI) in the related art, microfabrication by lithography using an actinic ray-sensitive or radiation-sensitive resin composition has been performed. In recent years, formation of an ultrafine pattern in a submicron region or a quarter-micron region has been demanded in accordance with realization of a high degree of integration for IC. Moreover, development of lithography using an ArF or KrF excimer laser light having a shorter wavelength, and further, extreme ultraviolet (EUV) rays has also been currently in progress.

For example, JP2011-0134479A discloses a resist material that is applicable to ArF exposure and contains a base resin containing one or more of any repeating units represented by specific General Formulae (11) to (15), a photoacid generator that generates a specific sulfonic acid, a quencher, and an organic solvent.

### SUMMARY OF THE INVENTION

With reference to the related art, the present inventors have prepared an actinic ray-sensitive or radiation-sensitive resin composition including a resin having a polarity that increases by an acid, have examined the composition, and have thus found that it is necessary to further improve the sensitivity to ultraviolet rays (EUV) and the line edge roughness (LER) of a pattern (resist pattern) to be formed.

Therefore, an object of the present invention is to provide an actinic ray-sensitive or radiation-sensitive resin composition which is excellent in the sensitivity of a resist film to be formed to EUV and is excellent in the LER of a pattern to be formed upon EUV exposure.

Furthermore, another object of the present invention is to provide a resist film, a pattern forming method, and a method for manufacturing an electronic device, each using the actinic ray-sensitive or radiation-sensitive resin composition.

The present inventors have conducted intensive studies to solve the problems, and as a result, they have found that the problems can be solved by incorporating a resin with a specific structure, having a polarity that increases by an action of an acid, into an actinic ray-sensitive or radiation-sensitive resin composition, thereby completing the present invention.

That is, the present inventors have found that the objects can be accomplished by the following configurations.

[1] An actinic ray-sensitive or radiation-sensitive resin composition comprising:

a compound that generates an acid upon irradiation with actinic rays or radiation; and

a resin having a polarity that increases by an action of an acid,

in which the resin includes a repeating unit represented by General Formula (B-1) which will be described later.

[2] The actinic ray-sensitive or radiation-sensitive resin composition as described in [1],

in which the repeating unit represented by General Formula (B-1) is a repeating unit represented by General Formula (B-2) which will be described later.

[3] The actinic ray-sensitive or radiation-sensitive resin composition as described in [2],

in which a ring W² is a 6-membered ring.

[4] The actinic ray-sensitive or radiation-sensitive resin composition as described in [2] or [3],

in which the repeating unit represented by General Formula (B-2) is a repeating unit represented by General Formula (B-3) which will be described later.

[5] The actinic ray-sensitive or radiation-sensitive resin composition as described in [4],

in which the repeating unit represented by General Formula (B-3) is a repeating unit represented by General Formula (B-4) which will be described later.

[6] The actinic ray-sensitive or radiation-sensitive resin composition as described in any one of [1] to [5],

in which R³ is a trifluoromethyl group.

[7] The actinic ray-sensitive or radiation-sensitive resin composition as described in any one of [1] to [6],

in which a content of the repeating unit represented by General Formula (B-1) is 10% to 80% by mass with respect to all repeating units in the resin.

[8] The actinic ray-sensitive or radiation-sensitive resin composition as described in any one of [1] to [7],

in which a weight-average molecular weight of the resin is 3,500 to 25,000.

[9] A resist film formed from the actinic ray-sensitive or radiation-sensitive resin composition as described in any one of [1] to [8].

[10] A pattern forming method comprising:

a resist film forming step of forming a resist film using the actinic ray-sensitive or radiation-sensitive resin composition as described in any one of [1] to [8];

an exposing step of exposing the resist film; and

a developing step of developing the exposed resist film using a developer.

[11] A method for manufacturing an electronic device, comprising the pattern forming method as described in [10].

According to the present invention, it is possible to provide an actinic ray-sensitive or radiation-sensitive resin composition which is excellent in the sensitivity of a resist film to be formed to EUV and is excellent in the LER of a pattern to be formed upon EUV exposure.

In addition, according to the present invention, it is possible to provide a resist film, a pattern forming method, and a method for manufacturing an electronic device, each using the actinic ray-sensitive or radiation-sensitive resin composition.

### DESCRIPTION OF THE PREFERRED EMBODIMENTS

Hereinafter, the present invention will be described in detail.

Description of configuration requirements described below may be made on the basis of representative embodiments of the present invention in some cases, but the present invention is not limited to such embodiments.

“Actinic rays” or “radiation” in the present specification means, for example, a bright line spectrum of a mercury lamp, far ultraviolet rays typified by an excimer laser, extreme ultraviolet rays (EUV), X-rays, electron beams (EB), or the like. “Light” in the present specification means actinic rays or radiation.

Unless otherwise specified, “exposure” in the present specification encompasses not only exposure by a bright line spectrum of a mercury lamp, far ultraviolet rays typified by an excimer laser, EUV light, X-rays, or the like, but also irradiation with particle rays such as EB and ion beams.

In the present specification, a numerical range expressed using “to” is used in a meaning of a range that includes the preceding and succeeding numerical values of “to” as the lower limit value and the upper limit value, respectively.

In the present specification, (meth)acrylate represents acrylate and methacrylate.

In citations for a group (atomic group) in the present specification, in a case where the group is cited without specifying whether it is substituted or unsubstituted, the group includes both a group having no substituent and a group having a substituent. For example, an “alkyl group” includes not only an alkyl group having no substituent (unsubstituted alkyl group), but also an alkyl group having a substituent (substituted alkyl group). In addition, an “organic group” in the present specification refers to a group including at least one carbon atom.

Furthermore, in the present specification, in a case of referring to an expression “a substituent may be contained”, the types of substituents, the positions of the substituents, and the number of the substituents are not particularly limited. The number of the substituents may be, for example, one, two, three, or more. Examples of the substituent include a monovalent non-metal atomic group from which a hydrogen atom has been excluded, and the substituent can be selected from the following substituent T group, for example.

(Substituent T)

Examples of the substituent T include halogen atoms such as a fluorine atom, a chlorine atom, a bromine atom, and an iodine atom; an alkoxy group such as a methoxy group, an ethoxy group, and a tert-butoxy group; an aryloxy group such as a phenoxy group and a p-tolyloxy group; an alkoxycarbonyl group such as a methoxycarbonyl group, a butoxycarbonyl group, and a phenoxycarbonyl group; an acyloxy group such as an acetoxy group, a propionyloxy group, and a benzoyloxy group; an acyl group such as an acetyl group, a benzoyl group, an isobutyryl group, an acryloyl group, a methacryloyl group, and a methoxalyl group; an alkylsulfanyl group such as a methylsulfanyl group and a tert-butylsulfanyl group; an arylsulfanyl group such as a phenylsulfanyl group and a p-tolylsulfanyl group; an alkyl group; a cycloalkyl group; an aryl group; a heteroaryl group; a hydroxyl group; a carboxyl group; a formyl group; a sulfo group; a cyano group; an alkylaminocarbonyl group; an arylaminocarbonyl group; a sulfonamido group; a silyl group; an amino group; a monoalkylamino group; a dialkylamino group; an arylamino group; and a combination thereof.

Furthermore, in the present specification, the weight-average molecular weight (Mw), the number-average molecular weight (Mn), and the dispersity (also referred to as a molecular weight distribution) (Mw/Mn) of a resin are each defined as a value converted in terms of polystyrene by means of gel permeation chromatography (GPC) measurement (solvent: tetrahydrofuran, flow amount (amount of a sample injected): 10 μL, columns: TSK gel Multipore HXL-M manufactured by Tosoh Corporation, column temperature: 40° C., flow rate: 1.0 mL/min, detector: differential refractive index detector) using a GPC apparatus (HLC-8120 GPC manufactured by Tosoh Corporation).

[Actinic Ray-Sensitive or Radiation-Sensitive Resin Composition]

The actinic ray-sensitive or radiation-sensitive resin composition (hereinafter also simply referred to as a “composition”) of an embodiment of the present invention includes a compound that generates an acid upon irradiation with actinic rays or radiation, and a resin having a polarity that increases by an action of an acid, in which the resin includes a repeating unit represented by General Formula (B-1). A reason why a desired effect can be obtained by satisfying these requirements is not always clear, but is considered to be as follows.

Since EUV (wavelength: 13.5 nm) has a shorter wavelength than, for example, ArF excimer laser light (wavelength: 193 nm), the number of incident photons may be small in a case where the same sensitivity is used upon exposure of a resist film. As a result, in lithography with EUV, a “photon shot noise” in which the number of photons varies probabilistically gives a significant influence, which is a major cause of the deterioration in LER.

In order to reduce the photon shot noise, it is effective to increase an exposure dose to increase the number of incident photons, but this is a trade-off with a demand for a high sensitivity.

In contrast, the present inventors have found that in a case where the resin includes a repeating unit represented by General Formula (B-1) which will be described later, a large amount of fluorine atoms having high EUV absorption efficiency is introduced into a resist film, the sensitivity to EUV is improved, and a glass transition temperature (Tg) of the resin is enhanced due to a hydrogen bond derived from a hydroxyl group, whereby the acid diffusion length is suppressed, the LER of a pattern to be formed upon exposure and development is improved, other units having functions such as improvement of a sensitivity and a LER can be used by integration of a substituent having a fluorine atom and a hydroxyl group into one protective group-containing unit, and thus, the performance of the resin can be further improved. That is, in a case where the composition of the embodiment of the present invention has the configuration, it can be suitably used for lithography with EUV.

Hereinafter, the components included in the composition of the embodiment of the present invention will be described in detail. Furthermore, the composition of the embodiment of the present invention is a so-called resist composition, and may be either a positive tone resist composition or a negative tone resist composition. In addition, the composition of the embodiment of the present invention may be either a resist composition for alkali development or a resist composition for organic solvent development.

The composition is typically a chemically amplified resist composition.

<Resin>

(Resin (X))

The composition includes a resin including a repeating unit represented by General Formula (B-1) which will be described later (hereinafter also referred to as a “resin (X)”).

The resin (X) is a resin having a polarity that increases by an action of an acid. Therefore, in a pattern forming method which will be described later, typically, in a case where an alkali developer is adopted as the developer, a positive tone pattern is suitably formed, and in a case where an organic developer is adopted as the developer, a negative tone pattern is suitably formed.

Hereinafter, the repeating unit represented by General Formula (B-1) (hereinafter also referred to as a “repeating unit (b)”) included in the resin (X) and other repeating units which may be optionally included will be described in detail.

[Repeating Unit Represented by General Formula (B-1) (Repeating Unit (b))]

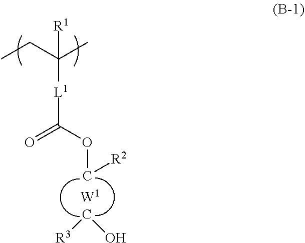

In General Formula (B-1),

R¹ represents a hydrogen atom, a fluorine atom, or an alkyl group which may have a substituent.

L¹ represents a single bond or a divalent linking group consisting of a carbon atom and an oxygen atom.

The ring W¹ represents a monocyclic or polycyclic ring.

R² represents an alkyl group, an alkenyl group, or an aryl group, each of which may have a substituent.

R³ represents an organic group including 3 or more fluorine atoms.

In the ring W¹, a carbon atom is bonded to the tertiary carbon atom bonded to R², and the carbon atom is bonded to a hydrogen atom or an electron-donating group having a value of a Hammett substituent constant am of less than 0.

As shown in General Formula (B-1), the repeating unit (b) has a structure in which a carboxyl group as a polar group is protected by a group including a ring W¹ as a group that is eliminated by an action of an acid (eliminable group). In a case where the repeating unit (b) has the structure as a group having a polarity that increases by an action of an acid (hereinafter also referred to as an “acid-decomposable group”), the resin (X) has a property that a polarity of the resin (X) increases by an action of an acid.

Examples of the alkyl group which may have a substituent, represented by R, include a methyl group, a group represented by —CH₂—R¹⁰¹, and a group in which at least one of the hydrogen atoms of these groups is substituted with a halogen atom. R¹⁰¹ represents a halogen atom (a fluorine atom and the like), a hydroxyl group, or a monovalent organic group, for example, an alkyl group having 5 or less carbon atoms and an acyl group having 5 or less carbon atoms, and R¹⁰¹ is preferably the alkyl group having 3 or less carbon atoms, and more preferably a methyl group.

As R¹, the hydrogen atom, the fluorine atom, the methyl group, a trifluoromethyl group, or a hydroxymethyl group is preferable, the hydrogen atom or the methyl group is more preferable, and the methyl group is still more preferable.

Examples of the divalent linking group consisting of a carbon atom and an oxygen atom represented by L¹ include —COO—Rt- and —O—Rt-. In the formulae, Rt represents an alkylene group or a cycloalkylene group.

In a case where L¹ represents —COO—Rt-, Rt is preferably an alkylene group having 1 to 5 carbon atoms, more preferably —CH₂—, —(CH₂)₂—, or —(CH₂)₃—, and still more preferably —CH₂—.

As L¹, the single bond or —COO—Rt- is preferable, the single bond or —COO—CH₂. is more preferable, and from the viewpoint that the LER and the LWR of a pattern to be formed are more excellent, the single bond is still more preferable.

The ring W represents a monocyclic or polycyclic ring. The ring W¹ is not particularly limited as long as it is a ring having a tertiary carbon atom bonded to R² and a tertiary carbon atom bonded to R³ and a hydroxyl group, as shown in the General Formula (B-1), and may be, for example, a ring in which carbon contributing to ring formation is carbonyl carbon or a heterocycle including a heteroatom. Further, the ring W¹ may have a non-aromatic unsaturated bond. Examples of the ring W¹ include monocyclic or polycyclic alicycles and heterocycles.

The number of the ring members of the ring W¹ is not particularly limited, but is, for example, 3 to 14, and preferably 4 to 10.

From the viewpoint that the EUV sensitivity of a resist film to be formed is more excellent, and the LER and the collapse suppressing ability of a pattern to be formed are more excellent, the ring W¹ is more preferably a 6- or 10-membered ring, and still more preferably the 6-membered ring.

Examples of the monocyclic alicycle include a monocyclic saturated aliphatic hydrocarbon ring and an unsaturated aliphatic hydrocarbon ring, having 3 to 10 carbon atoms, such as a cyclopentane ring, a cyclohexane ring, a cyclohexene ring and a cyclooctane ring. Examples of the polycyclic alicycle include a polycyclic saturated aliphatic hydrocarbon ring and an unsaturated aliphatic hydrocarbon ring, having 7 to 14 carbon atoms, such as a norbornene ring, a tricyclodecane ring, a tetracyclodecane ring, an adamantane ring, and a decahydronaphthalene ring.

The heteroatom included in the heterocycle is not particularly limited, and examples thereof include a nitrogen atom, an oxygen atom, and a sulfur atom. Examples of the heterocycle include a lactone ring (a tetrahydrofuran ring, a tetrahydropyran ring, and the like), a sultone ring, and a decahydroisoquinoline ring.

As the ring W¹, the cyclopentane ring, the cyclohexane ring, the cyclohexene ring, the norbornene ring, or the adamantane ring is preferable; from the viewpoint that the LER of a pattern to be formed is more excellent, the cyclohexane ring, the cyclohexene ring, the norbornene ring, or the adamantane ring is more preferable; from the viewpoint that the EUV sensitivity of a resist film to be formed is more excellent, and the LER and the collapse suppressing ability of a pattern to be formed are more excellent, the cyclohexane ring is still more preferable.

In addition, as the ring W¹, the monocyclic saturated aliphatic hydrocarbon ring is preferable, and the cyclohexane ring is more preferable, from the viewpoint that the LWR of a pattern to be formed is more excellent.

R² represents an alkyl group, an alkenyl group, or an aryl group, each of which may have a substituent.

The alkyl group represented by R² is not particularly limited, and examples thereof include an alkyl group having 1 to 8 carbon atoms (which may be in any of linear, branched, and cyclic forms), with a linear or branched alkyl group having 1 to 4 carbon atoms being preferable.

The alkenyl group represented by R² is not particularly limited, and examples thereof include an alkenyl group having 2 to 8 carbon atoms (which may be in any of linear, branched, and cyclic forms), with a linear or branched alkenyl group having 2 to 4 carbon atoms being preferable.

The aryl group represented by R² is not particularly limited, and examples thereof include an aryl group having 6 to 10 carbon atoms. Specific examples of the aryl group include a phenyl group, a naphthyl group, and an anthryl group, and the phenyl group is preferable.

Furthermore, the alkyl group, the alkenyl group, or the aryl group represented by R² may have a substituent. The substituent is not particularly limited, and examples thereof include the groups exemplified in the above-mentioned substituent T group.

As R², a linear or branched alkyl group having 1 to 4 carbon atoms or a linear or branched alkenyl group having 2 to 4 carbon atoms is preferable, a methyl group or an ethyl group is more preferable, and the methyl group is still more preferable, from the viewpoint that the LER of a pattern to be formed is more excellent.

Furthermore, as R², a cycloalkyl group is preferable, and a cyclohexyl group is more preferable, from the viewpoint that the LWR of a pattern to be formed is more excellent.

R³ represents an organic group including 3 or more fluorine atoms.

The organic group represented by R³ is not particularly limited as long as it has 3 or more fluorine atoms, and examples thereof include an alkyl group, an aryl group, an aralkyl group, and an alkenyl group, each having 3 or more fluorine atoms. That is, R³ may be a group in which 3 or more hydrogen atoms contained in these organic groups are substituted with fluorine atoms.

The upper limit of the number of fluorine atoms contained in R³ is not particularly limited, but is, for example, 20 or less.

Examples of the alkyl group include an alkyl group having 1 to 8 carbon atoms (which may be in any of linear, branched, and cyclic forms), and the alkyl group is preferably a linear or branched alkyl group having 1 to 4 carbon atoms. Further, the alkyl group may have a substituent. The substituent is not particularly limited, and examples thereof include the groups exemplified in the above-mentioned substituent T group.

Examples of the alkyl group having 3 or more fluorine atoms include a perfluoroalkyl group having 1 to 4 carbon atoms. Specific examples of the alkyl group having 3 or more fluorine atoms include CF₃, C₂F₅, C₃F₇, C₄F₉, CH₂CF₃, CH₂CH₂CF₃, CH₂C₂F₅, CH₂CH₂C₂F₅, CH₂C₃F₇, CH₂CH₂C₃F₇, CH₂C₄F₉, and CH₂CH₂C₄F₉, and the alkyl group is preferably CF₃, C₂F₅, or C₃F₇, and more preferably CF₃ (trifluoromethyl group).

Examples of the aryl group include an aryl group having 6 to 10 carbon atoms, and the aryl group is preferably a phenyl group, a naphthyl group, or an anthryl group, and more preferably phenyl group.

Examples of the aryl group having 3 or more fluorine atoms include a group in which a hydrogen atom on a ring of an aryl group is substituted with a fluorine atom or a group having a fluorine atom. Examples of the group having a fluorine atom include the above-mentioned alkyl group having 3 or more fluorine atoms, and the group is preferably CF₃, C₂F₅, or C₃F₇, and more preferably CF₃. Further, the aryl group may have a substituent other than a fluorine atom or a group having a fluorine atom.

As the aryl group having 3 or more fluorine atoms, a trifluoromethylphenyl group or a bis(trifluoromethyl)phenyl group is preferable.

The alkyl group moiety in the aralkyl group preferably has 1 to 6 carbon atoms, and more preferably has 1 to 3 carbon atoms. As the aralkyl group, a benzyl group or a phenethyl group is preferable. Further, the aralkyl group may have a substituent. The substituent is not particularly limited, and examples thereof include the groups exemplified in the above-mentioned substituent T group.

Examples of the aralkyl group having 3 or more fluorine atoms include a group in which the aryl group in an aralkyl group is the above-mentioned aryl group having 3 or more fluorine atoms.

Examples of the alkenyl group include an alkenyl group having 2 to 8 carbon atoms (which may be in any of linear, branched, and cyclic forms), and the alkenyl group is preferably a linear or branched alkenyl group having 2 to 4 carbon atoms. Examples of the alkenyl group include a vinyl group, an allyl group, a butenyl group, and a cyclohexenyl group. Further, the alkenyl group may have a substituent. The substituent is not particularly limited, and examples thereof include the groups exemplified in the above-mentioned substituent T group.

Examples of the alkenyl group having 3 or more fluorine atoms include a perfluoroalkenyl group having 2 to 4 carbon atoms. Specific examples of the alkenyl group having 3 or more fluorine atoms include a perfluorovinyl group and a perfluoroallyl group.

Furthermore, the organic group including 3 or more fluorine atoms represented by R³ may include a heteroatom. Examples of the heteroatom include a nitrogen atom, an oxygen atom, and a sulfur atom, and examples of the organic group including a heteroatom include a group obtained by introducing —CO—, —O—, —S—, —NH—, —SO—, —SO₂—, or a divalent linking group formed by combination thereof into the above-mentioned alkyl group, aryl group, aralkyl group, or alkenyl group.

As the organic group including 3 or more fluorine atoms, represented by R³, a perfluoroalkyl group having 1 to 3 carbon atoms, a trifluoromethylphenyl group, a perfluorophenyl group, a perfluorovinyl group, or a perfluoroallyl group is preferable, and the perfluoroalkyl group having 1 to 3 carbon atoms is more preferable, from the viewpoint that it is easy to synthesize a raw material monomer of the repeating unit (b). Among these, the trifluoromethyl group is more preferable from the viewpoint that it is more excellent in the sensitivity to EUV, and the LER, the LWR, and the collapse suppressing ability of a pattern to be formed.

In the ring W¹, a carbon atom (hereinafter also referred to as an “adjacent carbon atom”) is bonded to the tertiary carbon atom to which R² is bonded, and the adjacent carbon atom is bonded to a hydrogen atom or an electron-donating group having a value of a Hammett substituent constant am of less than 0.

Here, the Hammett substituent constant σ value is a numerical value representing an effect of a substituent on an acid dissociation equilibrium constant of a substituted benzoic acid, and is a parameter indicating the strength of the electron-withdrawing property and the electron-donating property of the substituent. The Hammett substituent constant am value (hereinafter also simply referred to as a “am value”) in the present specification means a substituent constant σ in a case where a substituent is located at the meta position of benzoic acid.

As the am value of each group in the present specification, the value described in a document “Hansch et al., Chemical Reviews, 1991, Vol, 91, No. 2, 165-195” is adopted. As a group whose σm value is not shown in the document, the am value can be calculated based on a difference between the pKa of benzoic acid and the pKa of a benzoic acid derivative having a substituent in the meta position, using software “ACD/ChemSketch (ACD/Labs 8.00 Release Product Version: 8.08)”.

In a case where the adjacent carbon atoms in the ring W¹ has an electron-withdrawing group having an am value that exceeds 0, elimination of an eliminable group including the ring W¹ by an action of an acid is suppressed, and thus, the repeating unit (b) does not have a polarity changing ability or has at least a reduced polarity changing ability. In contrast, by allowing the adjacent carbon atoms in the ring W¹ to have a hydrogen atom (am value=0) or an electron-donating group having an am value of less than 0 in the resin (X), elimination of an eliminable group including the ring W¹ by an action of an acid is accelerated, and thus, it is possible to enhance the polarity changing ability of the repeating unit (b) and improve the sensitivity of the resin (X) with respect to exposure.

The am value of the electron-donating group contained in the adjacent carbon atom is preferably −0.05 or less. The lower limit of the am value of the electron-donating group is not particularly limited, but is preferably −0.4 or higher.

Examples of the electron-donating group having a Hammett substituent constant am value of less than 0 include an alkyl group, an amino group, and a silyl group, and these groups may further have a substituent as long as the electron-donating property is not lost. Examples of the substituent include an alkyl group, an alkenyl group, an alkynyl group, an aryl group, a hydroxyl group, an alkoxy group, a thiol group, a thioalkoxy group, an amino group, and a halogen atom.

The adjacent carbon atom in the ring W¹ preferably has a hydrogen atom, or an alkyl group having 1 to 4 carbon atoms or an amino group which may have one or two of the alkyl groups having 1 to 4 carbon atoms as the electron-donating group, more preferably has a methyl group or an ethyl group, and still more preferably has the hydrogen atom.

Among the atoms constituting the ring W¹, the above-mentioned tertiary carbon atom bonded to R², the above-mentioned tertiary carbon atom bonded to R³ and the hydroxyl group, and the atom other than the adjacent carbon atom have a substituent. The substituent is not particularly limited, examples thereof include the groups exemplified in the above-mentioned substituent T group, and the substituent is preferably the halogen atom, the hydroxyl group, or the organic group, and more preferably the organic group.

Examples of the organic group include an alkyl group, an aryl group, an aralkyl group, and an alkenyl group.

Examples of the alkyl group include an alkyl group having 1 to 8 carbon atoms (which may be in any of linear, branched, and cyclic forms), and the alkyl group is preferably a linear or branched alkyl group having 1 to 4 carbon atoms.

Examples of the aryl group include an aryl group having 6 to 10 carbon atoms, and the aryl group is preferably a phenyl group, a naphthyl group, or an anthryl group, and more preferably phenyl group.

The alkyl group moiety in the aralkyl group preferably has 1 to 6 carbon atoms, and more preferably has 1 to 3 carbon atoms. As the aralkyl group, a benzyl group or a phenethyl group is preferable.

Examples of the alkenyl group include an alkenyl group having 2 to 8 carbon atoms (which may be in any of linear, branched, and cyclic forms), and the alkenyl group is preferably a linear or branched alkenyl group having 2 to 4 carbon atoms.

The organic group may have a halogen atom (preferably a fluorine atom). That is, R³ may be a group in which a hydrogen atom contained in the organic group is substituted with a halogen atom (preferably a fluorine atom).

Furthermore, the organic group may include a heteroatom such as a nitrogen atom, an oxygen atom, and a sulfur atom. That is, the organic group may be a group obtained by introducing —CO—, —O—, —S—, —NH—, —SO—, —SO₂—, or a divalent linking group formed by combination thereof into the alkyl group, the aryl group, the aralkyl group, or the alkenyl group.

The repeating unit (b) preferably has a fluorine atom content of 10% by mass or more, and more preferably has 20% by mass with respect to the total mass of the repeating unit (b), from the viewpoint that the sensitivity of a resist film to be formed is more excellent. In addition, an upper limit value thereof is not particularly limited, but is, for example, 60% by mass or less.

As the repeating unit (b), a repeating unit represented by General Formula (B-2) is preferable.

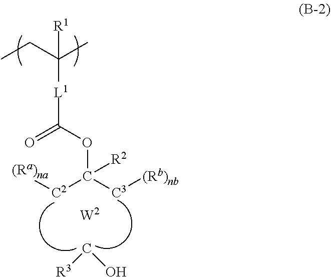

In General Formula (B-2), R¹, L¹, R², and R³ have the same definitions as R¹, L¹, R², and R³ in General Formula (B-1), respectively, and the respective suitable aspects thereof are also the same.

The ring W² represents a monocyclic or polycyclic ring.

Ra and R^{b} each independently represent a hydrogen atom or an electron-donating group having a Hammett substituent constant am value of less than 0.

na and nb each independently represent 1 or 2.

The ring W² represents a monocyclic or polycyclic ring. The ring W² may be, for example, a ring in which carbon contributing to ring formation is carbonyl carbon, and may be a heterocycle including a heteroatom and have a non-aromatic unsaturated bond. Examples of the ring W¹ include monocyclic or polycyclic alicycles and heterocycles.

Furthermore, the number of ring members of the ring W² is 4 or more, and in a case where the number of ring members of ring W² is 5 or more, the ring W² has an atom constituting the ring W² at either or both of positions between a tertiary carbon atom bonded to R³ and to a hydroxyl group, and a carbon atom C²; and between a tertiary carbon atom bonded to R³ and to a hydroxyl group, and a carbon atom C³.

Specific examples and suitable aspects of the ring W² are each the same as those of the ring W¹ as mentioned above.

The electron-donating group having a om value of less than 0, represented by each of R^{a} and R^{b}, has the same definition as the above-mentioned electron-donating group, and a suitable aspect thereof is also the same.

As each of R^{a} and R^{b}, a hydrogen atom, an alkyl group having 1 to 4 carbon atoms, or an amino group which may have one or two alkyl groups having 1 to 4 carbon atoms is preferable, the hydrogen atom, a methyl group, or an ethyl group is more preferable, and the hydrogen atom is still more preferable.

na and nb represent the number of R^{a}'s and R^{b}'s contained in the carbon atoms C² and C³, respectively. That is, in a case where the carbon atom C² (or the carbon atom C³) forms a double bond with an atom constituting the ring W², na (or nb) is 1, and in a case where the carbon atom C² (or the carbon atom C³) forms a single bond with an atom constituting the ring W², na (or nb) is 2.

Among the atoms constituting the ring W², an atom other than the tertiary carbon atom bonded to R², the tertiary carbon atom bonded to R³ and the hydroxyl group, the carbon atom C², and the carbon atom C³ may have a substituent. The substituent has the same definition as the above-mentioned substituent which may be contained in the ring W², and a suitable aspect thereof is also the same.

As the repeating unit represented by General Formula (B-2), in particular, a repeating unit represented by General Formula (B-3) is preferable among those from the viewpoint that the sensitivity of a resist film to be formed is more excellent and the LER and the collapse suppressing ability of a pattern to be formed are more excellent.

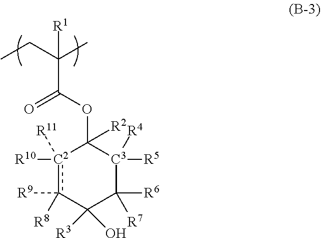

In General Formula (B-3), R¹, R², and R³ have the same definitions as R¹, R², and R³ in General Formula (B-2), respectively, and each of suitable aspects thereof is the same.

In General Formula (B-3), a portion where a solid line and a broken line are parallel represents a single bond or a double bond.

R⁴, R⁵, R¹⁰, and R¹¹ each independently represent a hydrogen atom or an electron-donating group having a Hammett substituent constant am value of less than 0.

R⁶ and R⁹ each independently represent a hydrogen atom or an organic group.

It should be noted that in a case where the portion where a solid line and a broken line are parallel represents a double bond, R⁹ and R¹¹ do not exist. That is, only in a case where a portion where a solid line and a broken line are parallel in General Formula (B-3) represents a single bond, R⁹ and R¹¹ exist.

Suitable aspects of R⁴, R⁵, R¹⁰, and R¹¹ in General Formula (B-3) are each the same as those of R^{a} and R^{b} in General Formula (B-3) as mentioned above.

The organic group represented by each of R⁶ to R⁹ is a tertiary carbon atom has the same definition as the organic group which may be contained in an atom other than the tertiary carbon atom bonded to R² and the oxygen atom, the tertiary carbon atom bonded to R³ and the hydroxyl group, and the adjacent carbon atom as mentioned above, among the atoms constituting the ring W1 in General Formula (B-1), and a suitable aspect thereof is also the same. As each of R⁶ to R⁹, a hydrogen atom is preferable.

As the repeating unit represented by General Formula (B-3), a repeating unit represented by General Formula (B-4) is preferable.

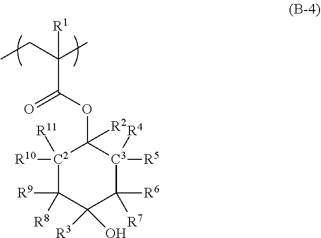

In General Formula (B-4), R¹ to R¹¹ have the same definitions as R¹ to R¹¹ in General Formula (B-3), respectively, and each of suitable aspects thereof is also the same.

Specific examples of the monomer which can constitute the repeating unit represented by General Formula (B-1) are shown below, but the present invention is not limited thereto.

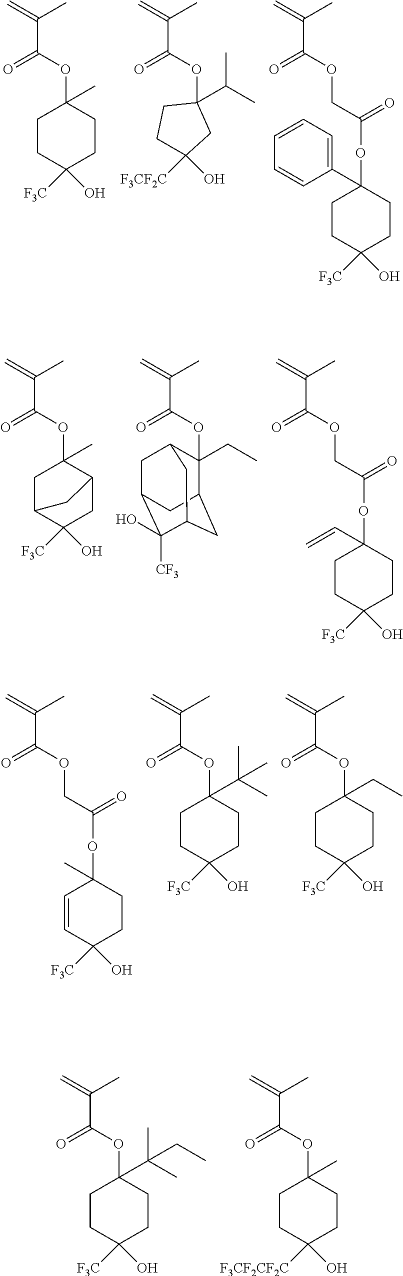

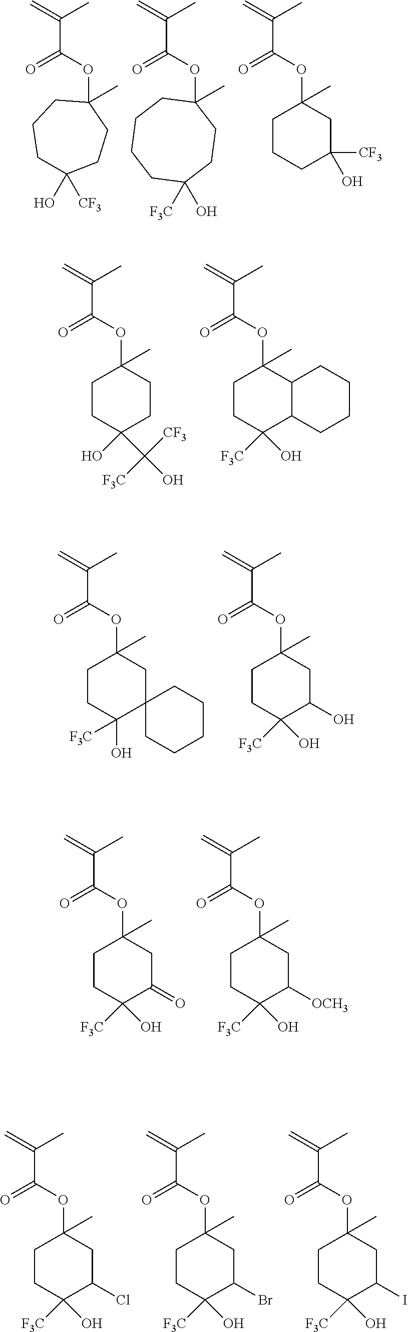

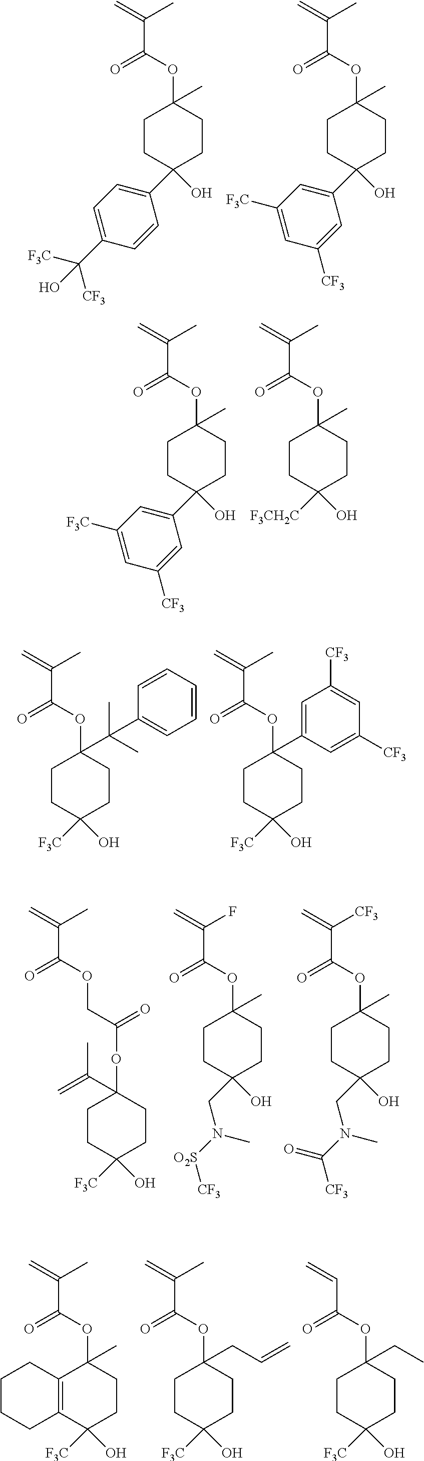

The repeating unit (b) included in the resin (X) may be used singly or in combination of two or more kinds thereof.

A content of the repeating unit (b) (in a case where the repeating units (b) are present in a plural number, a total content thereof) in the resin (X) is preferably 10% to 80% by mass, more preferably 20% to 75% by mass, and still more preferably 30% to 70% by mass with respect to all the repeating units in the resin (X).

[Other Repeating Units]

The resin (X) may further include another repeating unit, in addition to the repeating unit (b).

Such another repeating unit which can be included in the resin (X) will be described below in detail.

Repeating Unit Having Acid-Decomposable Group

The resin (X) may include a repeating unit having an acid-decomposable group (hereinafter also referred to as a “repeating unit Y1”). It should be noted that the repeating unit Y1 does not correspond to the repeating unit (b).

The acid-decomposable group is not particularly limited as long as it is a group other than the acid-decomposable group contained in the repeating unit (b) represented by General Formula (B-1) as mentioned above, and preferably has a structure in which a polar group is protected by a group (eliminable group) that is eliminated through decomposition by an action of an acid.

Examples of the polar group include an acidic group (a group which dissociates in a 2.38%-by-mass aqueous tetramethylammonium hydroxide solution), such as a carboxyl group, a phenolic hydroxyl group, a fluorinated alcohol group, a sulfonic acid group, a sulfonamido group, a sulfonylimido group, an (alkylsulfonyl)(alkylcarbonyl)methylene group, an (alkylsulfonyl)(alkylcarbonyl)imido group, a bis(alkylcarbonyl)methylene group, a bis(alkylcarbonyl)imido group, a bis(alkylsulfonyl)methylene group, a bis(alkylsulfonyl)imido group, a tris(alkylcarbonyl)methylene group, and a tris(alkylsulfonyl)methylene group, and an alcoholic hydroxyl group.

Moreover, the alcoholic hydroxyl group refers to a hydroxyl group bonded to a hydrocarbon group, which is a hydroxyl group other than a hydroxyl group (phenolic hydroxyl group) directly bonded to an aromatic ring, from which an aliphatic alcohol group (for example, a hexafluoroisopropanol group) having the α-position substituted with an electron-withdrawing group such as a fluorine atom is excluded as a hydroxyl group. The alcoholic hydroxyl group is preferably a hydroxyl group having an acid dissociation constant (pKa) from 12 to 20.

As the polar group, a carboxyl group, a phenolic hydroxyl group, a fluorinated alcohol group (more preferably a hexafluoroisopropanol group), or a sulfonic acid group is preferable.

As the acid-decomposable group, a group obtained by substituting a hydrogen atom of a preferred polar group with a group (eliminable group) that is eliminated by an action of an acid is preferable.

Examples of the group (eliminable group) that is eliminated by an action of an acid include —C(R₃₆)(R₃₇)(R₃₈), —C(R₃₆)(R₃₇)(OR₃₉), and —C(R₀₁)(R₀₂)(OR₃₉).

In the formulae, R₃₆ to R₃₉ each independently represent an alkyl group, a cycloalkyl group, an aryl group, an aralkyl group, or an alkenyl group. R₃₆ and R₃₇ may be bonded to each other to form a ring.

R₀₁ and R₀₂ each independently represent a hydrogen atom, an alkyl group, a cycloalkyl group, an aryl group, an aralkyl group, or an alkenyl group.

As the alkyl group represented by each of R₃₆ to R₃₉, R₀₁, and R₀₂, an alkyl group having 1 to 8 carbon atoms is preferable. Examples of the alkyl group having 1 to 8 carbon atoms include a methyl group, an ethyl group, a propyl group, an n-butyl group, a sec-butyl group, a hexyl group, and an octyl group.

The cycloalkyl group represented by each of R₃₆ to R₃₉, R₀₁, and R₀₂ may be either a monocycle or a polycycle. As the monocyclic cycloalkyl group, a cycloalkyl group having 3 to 8 carbon atoms is preferable. Examples of the monocyclic cycloalkyl group having 3 to 8 carbon atoms include a cyclopropyl group, a cyclobutyl group, a cyclopentyl group, a cyclohexyl group, and a cyclooctyl group. As the polycyclic cycloalkyl group, a cycloalkyl group having 6 to 20 carbon atoms is preferable. Examples of the polycyclic cycloalkyl group having 6 to 20 carbon atoms include an adamantyl group, a norbornyl group, an isobornyl group, a camphanyl group, a dicyclopentyl group, an α-pinene group, a tricyclodecanyl group, a tetracyclododecyl group, and an androstanyl group. Further, at least one carbon atom in the cycloalkyl group may be substituted with a heteroatom such as an oxygen atom.

As the aryl group represented by each of R₃ to R₃₉, R₀₁, and R₀₂, an aryl group having 6 to 10 carbon atoms is preferable. Examples of the aryl group having 6 to 10 carbon atoms include a phenyl group, a naphthyl group, and an anthryl group.

As the aralkyl group represented by each of R₃₆ to R₃₉, R₀₁, and R₀₂, an aralkyl group having 7 to 12 carbon atoms is preferable. Examples of the aralkyl group having 7 to 12 carbon atoms include a benzyl group, a phenethyl group, and a naphthylmethyl group.

As the alkenyl group represented by each of R₃₆ to R₃₉, R₀₁, and R₀₂, an alkenyl group having 2 to 8 carbon atoms is preferable. Examples of the alkenyl group having 2 to 8 carbon atoms include a vinyl group, an allyl group, a butenyl group, and a cyclohexenyl group.

The ring formed by the mutual bonding of R₃₆ and R₃₇ is preferably a (monocyclic or polycyclic) cycloalkyl group. As the cycloalkyl group, a monocyclic cycloalkyl group such as a cyclopentyl group and a cyclohexyl group, and a polycyclic cycloalkyl group such as a norbornyl group, a tetracyclodecanyl group, a tetracyclododecanyl group, and an adamantyl group are preferable.

As the acid-decomposable group, a cumyl ester group, an enol ester group, an acetal ester group, a tertiary alkyl ester group, or the like is preferable, and the acetal ester group or the tertiary alkyl ester group is more preferable.

As the repeating unit Y1, a repeating unit represented by General Formula (AII) is preferable.

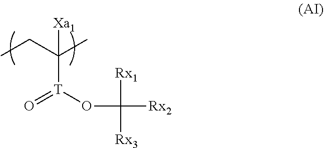

In General Formula (AI),

Xa₁ represents a hydrogen atom, a halogen atom, or an alkyl group which may have a substituent.

T represents a single bond or a divalent linking group.

Rx₁ to Rx₃ each independently represent an (linear or branched) alkyl group or a (monocyclic or polycyclic) cycloalkyl group. It should be noted that in a case where all of Rx₁ to Rx₃ are (linear or branched) alkyl groups, it is preferable that at least two of Rx₁, Rx₂, or Rx₃ are methyl groups.

Two of Rx₁ to Rx₃ may be bonded to each other to form a (monocyclic or polycyclic) cycloalkyl group.

Examples of the alkyl group which may have a substituent, represented by Xa₁, include a methyl group and a group represented by —CH₂—R₁₁. R₁₁ represents a halogen atom (a fluorine atom and the like), a hydroxyl group, or a monovalent organic group, examples thereof include an alkyl group having 5 or less carbon atoms and an acyl group having 5 or less carbon atoms, the alkyl group having 3 or less carbon atoms is preferable, and the methyl group is more preferable.

Examples of the halogen atom represented by Xa₁ include a fluorine atom, a chlorine atom, a bromine atom, and an iodine atom, and the halogen atom is preferably the fluorine atom or the iodine atom.

As Xa₁, the hydrogen atom, the fluorine atom, the iodine atom, the methyl group, a trifluoromethyl group, or a hydroxymethyl group is preferable.

Examples of the divalent linking group represented by T include an alkylene group, an arylene group, a —COO—Rt- group, and an —O—Rt- group. In the formulae, Rt represents an alkylene group or a cycloalkylene group.

T is preferably the single bond or the —COO—Rt- group. In a case where T represents the —COO—Rt-group, Rt is preferably an alkylene group having 1 to 5 carbon atoms, and more preferably a —CH₂— group, a —(CH₂)₂— group, or a —(CH₂)₃— group.

As the alkyl group represented by each of Rx₁ to Rx₃, an alkyl group having 1 to 4 carbon atoms, such as a methyl group, an ethyl group, an n-propyl group, an isopropyl group, an n-butyl group, an isobutyl group, and a t-butyl group, is preferable.

As the cycloalkyl group represented by each of Rx₁ to Rx₃, a monocyclic cycloalkyl group such as a cyclopentyl group and a cyclohexyl group, or a polycyclic cycloalkyl group such as a norbornyl group, a tetracyclodecanyl group, a tetracyclododecanyl group, and an adamantyl group is preferable.

As the cycloalkyl group formed by the bonding of two of Rx₁ to Rx₃, a monocyclic cycloalkyl group such as a cyclopentyl group and a cyclohexyl group is preferable, and in addition, a polycyclic cycloalkyl group such as a norbornyl group, a tetracyclodecanyl group, a tetracyclododecanyl group, and an adamantyl group is also preferable. Among those, a monocyclic cycloalkyl group having 5 or 6 carbon atoms is more preferable.

In the cycloalkyl group formed by the bonding of two of Rx₁ to Rx₃, for example, one of the methylene groups constituting the ring may be substituted with a heteroatom such as an oxygen atom, or a group having a heteroatom, such as a carbonyl group.

In a case where each of the groups has a substituent, examples of the substituent include an alkyl group (having 1 to 4 carbon atoms), a halogen atom, a hydroxyl group, an alkoxy group (having 1 to 4 carbon atoms), a carboxyl group, and an alkoxycarbonyl group (having 2 to 6 carbon atoms). The substituent preferably has 8 or less carbon atoms.

Specific examples of the repeating unit Y1 are shown below, but the present invention is not limited to these specific examples.

In the specific examples, Rx represents a hydrogen atom, a fluorine atom, an iodine atom, CH₃, CF₃, or CH₂OH. Rxa and Rxb each independently represent an alkyl group having 1 to 4 carbon atoms. Z represents a substituent including a polar group, and in a case where Z's are present in a plural number, Z's may be the same as or different from each other. p represents 0 or a positive integer. Examples of the substituent including a polar group represented by Z include a linear or branched alkyl group or alicyclic group, which has a hydroxyl group, a cyano group, an amino group, an alkylamido group, or a sulfonamido group, and an alkyl group having a hydroxyl group is preferable. As the branched alkyl group, an isopropyl group is preferable.

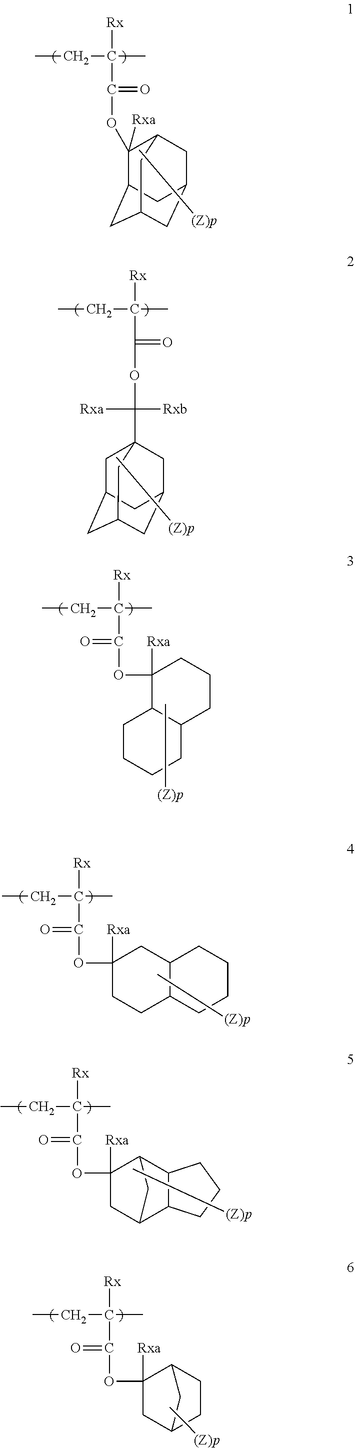

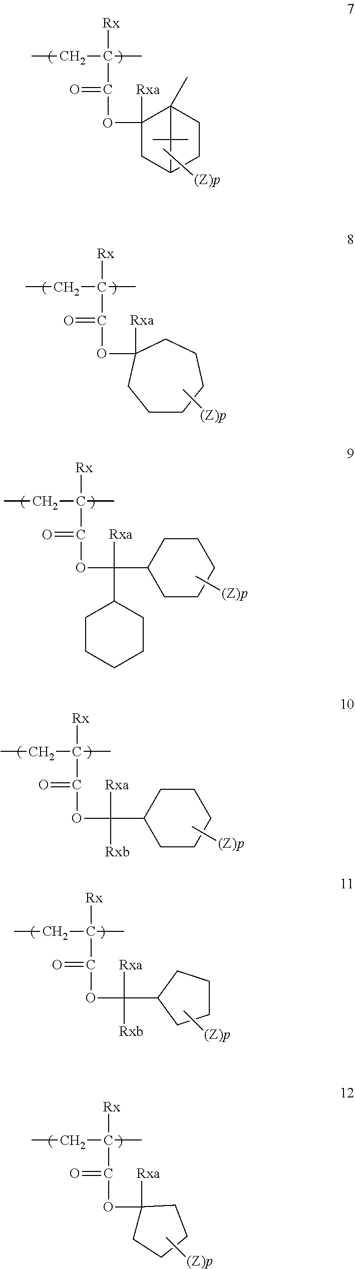

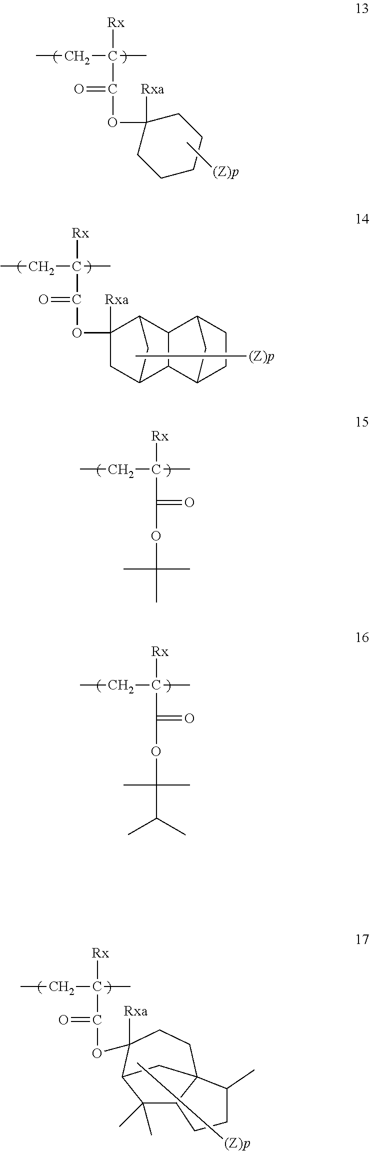

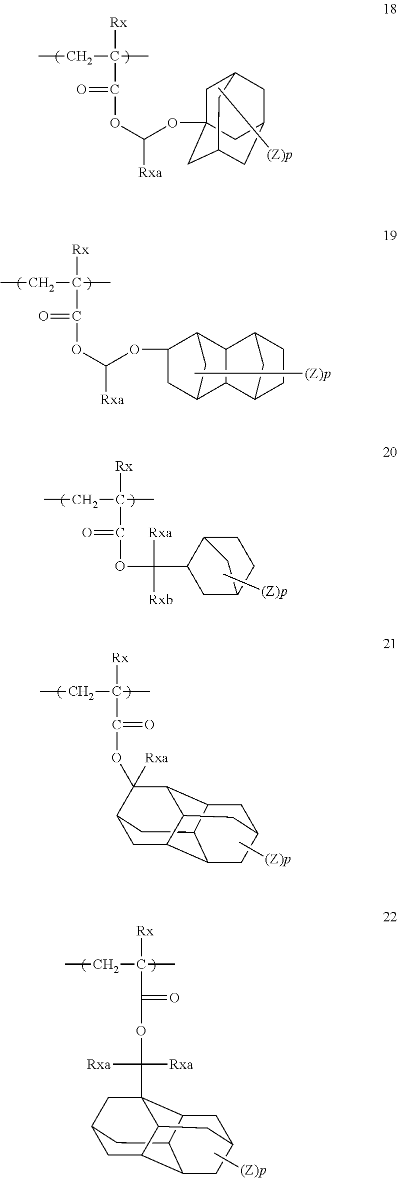

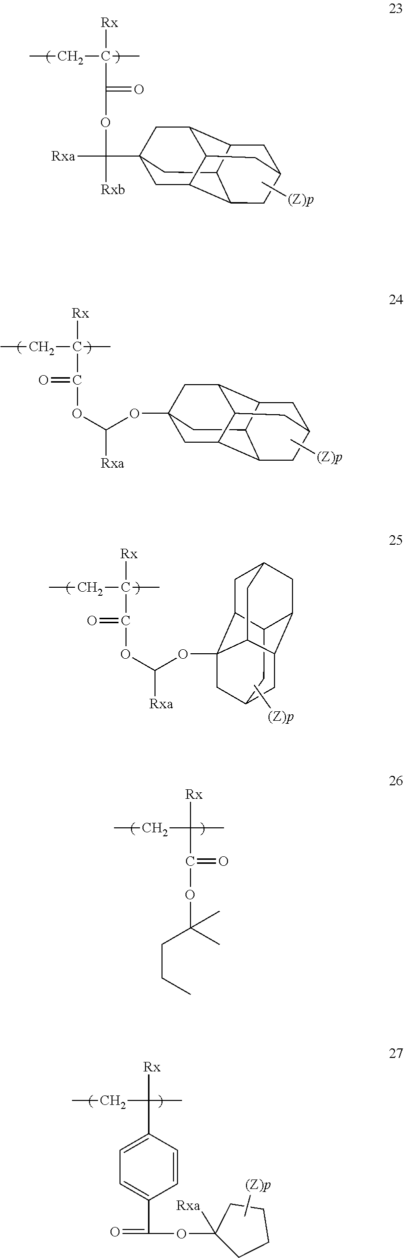

The repeating unit Y1 included in the resin (X) may be used singly or in combination of two or more kinds thereof.

In a case where the resin (X) includes a repeating unit Y1, a content of the repeating unit Y1 is preferably 5% to 50% by mass, more preferably 5% to 40% by mass, and still more preferably 10% to 30% by mass with respect to all the repeating units in the resin (X).

In addition, in a case where the resin (X) includes a repeating unit Y1, a total content of the repeating unit (b) and the repeating unit Y1 is preferably 10% to 80% by mass, more preferably 20% to 75% by mass, and still more preferably 30% to 70% by mass with respect to all the repeating units in the resin (X).

Other Repeating Unit Having Lactone Structure

The resin (X) may include another repeating unit having a lactone structure (hereinafter also referred to as a “repeating unit Y2”). It should be noted that the repeating unit Y2 does not correspond to the repeating unit (b) and the repeating unit Y1.

Examples of the repeating unit Y2 include a repeating unit represented by General Formula (AII).

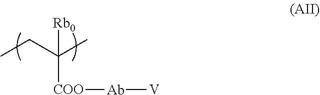

In General Formula (AII), Rb₀ represents a hydrogen atom, a halogen atom, or an alkyl group having 1 to 4 carbon atoms.

The alkyl group of Rb₀ may have a substituent, and examples of the substituent include a hydroxyl group and a halogen atom (a fluorine atom, a chlorine atom, a bromine atom, and an iodine atom). Among these, Rb₀ is preferably the hydrogen atom or a methyl group.

In General Formula (AII), Ab represents a single bond, an alkylene group, a divalent linking group having a monocyclic or polycyclic alicyclic hydrocarbon structure, an ether group, an ester group, a carbonyl group, a carboxyl group, or a divalent group formed by combination thereof. Among these, the single bond or a linking group represented by -Ab₁-COO— is preferable. Ab₁ is a linear or branched alkylene group, or a monocyclic or polycyclic cycloalkylene group, and is preferably a methylene group, an ethylene group, a cyclohexylene group, an adamantylene group, or a norbornylene group.

In General Formula (AII), V represents a group including a lactone structure.

The group including a lactone structure is not particularly limited as long as it includes a lactone structure.

As the lactone structure, a 5- to 7-membered ring lactone structure is preferable, and a 5- to 7-membered ring lactone structure to which another ring structure is fused so as to form a bicyclo structure or spiro structure is more preferable.

As the lactone structure, lactone structures represented by General Formulae (LC1-1) to (LC1-17) are preferable, and among these, the group represented by General Formula (LC1-1), General Formula (LC1-4), General Formula (LC1-5), General Formula (LC1-6), General Formula (LC1-13), or General Formula (LC1-14) is more preferable. A lactone structure from which any one of hydrogen atoms is removed is derived into a group including the lactone structure.

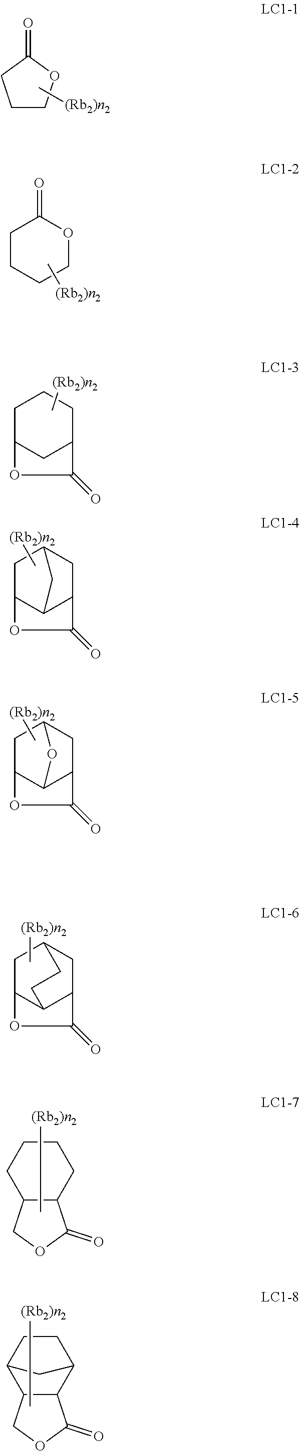

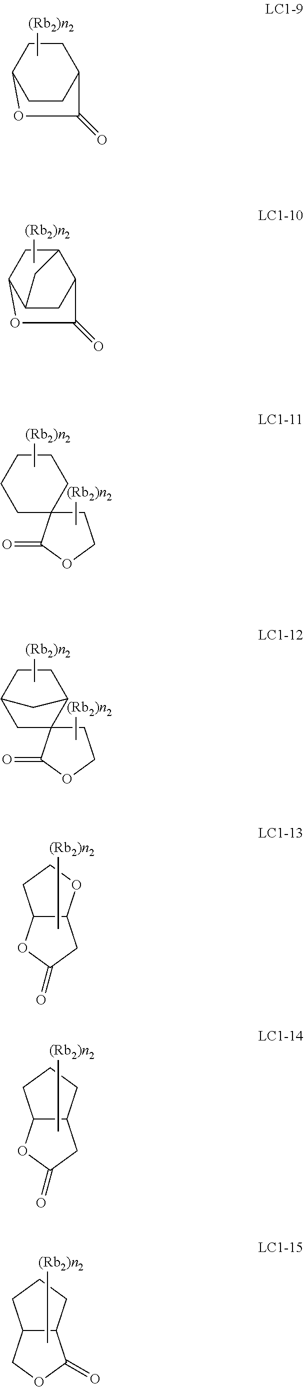

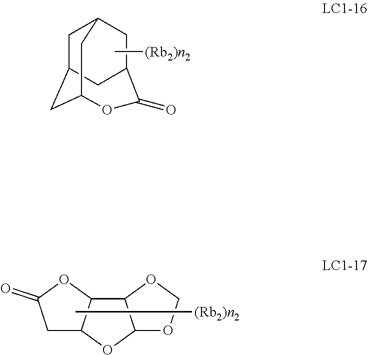

The lactone structure moiety may have a substituent (Rb₂). Examples of the substituent (Rb₂) include an alkyl group having 1 to 8 carbon atoms, a cycloalkyl group having 4 to 7 carbon atoms, an alkoxy group having 1 to 8 carbon atoms, an alkoxycarbonyl group having 2 to 8 carbon atoms, a carboxyl group, a halogen atom, and a cyano group, an alkyl group having 1 to 4 carbon atoms or the cyano group is preferable, and the cyano group is more preferable. n₂ represents an integer of 0 to 4. In a case where n₂ is 2 or more, the substituents (Rb₂) which are present in a plural number may be the same as or different from each other. Further, the substituents (Rb₂) which are present in a plural number may be bonded to each other to form a ring.

Optical isomers of the repeating unit Y2 are typically present, but any of the optical isomers may be used. In addition, one kind of optical isomers may be used singly or a mixture of a plurality of the optical isomers may be used. In a case where one kind of optical isomers is mainly used, an optical purity (ee) thereof is preferably 90 or more, and more preferably 95 or more.

Specific examples of the repeating unit Y2 are shown below, but the present invention is not limited to these specific examples. Further, the following specific examples may further have a substituent (examples thereof include the above-mentioned substituent (Rb₂)).

(in the formulae, Rx represents H, CH₃, CH₂OH, or CF₃)

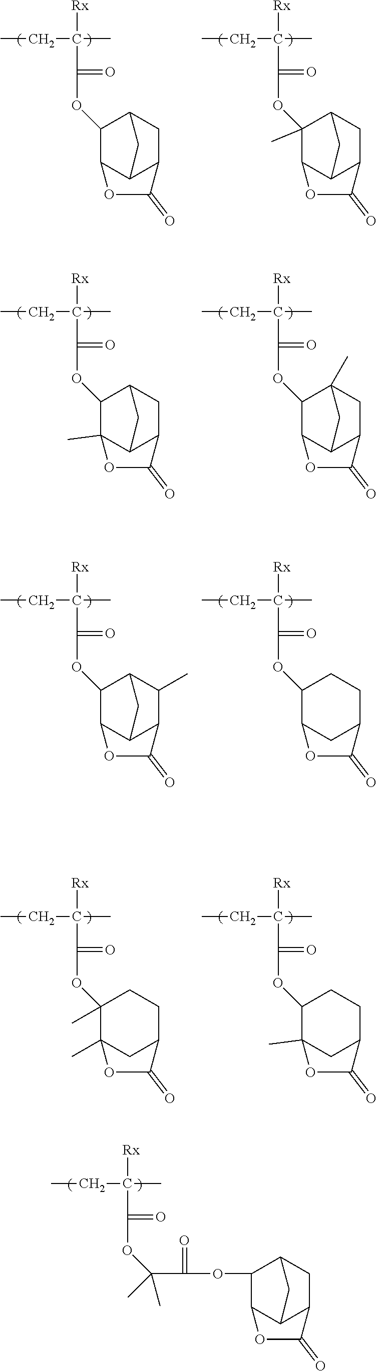

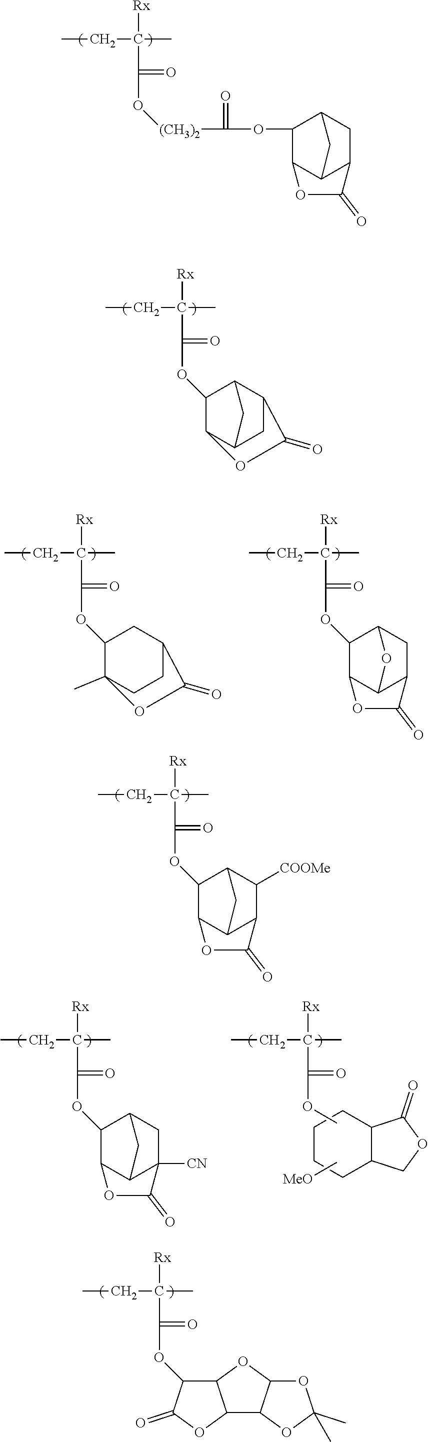

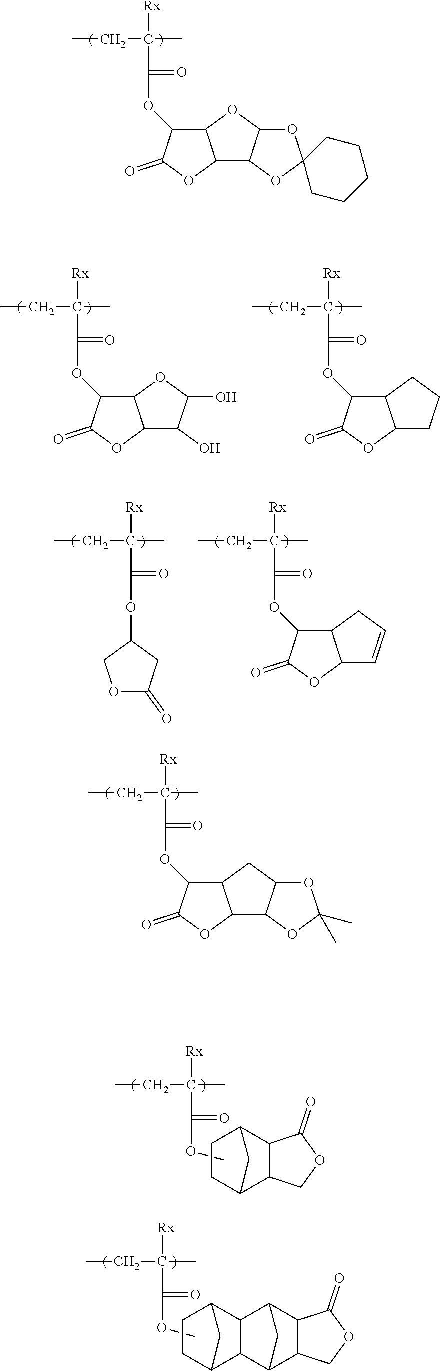

In a case where the resin (X) includes a repeating unit Y2, a content of the repeating unit Y2 is preferably 5% to 60% by mass, more preferably 10% to 60% by mass, and still more preferably 10% to 40% by mass with respect to all the repeating units in the resin (X).

Repeating Unit Having Phenolic Hydroxyl Group

The resin (X) may include a repeating unit having a phenolic hydroxyl group (hereinafter also referred to as a “repeating unit Y3”).

Examples of the repeating unit Y3 include a repeating unit represented by General Formula (I).

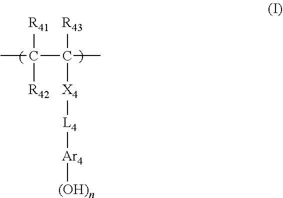

In Formula (I),

R₄₁, R₄₂, and R₄₃ each independently represent a hydrogen atom, an alkyl group, a cycloalkyl group, a halogen atom, a cyano group, or an alkoxycarbonyl group. It should be noted that R₄₂ may be bonded to Ar₄ to form a ring, and in this case, R₄₂ represents a single bond or an alkylene group.

X₄ represents a single bond, —COO—, or —CONR₆₄—, and R₆₄ represents a hydrogen atom or an alkyl group.

L₄ represents a single bond or a divalent linking group.

Ar₄ represents an (n+1)-valent aromatic group, and in a case where Ar₄ is bonded to R₄₂ to form a ring, it represents an (n+2)-valent aromatic group.

n represents an integer of 1 to 5.

For the purpose of increasing the polarity of the repeating unit represented by General Formula (I), it is preferable that n is an integer of 2 or more, or X₄ is —COO— or —CONR₆₄—.

As the alkyl group represented by each of R₄₁, R₄₂, and R₄₃ in General Formula (I), an alkyl group having 20 or less carbon atoms, such as a methyl group, an ethyl group, a propyl group, an isopropyl group, an n-butyl group, a sec-butyl group, a hexyl group, a 2-ethylhexyl group, an octyl group, and a dodecyl group, each of which may have a substituent, is preferable, an alkyl group having 8 or less carbon atoms is more preferable, and an alkyl group having 3 or less carbon atoms is still more preferable.

The cycloalkyl group represented by each of R₄₁, R₄₂, and R₄₃ in General Formula (I) may be either a monocycle or a polycycle. A monocyclic cycloalkyl group having 3 to 8 carbon atoms, such as a cyclopropyl group, a cyclopentyl group, and a cyclohexyl group, which may have a substituent, is preferable.

Examples of the halogen atom represented by each of R₄₁, R₄₂, and R₄₃ in General Formula (I) include a fluorine atom, a chlorine atom, a bromine atom, and an iodine atom, and the fluorine atom is preferable.

As the alkyl group included in the alkoxycarbonyl group represented by each of R₄₁, R₄₂, and R₄₃ in General Formula (I), the same ones as the alkyl group in each of R₄₁, R₄₂, and R₄₃ are preferable.

Preferred examples of the substituent in each of the groups include an alkyl group, a cycloalkyl group, an aryl group, an amino group, an amido group, a ureido group, a urethane group, a hydroxyl group, a carboxyl group, a halogen atom, an alkoxy group, a thioether group, an acyl group, an acyloxy group, an alkoxycarbonyl group, a cyano group, and a nitro group, and the substituent preferably has 8 or less carbon atoms.

Ar₄ represents an (n+1)-valent aromatic group. The divalent aromatic hydrocarbon group in a case where n is 1 may have a substituent. As Ar₄, an arylene group having 6 to 18 carbon atoms, such as a phenylene group, a tolylene group, a naphthylene group, and an anthracenylene group, or an aromatic hydrocarbon group including a heterocycle such as thiophene, furan, pyrrole, benzothiophene, benzofuran, benzopyrrole, triazine, imidazole, benzimidazole, triazole, thiadiazole, and thiazole is preferable.

Specific suitable examples of the (n+1)-valent aromatic group in a case where n is an integer of 2 or more include groups formed by excluding any (n−1) hydrogen atoms from the above-described specific examples of the divalent aromatic group.

The (n+1)-valent aromatic group may further have a substituent.

As the substituent in the (n+1)-valent aromatic group, a halogen atom is preferable, and a fluorine atom or an iodine atom is more preferable.

Preferred examples of the alkyl group of R₆₄ in —CONR₆₄— (R₆₄ represents a hydrogen atom or an alkyl group) represented by X₄ include an alkyl group having 20 or less carbon atoms, such as a methyl group, an ethyl group, a propyl group, an isopropyl group, an n-butyl group, a sec-butyl group, a hexyl group, a 2-ethylhexyl group, an octyl group, and a dodecyl group, each of which may have a substituent, and the alkyl group is more preferably an alkyl group having 8 or less carbon atoms.

As X₄, a single bond, —COO—, or —CONH— is preferable, the single bond or —COO— is more preferable, and the single bond is still more preferable.

As the divalent linking group represented by L₄, an alkylene group is preferable. As the alkylene group, an alkylene group having 1 to 8 carbon atoms, such as a methylene group, an ethylene group, a propylene group, a butylene group, a hexylene group, and an octylene group, each of which may have a substituent, is preferable.

As L₄, a single bond is preferable.

As Ar₄, an aromatic hydrocarbon group having 6 to 18 carbon atoms, which may have a substituent, is preferable, a benzene ring group, a naphthalene ring group, or a biphenylene ring group is more preferable, and the benzene ring group is still more preferable. n is preferably 1 or 2, and from the viewpoint that the LER of a pattern to be formed is more excellent, n is more preferably 1.

Among those, as the repeating unit represented by General Formula (I), a repeating unit derived from hydroxystyrene or a hydroxystyrene derivative is preferable. That is, Ar₄ represents a benzene ring group, and X₄ and L₄ each preferably represent a single bond.

Specific examples of the repeating unit Y3 are shown below, but the present invention is not limited to these specific examples. In the formulae, a represents 1 or 2.

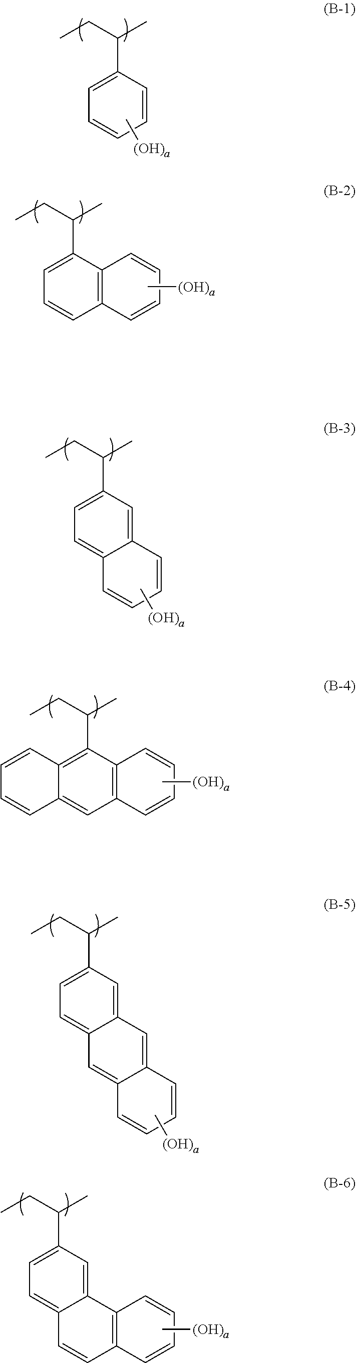

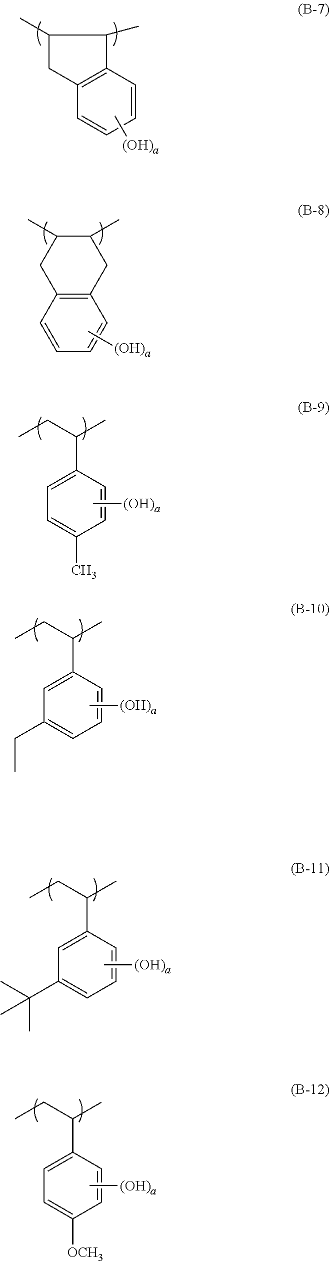

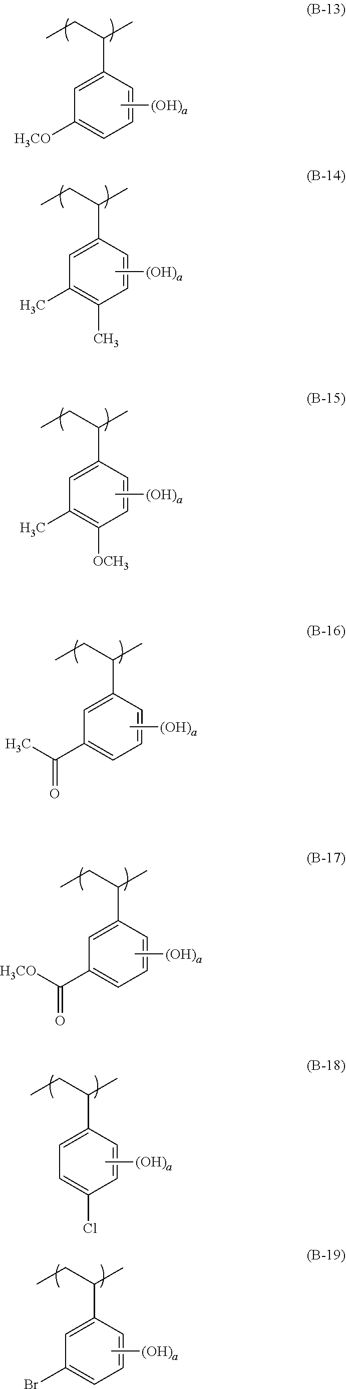

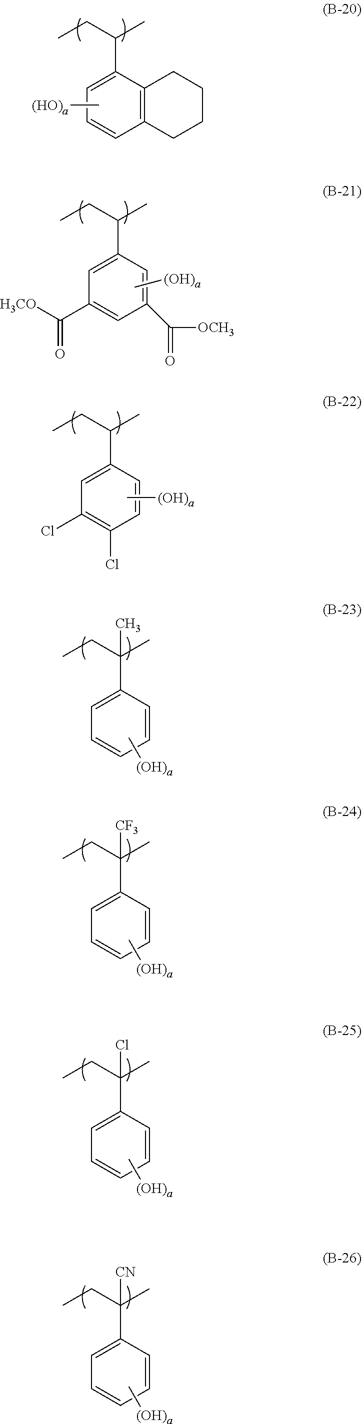

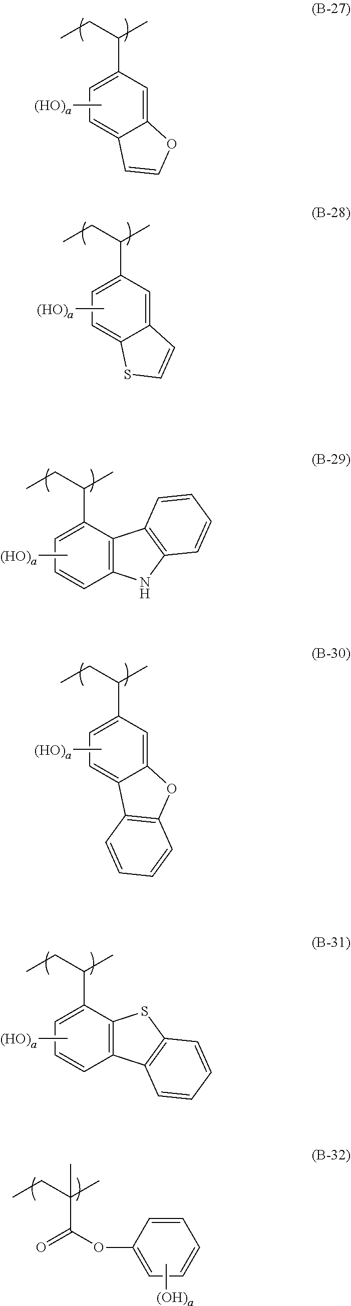

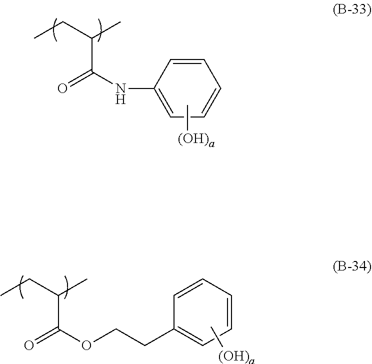

In a case where the resin (X) includes the repeating unit Y3, a content of the repeating unit Y3 is preferably 5% to 60% by mass, and more preferably 10% to 50% by mass with respect to all the repeating units in the resin (A).

Repeating Unit Having Acid Group Other than Phenolic Hydroxyl Group

The resin (X) may include another repeating unit having an acid group (hereinafter also referred to as a “repeating unit Y4”). The repeating unit Y4 does not correspond to the repeating unit (b), the repeating unit Y1, the repeating unit Y2, and the repeating unit Y3.

Examples of the acid group included in the repeating unit Y4 include a carboxylic acid group, a fluorinated alcohol group, a sulfonic acid group, a sulfonamido group, a sulfonylimido group, an (alkylsulfonyl)(alkylcarbonyl)methylene group, an (alkylsulfonyl)(alkylcarbonyl)imido group, a bis(alkylcarbonyl)methylene group, a bis(alkylcarbonyl)imido group, a bis(alkylsulfonyl)methylene group, a bis(alkylsulfonyl)imido group, a tris(alkylcarbonyl)methylene group, and a tris(alkylsulfonyl)methylene group.

As the acid group, the fluorinated alcohol group (more preferably hexafluoroisopropanol group), the sulfonimido group, or the bis(alkylcarbonyl)methylene group is preferable.

The skeleton of the repeating unit Y4 is not particularly limited, but the repeating unit Y4 is preferably a (meth)acrylate-based repeating unit or a styrene-based repeating unit.

Specific examples of the repeating unit Y4 are shown below, but the present invention is not limited to these specific examples. In the formulae, Rx represents a hydrogen atom, CH₃, CF₃, or CH₂OH.

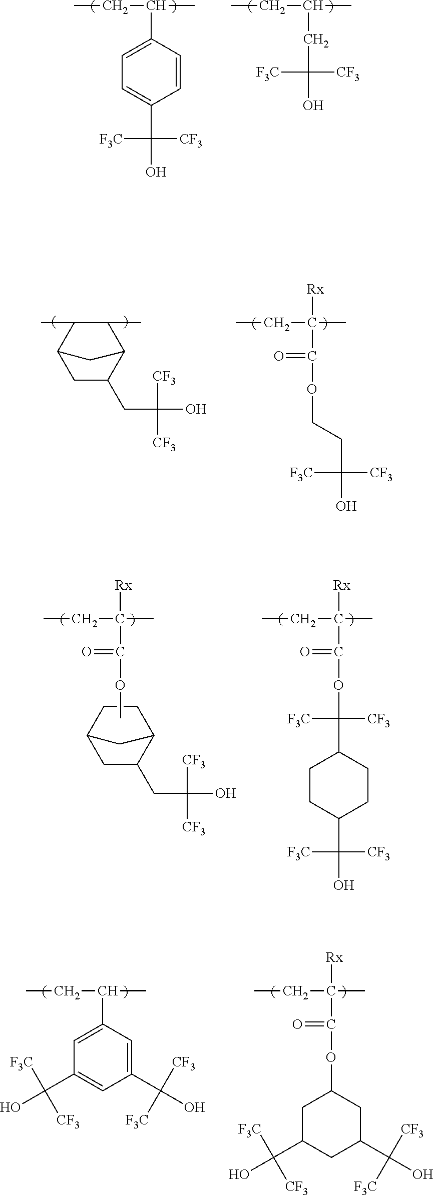

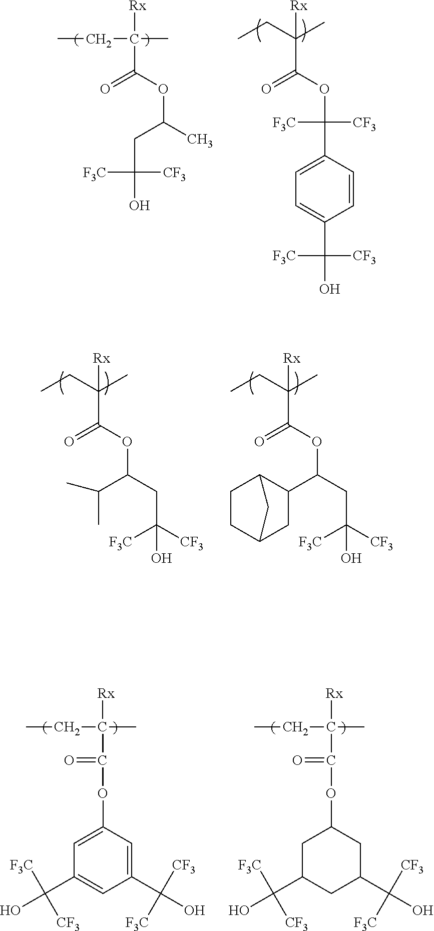

In a case where the resin (X) includes the repeating unit Y4, a content of the repeating unit Y4 is preferably 5% to 60% by mass, and more preferably 10% to 60% by mass with respect to all the repeating units in the resin (A).

The resin (X) may include another repeating unit, in addition to the repeating units Y1 to Y4.

From the viewpoint that the LER of a pattern to be formed upon EUV exposure is more excellent in a case where the composition is for EUV exposure, it is preferable that the resin (X) includes the above-mentioned repeating unit Y3 or includes a repeating unit having no aromatic group among the above-mentioned repeating units Y4, and it is more preferable that the resin (X) includes the repeating unit Y3 and the number of the phenolic hydroxyl groups contained in the repeating unit Y3 is 1 (n in General Formula (I) is 1).

In a case where the composition is for ArF exposure, it is preferable that the resin (X) does not substantially have an aromatic group from the viewpoint of transparency of ArF light. More specifically, the repeating unit having an aromatic group is preferably 5% by mole or less, more preferably 3% by mole or less, and ideally 0% by mole with respect to all the repeating units in the resin (X), that is, it is still more preferable that the repeating unit having an aromatic group is not included. In addition, the resin (X) preferably has a monocyclic or polycyclic alicyclic hydrocarbon structure.

[Method for Synthesizing Resin (X)]

The resin (X) can be synthesized by synthesizing monomers which serve as raw materials for the respective repeating units according to an ordinary method, mixing the respective raw material monomers so as to have a desired compositional ratio, and subjecting the monomers to polymerization (for example, radical polymerization).

For example, the above-mentioned raw material monomer of the repeating unit (b) represented by General Formula (B-1) can be synthesized by reacting an intermediate 1 with an organic metal R³M as shown in the following scheme.

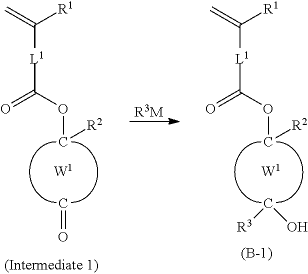

In the organic metal R³M, R³ has the same definition as R³ in General Formula (B-1), and M represents a metal-containing group.

Examples of the organic metal R³M include organic lithium (for example, the organic metal with M=Li), organic magnesium (for example, the organic metal with M=MgX, in which X represents a halogen atom), and organic zinc (for example, the organic metal with M=ZnX, in which X represents a halogen atom), organic silicon (for example, the organic metal with M=SiMe³), and organic boron (for example, the organic metal with M=BPh²).

In addition, in order to accelerate the reaction of the Intermediate 1 with the organic metal R³M, a Lewis acid and a Lewis base may be used in combination.

The weight-average molecular weight of the resin (X) is preferably 3,500 to 25,000, more preferably 3,500 to 20,000, still more preferably 4,000 to 10,000, and particularly preferably 4,000 to 8,000 from the viewpoint that the LER of a pattern to be formed is more excellent. The dispersity (Mw/Mn) of the resin (X) is usually 1.0 to 3.0, preferably 1.0 to 2.6, more preferably 1.0 to 2.0, and still more preferably 1.1 to 1.7 from the viewpoint that the LER of a pattern formed is more excellent.

The Tg of the resin (X) is preferably 90° C. or higher, more preferably 100° C. or higher, still more preferably 110° C. or higher, particularly preferably 115° C. or higher, and most preferably 120° C. or higher. The upper limit is preferably 200° C. or lower, more preferably 190° C. or lower, and still more preferably 180° C. or lower.

Moreover, in the present specification, the glass transition temperature (Tg) of a polymer such as the resin (A) is usually measured using a differential scanning calorimeter (DSC).

It should be noted that for a polymer having a Tg which cannot be measured using a differential scanning calorimeter (DSC), the Tg can be calculated by the following method. First, the Tg of a homopolymer consisting only of each repeating unit included in the polymer is calculated by a Bicerano method. Hereinafter, the calculated Tg is referred to as “the Tg of the repeating unit”. Next, the mass ratio (%) of each repeating unit to all the repeating units in the polymer is calculated. Next, the product of the Tg of each repeating unit and the mass ratio of the repeating unit is calculated, and the products are summed to obtain the Tg (° C.) of the polymer.

The Bicerano method is described in Prediction of polymer properties, Marcel Dekker Inc., New York (1993), and the like. Further, the calculation of a Tg by the Bicerano method can be carried out using MDL Polymer (MDL Information Systems, Inc.), which is software for estimating physical properties of a polymer.

The resin (X) may be used singly or in combination of two or more kinds thereof.

The content of the resin (X) in the composition (in a case where the resins (X) are present in a plural number, a total content thereof) is generally 20.0% by mass or more in many cases, and is preferably 40.0% by mass or more, more preferably 50.0% by mass or more, and still more preferably 60.0% by mass or more with respect to the total solid content of the composition. An upper limit thereof is not particularly limited, but is preferably 99.9% by mass or less, more preferably 99.5% by mass or less, and still more preferably 99.0% by mass or less.

<Compound that Generates Acid Upon Irradiation with Actinic Rays or Radiation>

The composition includes a compound that generates an acid upon irradiation with actinic rays or radiation (hereinafter also referred to as a “photoacid generator”).

The photoacid generator may be in a form of a low-molecular-weight compound or a form incorporated into a part of a polymer. Further, a combination of the form of a low-molecular-weight compound and the form incorporated into a part of a polymer may also be used.

In a case where the photoacid generator is in the form of a low-molecular-weight compound, the molecular weight is preferably 3,000 or less, more preferably 2,000 or less, and still more preferably 1,000 or less.

In a case where the photoacid generator is incorporated into a part of a polymer, it may be incorporated into a part of the resin (X) or in a resin different from the resin (X).

Among those, the photoacid generator is preferably in the form of a low-molecular-weight compound.

The photoacid generator is not particularly limited as long as it is a known one, but is preferably a compound that generates an organic acid upon irradiation with actinic rays or radiation (preferably EUV or EB).

As the organic acid, for example, at least any one of sulfonic acid, bis(alkylsulfonyl)imide, or tris(alkylsulfonyl)methide is preferable.

The pKa of an acid generated from the photoacid generator is preferably −16.0 to 2.0, more preferably −15.0 to 1.0, and still more preferably −14.0 to 0.5 from the viewpoint that the LER performance is more excellent.

The pKa refers to an acid dissociation constant pKa in an aqueous solution, and is defined, for example, in Chemical Handbook (II) (Revised 4th Edition, 1993, compiled by the Chemical Society of Japan, Maruzen Company, Ltd.). A lower value of the acid dissociation constant pka indicates higher acid strength. Specifically, the acid dissociation constant pKa in an aqueous solution can be actually measured by using an infinite-dilution aqueous solution and measuring the acid dissociation constant at 25° C. Alternatively, the acid dissociation constant pKa can also be determined using the following software package 1 by computation from a value based on a Hammett substituent constant and the database of publicly known literature values. All of the values of pKa described in the present specification indicate values determined by computation using the software package.

Software package 1: ACD/pka DB version 8.0

The photoacid generator is preferably a compound represented by General Formula (ZI), General Formula (ZII), or General Formula (ZIII).

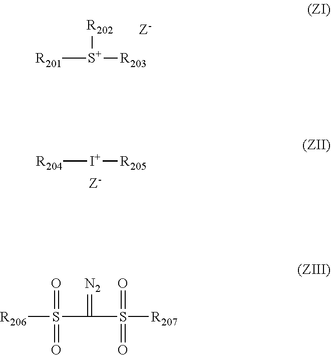

In General Formula (ZI),

R₂₀₁, R₂₀₂, and R₂₀₃ each independently represent an organic group.

The organic group represented by each of R₂₀₁, R₂₀₂, and R₂₀₃ generally has 1 to 30 carbon atoms, and preferably has 1 to 20 carbon atoms.

In addition, two of R₂₀₁ to R₂₀₃ may be bonded to each other to form a ring structure, and the ring may include an oxygen atom, a sulfur atom, an ester bond, an amide bond, or a carbonyl group. Examples of the group formed by the bonding of two of R₂₀₁ to R₂₀₃ include an alkylene group (for example, a butylene group and a pentylene group).

Z⁻ represents a non-nucleophilic anion (anion having an extremely low ability to cause a nucleophilic reaction).

Examples of the organic group of each of R₂₀₁, R₂₀₂, and R₂₀₃ include an aryl group, an alkyl group, and a cycloalkyl group.

It is preferable that at least one of R₂₀₁, R₂₀₂, or R₂₀₃ is an aryl group, and it is more preferable that all of R₂₀₁, R₂₀₂, and R₂₀₃ represent an aryl group. As the aryl group, not only a phenyl group, a naphthyl group, or the like but also a heteroaryl group such as an indole residue and a pyrrole residue is also available.

As the alkyl group of each of R₂₀₁ to R₂₀₃, a linear or branched alkyl group having 1 to 10 carbon atoms is preferable, and a methyl group, an ethyl group, an n-propyl group, an i-propyl group, or an n-butyl group is more preferable.

As the cycloalkyl group of each of R₂₀₁ to R₂₀₃, a cycloalkyl group having 3 to 10 carbon atoms is preferable, and a cyclopropyl group, a cyclobutyl group, a cyclopentyl group, a cyclohexyl group, or a cycloheptyl group is more preferable.

Examples of the non-nucleophilic anion include a sulfonate anion (an aliphatic sulfonate anion, an aromatic sulfonate anion, a camphor sulfonate anion, and the like), a carboxylate anion (an aliphatic carboxylate anion, an aromatic carboxylate anion, an aralkyl carboxylate anion, and the like), a sulfonylimide anion, a bis(alkylsulfonyl)imide anion, and a tris(alkylsulfonyl)methide anion.

The aliphatic moiety in each of the aliphatic sulfonate anion and the aliphatic carboxylate anion may be an alkyl group or a cycloalkyl group, and has a linear or branched alkyl group having 1 to 30 carbon atoms, or is preferably a cycloalkyl group having 3 to 30 carbon atoms.

The aryl group in each of the aromatic sulfonate anion and the aromatic carboxylate anion is preferably an aryl group having 6 to 14 carbon atoms. Examples of the aryl group having 6 to 14 carbon atoms include a phenyl group, a tolyl group, and a naphthyl group.

The alkyl group, the cycloalkyl group, and the aryl group exemplified above may have a substituent.

As the aralkyl group in the aralkylcarboxylate anion, an aralkyl group having 7 to 14 carbon atoms is preferable. Examples of the aralkyl group having 7 to 14 carbon atoms include a benzyl group, a phenethyl group, a naphthylmethyl group, a naphthylethyl group, and a naphthylbutyl group.

Examples of the sulfonylimide anion include a saccharin anion.

The alkyl group in the bis(alkylsulfonyl)imide anion and the tris(alkylsulfonyl)methide anion is preferably an alkyl group having 1 to 5 carbon atoms. Furthermore, the alkyl group in the bis(alkylsulfonyl)imide anion may be bonded to each other to form a ring structure. As a result, the acid strength increases.

Examples of the other non-nucleophilic anions include fluorinated phosphorus (for example, PF₆⁻), fluorinated boron (for example, BF₄⁻), and fluorinated antimony (for example, SbF₆⁻).

As the non-nucleophilic anion, an aliphatic sulfonate anion in which at least α-position of sulfonic acid is substituted with a fluorine atom, an aromatic sulfonate anion substituted with a fluorine atom or a group having a fluorine atom, a bis(alkylsulfonyl)imide anion in which an alkyl group is substituted with a fluorine atom, or a tris(alkylsulfonyl)methide anion in which an alkyl group is substituted with a fluorine atom is preferable. Among those, a perfluoroaliphatic sulfonate anion (preferably having 4 to 8 carbon atoms) or a benzene sulfonate anion having a fluorine atom is more preferable, and a nonafluorobutane sulfonate anion, a perfluorooctane sulfonate anion, a pentafluorobenzene sulfonate anion, or a 3,5-bis(trifluoromethyl) benzenesulfonate anion is more preferable.

Furthermore, as the non-nucleophilic anion, an anion represented by General Formula (AN1) is also preferable.

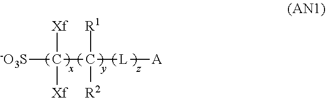

In the formula,

Xf's each independently represent a fluorine atom or an alkyl group substituted with at least one fluorine atom.

R¹ and R² each independently represent a hydrogen atom, a fluorine atom, or an alkyl group, and in a case where R¹'s and R²'s are each present in a plural number, R¹'s and R²'s may each be the same as or different from each other.

L represents a divalent linking group, and in a case where L's are present in a plural number, L's may be the same as or different from each other.

A represents a cyclic organic group.

x represents an integer of 1 to 20, y represents an integer of 0 to 10, and z represents an integer of 0 to 10.

In General Formula (ZII) and General Formula (ZIII),

R₂₀₄ to R₂₀₇ each independently represent an aryl group, an alkyl group, or a cycloalkyl group.

As the aryl group, the alkyl group, and the cycloalkyl group of each of R₂₀₄ to R₂₀₇ have the same definitions as the aryl group, the alkyl group, and the cycloalkyl group, respectively, of each of R₂₀₁ to R₂₀₃ in General Formula (ZI) as described above.

Z⁻ represents a non-nucleophilic anion, has the same definition as the non-nucleophilic anion of Z⁻ in General Formula (ZI), and a suitable aspect thereof is also the same.

Furthermore, from the viewpoint of suppressing an acid generated upon exposure from diffusing to an unexposed area and further improving the resolution, the photoacid generator is preferably a compound that generates an acid in size with a volume of 130 Å³ or more, and more preferably a compound that generates an acid in size with a volume of 150 Å³ or more, upon irradiation with electron beams or extreme ultraviolet rays. Further, it should be noted that from the viewpoint of the sensitivity or the solubility in the coating solvent, the volume is preferably 2,000 Å³ or less, and more preferably 1,500 Å³ or less.

1 Å is 1×10⁻¹⁰ m.

In the present specification, the volume value of an acid generated from the photoacid generator is a value calculated by the following method.

The structure of the generated acid is optimized by a parameterized model number 3 (PM3) method using MOPAC7 enclosed with Winmostar (software manufactured by X-Ability Co., Ltd.). A Van der Waals volume is calculated for the obtained optimized structure by the method described in Non-Patent Document 1, using Winmostar (software manufactured by X-Ability Co., Ltd.).

Non-Patent Document 1: Improvement of molecular surface area and volume calculation program, Teruo Nagao, Bulletin of Hakodate National College of Technology, No. 27, p 111-120, 1993).

With regard to the photoacid generator, reference can be made to paragraphs [0368] to [0377] of JP2014-041328A and paragraphs [0240] to [0262] of JP2013-228681A (corresponding to paragraph [0339] of the specification of US2015/0004533A), the contents of which are incorporated herein by reference.

The photoacid generators may be used singly or in combination of two or more kinds thereof.

The content of the photoacid generator (in a case where the photoacid generators are present in a plural number, a total content thereof) in the composition is preferably 0.1% to 50.0% by mass, more preferably 5.0% to 40.0% by mass, and still more preferably 5.0% to 35.0% by mass with respect to a total solid content of the composition.

<Acid Diffusion Control Agent>

The composition preferably includes an acid diffusion control agent. The acid diffusion control agent acts as a quencher that suppresses a reaction of the acid-decomposable resin in the unexposed area by excessive generated acids by trapping the acids generated from a photoacid generator and the like upon exposure. For example, a basic compound (DA), a compound (DB) having basicity that is reduced or lost upon irradiation with actinic rays or radiation, an onium salt (DC) which is a relatively weak acid with respect to an acid generator, or the like can be used as the acid diffusion control agent.

As the basic compound (DA), compounds having structures represented by Formulae (A) to (E) are preferable.

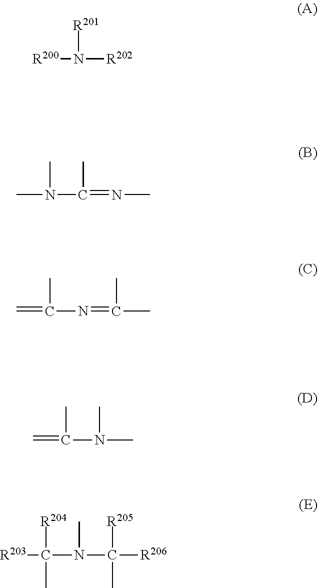

In General Formulae (A) and (E), R²⁰⁰, R²⁰¹, and R²⁰² each independently represent a hydrogen atom, an alkyl group (preferably having 1 to 20 carbon atoms), a cycloalkyl group (preferably having 3 to 20 carbon atoms), or an aryl group (preferably having 6 to 20 carbon atoms). R²⁰¹ and R²⁰² may be bonded to each other to form a ring.

In General Formula (E), R²⁰³, R²⁰⁴, R²⁰⁵, and R²⁰⁶ each independently represent an alkyl group having 1 to 20 carbon atoms.

The alkyl group in each of General Formulae (A) and (E) may have a substituent or may be unsubstituted.

With regard to the alkyl group, the alkyl group having a substituent is preferably an aminoalkyl group having 1 to 20 carbon atoms, a hydroxyalkyl group having 1 to 20 carbon atoms, or a cyanoalkyl group having 1 to 20 carbon atoms.

The alkyl group in each of General Formulae (A) and (E) is more preferably unsubstituted.

As the basic compound (DA), guanidine, aminopyrrolidine, pyrazole, pyrazoline, piperazine, aminomorpholine, aminoalkylmorpholine, piperidine, or the like is preferable; and

a compound having an imidazole structure, a diazabicyclo structure, an onium hydroxide structure, an onium carboxylate structure, a trialkylamine structure, an aniline structure, or a pyridine structure, an alkylamine derivative having a hydroxyl group and/or an ether bond, and an aniline derivative having a hydroxyl group and/or an ether bond, or the like is more preferable.

Moreover, a superorganic base can also be used as the basic compound (DA).

Examples of the superorganic base include guanidine base compounds such as tetramethylguanidine and polyguanidine (including guanidine and guanidine derivatives such as a substituted form of guanidine and a polyguanide compound), amidine-based and guanidine-based polynitrogen polyheterocyclic compounds and polymer-carrying strong base compounds thereof, typified by diazabicyclononene (DBN), diazabicycloundecene (DBU), triazabicyclodecene (TBD), N-methyl-triazabicyclodecene (MTBD), and the like, phosphazene-based (Schweisinger) base compounds, and proazaphosphatran (Verkade) base compounds.

Moreover, as the basic compound (DA), an amine compound and an ammonium salt compound can also be used.

Examples of the amine compound include primary, secondary, and tertiary amine compounds, and the amine compound is preferably an amine compound in which at least one or more alkyl groups (preferably having 1 to 20 carbon atoms) are bonded to nitrogen atoms, and more preferably the tertiary amine compound among those.

Furthermore, in a case where the amine compound is the secondary or tertiary amine compound, examples of a group bonded to the nitrogen atom in the amine compound include, in addition to the above-described alkyl groups, a cycloalkyl group (preferably having 3 to 20 carbon atoms) and an aryl group (preferably having 6 to 12 carbon atoms).

Examples of the ammonium salt compound include primary, secondary, tertiary, and quaternary ammonium salt compounds, and an ammonium salt compound in which one or more alkyl groups are bonded to a nitrogen atom is preferable.

Furthermore, in a case where the ammonium salt compound is a secondary, tertiary, or quaternary ammonium salt compound, examples of a group which is bonded to a nitrogen atom in the ammonium salt compound include, in addition to the above-described alkyl groups, a cycloalkyl group (preferably having 3 to 20 carbon atoms) and an aryl group (preferably having 6 to 12 carbon atoms).

Examples of the anion of the ammonium salt compound include a halogen atom, a sulfonate, a borate, and a phosphate, and among these, the halogen atom or the sulfonate is preferable.

As the halogen atom, a chlorine atom, a bromine atom, or an iodine atom is preferable.

As the sulfonate, an organic sulfonate having 1 to 20 carbon atoms is preferable. Examples of the organic sulfonate having 1 to 20 carbon atoms include alkyl sulfonate and aryl sulfonate, having 1 to 20 carbon atoms.

Moreover, as the basic compound (DA), an amine compound having a phenoxy group and an ammonium salt compound having a phenoxy group can also be used.

The amine compound having a phenoxy group and the ammonium salt compound having a phenoxy group are each a compound having a phenoxy group at the terminal on the opposite side to the nitrogen atom of the alkyl group which is contained in the amine compound or the ammonium salt compound.

The compound (DB) having basicity that is reduced or lost upon irradiation with actinic rays or radiation (hereinafter also referred to as a “compound (DB)”) is a compound which has a proton-accepting functional group, and decomposes under irradiation with actinic rays or radiation to exhibit deterioration in proton-accepting properties, no proton-accepting properties, or a change from the proton-accepting properties to acidic properties.

The proton-accepting functional group refers to a functional group having a group or an electron which is capable of electrostatically interacting with a proton, and for example, means a functional group with a macrocyclic structure, such as a cyclic polyether, or a functional group having a nitrogen atom having an unshared electron pair not contributing to π-conjugation. The nitrogen atom having an unshared electron pair not contributing to π-conjugation is, for example, a nitrogen atom having a partial structure represented by General Formula.

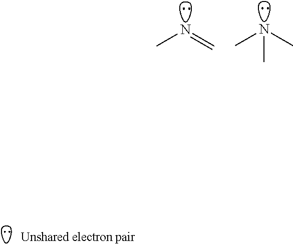

As the partial structure of the proton-accepting functional group, a crown ether structure, an azacrown ether structure, primary to tertiary amine structures, a pyridine structure, an imidazole structure, or a pyrazine structure is preferable.

The compound (DB) decomposes upon irradiation with actinic rays or radiation to generate a compound exhibiting deterioration in proton-accepting properties, no proton-accepting properties, or a change from the proton-accepting properties to acidic properties. Here, exhibiting deterioration in proton-accepting properties, no proton-accepting properties, or a change from the proton-accepting properties to acidic properties means a change of proton-accepting properties due to the proton being added to the proton-accepting functional group, and specifically a decrease in the equilibrium constant at chemical equilibrium in a case where a proton adduct is generated from the compound (DB) having the proton-accepting functional group and the proton.

The proton-accepting properties can be confirmed by performing pH measurement.

With regard to specific examples of the compound (DB), reference can be made to those described in paragraphs [0421] to [0428] of JP2014-041328A or paragraphs [0108] to [0116] of JP2014-134686A, the contents of which are incorporated herein by reference.

As the onium salt (DC) which is a weak acid relative to the acid generator, compounds represented by General Formulae (d1-1) to (d1-3) are preferable.

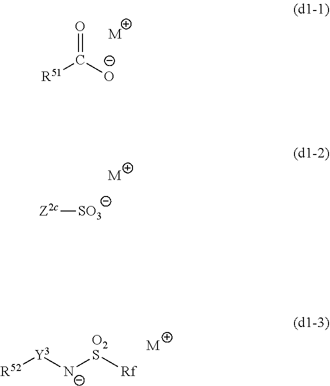

In the formula, R⁵¹ is a hydrocarbon group which may have a substituent, Z^{2c} is a hydrocarbon group having 1 to 30 carbon atoms, which may have a substituent (provided that carbon adjacent to S is not substituted with a fluorine atom), R⁵² is an organic group, Y³ is a linear, branched or cyclic alkylene group or an arylene group, Rf is a hydrocarbon group including a fluorine atom, and M⁺'s are each independently an ammonium cation, a sulfonium cation, or an iodonium cation.

R⁵¹ is preferably an aryl group which may have a substituent, more preferably an aryl group which has a substituent having a fluorine atom (a fluoroalkyl group such as a trifluoromethyl group), and still more preferably a phenyl group which has a substituent having a fluorine atom. The number of fluorine atoms contained in R⁵¹ is preferably 1 to 12, and more preferably 3 to 9.

As the sulfonium cation or the iodonium cation represented by M⁺, the sulfonium cation in General Formula (ZI) and the iodonium cation in General Formula (ZII) are preferable.

Specific examples of an acid diffusion aid are shown below, but the present invention is not limited thereto.

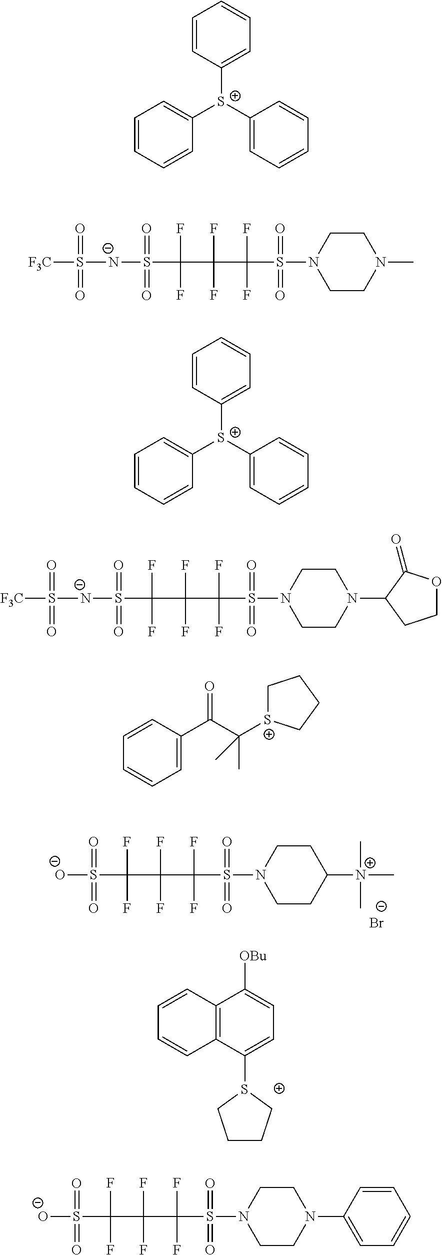

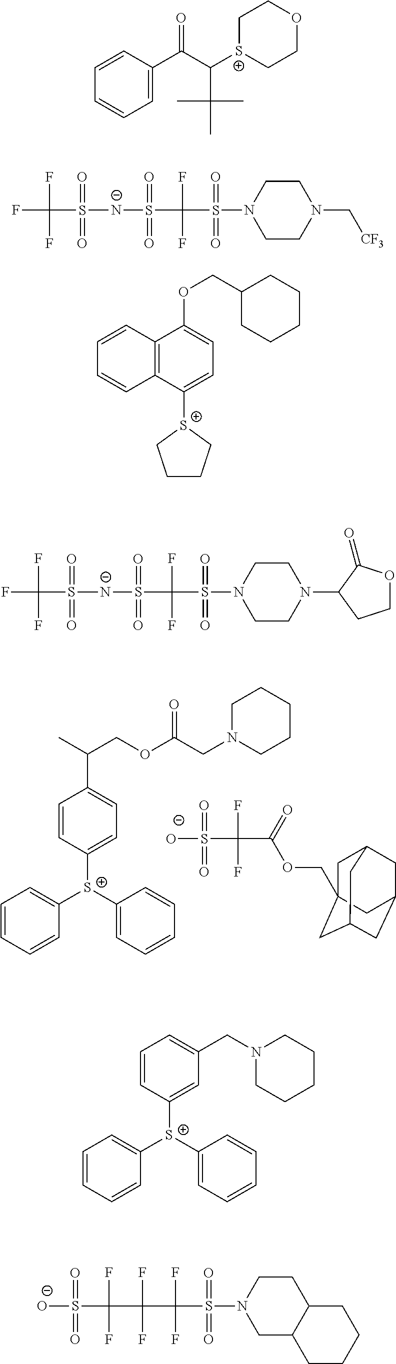

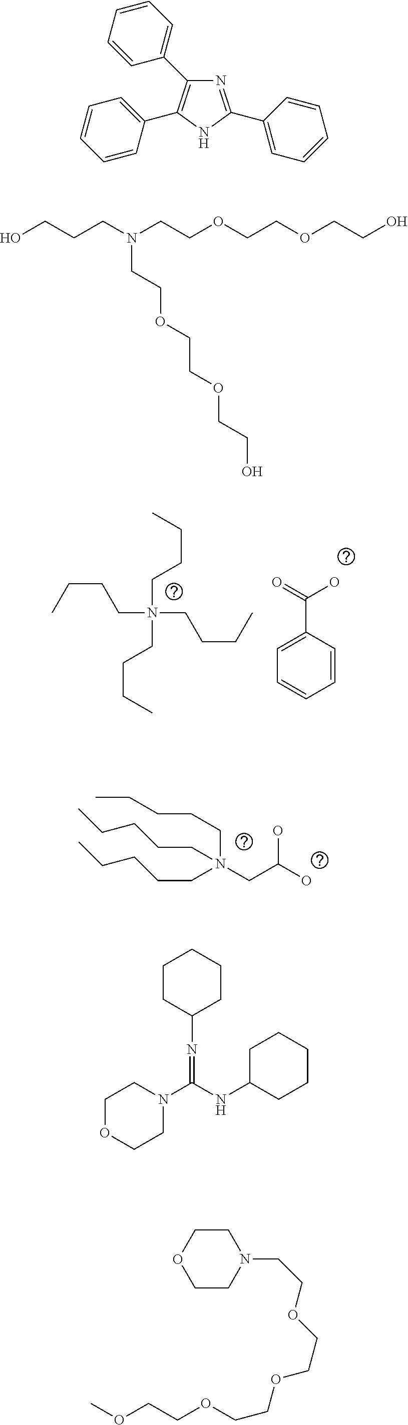

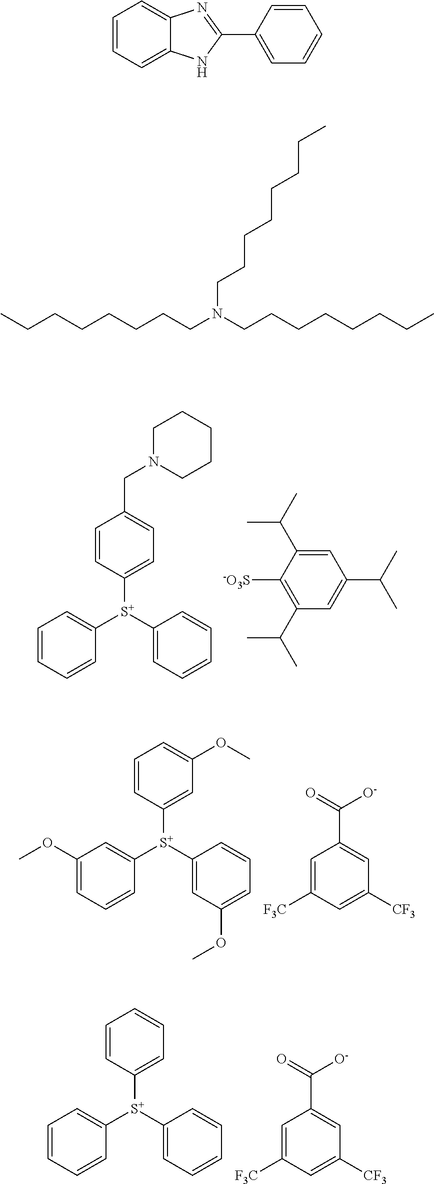

The acid diffusion control agents may be used singly or in combination of two or more kinds thereof.

The content of the acid diffusion control agent (in a case where the acid diffusion control agents are present in a plural number, a total content thereof) in the composition is preferably 0.001% to 10% by mass, and more preferably 0.01% to 7.0% by mass with respect to the total solid content of the composition.

Moreover, as an acid diffusion control agent, for example, the compounds (amine compounds, amido group-containing compounds, urea compounds, nitrogen-containing heterocyclic compounds, and the like) described in paragraphs [0140] to [0144] of JP2013-011833A can also be used.

<Surfactant>

The composition may include a surfactant. By incorporating the surfactant into the composition, it is possible to provide a pattern having improved adhesiveness and less development defects with good sensitivity and resolution in a case where an exposure light source at a wavelength of 250 nm or less, and particularly 220 nm or less is used.

As the surfactant, fluorine-based and/or silicon-based surfactants are preferable.

Examples of the fluorine-based and/or silicon-based surfactants include the surfactants described in paragraph [0276] of the specification of US2008/0248425A. In addition, EFTOP EF301 and EF303 (manufactured by Shin-Akita Chemical Co., Ltd.); FLUORAD FC430, 431, and 4430 (manufactured by Sumitomo 3M Inc.); MEGAFACE F171, F173, F176, F189, F113, F110, F177, F120, and R08 (manufactured by DIC Corp.); SURFLON S-382, SC101, 102, 103, 104, 105, and 106 (manufactured by Asahi Glass Co., Ltd.), TROYSOL S-366 (manufactured by Troy Chemical Corp.); GF-300 and GF-150 (manufactured by Toagosei Chemical Industry Co., Ltd.); SURFLON 5-393 (manufactured by Seimi Chemical Co., Ltd.); EFTOP EF121, EF122A, EF122B, RF122C, EF125M, EF135M, EF351, EF352, EF801, EF802, and EF601 (manufactured by JEMCO Inc.); PF636, PF656, PF6320, and PF6520 (manufactured by OMNOVA Solutions Inc.); KH-20 (manufactured by Asahi Kasei Co., Ltd.); or FTX-204G, 208G, 218G, 230G, 204D, 208D, 212D, 218D, and 222D (manufactured by NEOS Co., Ltd.) may be used. In addition, a polysiloxane polymer KP-341 (manufactured by Shin-Etsu Chemical Co., Ltd.) can also be used as the silicon-based surfactant.

Moreover, in addition to the known surfactants as shown above, a surfactant may be synthesized using a fluoroaliphatic compound manufactured using a telomerization method (also referred to as a telomer method) or an oligomerization method (also referred to as an oligomer method). Specifically, a polymer including a fluoroaliphatic group derived from fluoroaliphatic compound may be used as the surfactant. This fluoroaliphatic compound can be synthesized, for example, by the method described in JP2002-090991A.

In addition, a surfactant other than the fluorine-based surfactant and/or the silicon-based surfactants described in paragraph [0280] of the specification of US2008/0248425A may be used.

These surfactants may be used singly or in combination of two or more kinds thereof.

The content of the surfactant in the composition is preferably 0.0001% to 2.0% by mass, and more preferably 0.0005% to 1.0% by mass with respect to the total solid content of the composition.

<Hydrophobic Resin>

The composition may include a hydrophobic resin. Further, the hydrophobic resin is a resin which is different from the resin (X).

In a case where the composition of the embodiment includes the hydrophobic resin, it is possible to control the static/dynamic contact angle on a surface of an actinic ray-sensitive or radiation-sensitive film. Thus, it is possible to improve development characteristics, suppress generation of out gas, improve immersion liquid followability upon liquid immersion exposure, and reduce liquid immersion defects, for example.

It is preferable that the hydrophobic resin is designed to be unevenly distributed on a surface of a resist film, but unlike the surfactant, the hydrophobic resin does not necessarily have a hydrophilic group in a molecule thereof and does not necessarily contribute to homogeneous mixing of polar/non-polar materials.

The hydrophobic resin is preferably a resin having a repeating unit having at least one selected from the group consisting of a “fluorine atom”, a “silicon atom”, or a “CH₃ partial structure which is included in a side chain portion of a resin” from the viewpoint of uneven distribution on a film surface layer.

In a case where the hydrophobic resin includes a fluorine atom and/or a silicon atom, the fluorine atom and/or the silicon atom described above in the hydrophobic resin may be included in the main chain of a resin or may be included in a side chain.

In a case where the hydrophobic resin includes a fluorine atom, it is preferably a resin which has an alkyl group having a fluorine atom, a cycloalkyl group having a fluorine atom, or an aryl group having a fluorine atom as a partial structure having a fluorine atom.

The hydrophobic resin preferably has at least one group selected from the following (x) to (z) groups:

(x) an acid group,

(y) a group having a solubility in an alkali developer that increases through decomposition by an action of an alkali developer (hereinafter also referred to as a polarity conversion group), and

(z) a group that decomposes by an action of an acid.

Examples of the acid group (x) include a phenolic hydroxyl group, a carboxylic acid group, a fluorinated alcohol group, a sulfonic acid group, a sulfonamido group, a sulfonylimido group, an (alkylsulfonyl)(alkylcarbonyl)methylene group, an (alkylsulfonyl)(alkylcarbonyl)imido group, a bis(alkylcarbonyl)methylene group, a bis(alkylcarbonyl)imido group, a bis(alkylsulfonyl)methylene group, a bis(alkylsulfonyl)imido group, a tris(alkylcarbonyl)methylene group, and a tris(alkylsulfonyl)methylene group.

As the acid group (x), the fluorinated alcohol group (preferably hexafluoroisopropanol group), the sulfonimido group, or the bis(alkylcarbonyl)methylene group is preferable.

Examples of the polarity conversion group (y) include a lactone group, a carboxylic ester group (—COO—), an acid anhydride group (—C(O)OC(O)—), an acid imido group (—NHCONH—), a carboxylic thioester group (—COS—), a carbonic ester group (—OC(O)O—), a sulfuric ester group (—OSO₂O—), and a sulfonic ester group (—SO₂O—), and the lactone group or the carboxylic ester group (—COO—) is preferable.

The repeating unit including such the group is, for example, a repeating unit in which the group is directly bonded to the main chain of a resin, and examples thereof include a repeating unit with an acrylic ester or a methacrylic ester. In this repeating unit, such the group may be bonded to the main chain of the resin via a linking group. Alternatively, this repeating unit may also be incorporated into a terminal of the resin by using a polymerization initiator or a chain transfer agent having such the group during polymerization.

Examples of the repeating unit having a lactone group include the same ones as those of the repeating unit having a lactone structure described earlier in the section of the resin (X).

The content of the repeating unit having the polarity conversion group (y) is preferably 1% to 100% by mole, more preferably 3% to 98% by mole, and still more preferably 5% to 95% by mole with respect to all the repeating units in the hydrophobic resin.

Examples of the repeating unit having the group (z) that decomposes by an action of an acid in the hydrophobic resin include the same ones as the repeating units having an acid-decomposable group exemplified in the resin (X). The repeating unit having a group (z) that decomposes by an action of an acid may have at least any one of a fluorine atom or a silicon atom. The content of the repeating unit having a group (z) that decomposes by an action of an acid is preferably 1% to 80% by mole, more preferably 10% to 80% by mole, and still more preferably 20% to 60% by mole with respect to all the repeating units in the hydrophobic resin.

The hydrophobic resin may further have a repeating unit which is different from the above-mentioned repeating units.

The content of the repeating unit including a fluorine atom is preferably 10% to 100% by mole, and more preferably 30% to 100% by mole with respect to all the repeating units in the hydrophobic resin. Further, the content of the repeating units including a silicon atom is preferably 10% to 100% by mole, and more preferably 20% to 100% by mole with respect to all the repeating units in the hydrophobic resin.

On the other hand, in a case where the hydrophobic resin includes a CH₃ partial structure in the side chain portion thereof, a form in which the hydrophobic resin does not substantially include a fluorine atom and a silicon atom is preferable. Further, it is preferable that the hydrophobic resin is substantially constituted with only repeating units which are constituted with only atoms selected from a carbon atom, an oxygen atom, a hydrogen atom, a nitrogen atom, and a sulfur atom.

The weight-average molecular weight of the hydrophobic resin in terms of standard polystyrene is preferably 1,000 to 100,000, and more preferably 1,000 to 50,000.

A total content of the residual monomers and/or oligomer components included in the hydrophobic resin is preferably 0.01% to 5% by mass, and more preferably 0.01% to 3% by mass. In addition, the dispersity (Mw/Mn) is preferably in the range of 1 to 5, and more preferably in the range of 1 to 3.

As the hydrophobic resin, known resins can be appropriately selected and used singly or as a mixture. For example, the known resins disclosed in paragraphs [0451] to [0704] of the specification of US2015/0168830A1 and paragraphs [0340] to [0356] of the specification of US2016/0274458A1 can be suitably used as the hydrophobic resin (E). Further, the repeating units disclosed in paragraphs [0177] to [0258] of the specification of US2016/0237190A1 are also preferable as a repeating unit constituting the hydrophobic resin (E).

The hydrophobic resin may be used singly or in combination of two or more kinds thereof.

It is preferable to use a mixture of two or more kinds of hydrophobic resins having different levels of surface energy from the viewpoint of satisfying both the immersion liquid followability and the development characteristics upon liquid immersion exposure.

The content of the hydrophobic resin in the composition (in a case where the hydrophobic resins are present in a plural number, a total content thereof) is preferably 0.01% to 10.0% by mass, and more preferably 0.05% to 8.0% by mass with respect to the total solid content in the composition.

<Solvent>

The composition may include a solvent.

It is preferable that the solvent includes at least any one of the following component (M1) or the following component (M2), and it is more preferable that the solvent includes the following component (M1).

In a case where the solvent includes the following component (M1), it is preferable that the solvent consists of substantially only the component (M1) or is a mixed solvent including at least the component (M1) and the component (M2).

Hereinafter, the component (M1) and the component (M2) will be shown.

Component (M1): Propylene glycol monoalkyl ether carboxylate

Component (M2): A solvent selected from the following component (M2-1) or a solvent selected from the following component (M2-2)
Component (M2-1): Propylene glycol monoalkyl ether, lactic ester, acetic ester, butyl butyrate, alkoxy propionic ester, chained ketone, cyclic ketone, lactone, or alkylene carbonate
Component (M2-2): Another solvent having a flash point (also referred to as fp) of 37° C. or higher.

In a case where the solvent and the above-described resin (X) are used in combination, the coating property of the composition is improved and a pattern having a less number of development defects can be obtained. Although a reason therefor is not necessarily clear, it is considered that the solvent has a good balance among the solubility, the boiling point, and the viscosity of the above-described resin (X), and therefore, unevenness in the film thickness of a resist film, generation of precipitates during spin coating, and the like can be suppressed.

As the component (M1), at least one selected from the group consisting of propylene glycol monomethyl ether acetate (PGMEA), propylene glycol monomethyl ether propionate, and propylene glycol monoethyl ether acetate is preferable, and the propylene glycol monomethyl ether acetate (PGMEA) is more preferable.

As the component (M2-1), the following ones are preferable.

As the propylene glycol monoalkyl ether, propylene glycol monomethyl ether (PGME) or propylene glycol monoethyl ether is preferable.

As the lactic ester, ethyl lactate, butyl lactate, or propyl lactate is preferable.

As the acetic ester, methyl acetate, ethyl acetate, butyl acetate, isobutyl acetate, propyl acetate, isoamyl acetate, methyl formate, ethyl formate, butyl formate, propyl formate, or 3-methoxybutyl acetate is preferable.

As the alkoxy propionic ester, methyl 3-methoxypropionate (MMP) or ethyl 3-ethoxypropionate (EEP) is preferable.

As the chained ketone, 1-octanone, 2-octanone, 1-nonanone, 2-nonanone, acetone, 2-heptanone, 4-heptanone, 1-hexanone, 2-hexanone, diisobutyl ketone, phenyl acetone, methyl ethyl ketone, methyl isobutyl ketone, acetyl acetone, acetonyl acetone, ionone, diacetonyl alcohol, acetyl carbinol, acetophenone, methyl naphthyl ketone, or methyl amyl ketone is preferable.

As the cyclic ketone, methyl cyclohexanone, isophorone, or cyclohexanone is preferable.

As the lactone, γ-butyrolactone is preferable.

As the alkylene carbonate, propylene carbonate is preferable.

As the component (M2-1), PGME, ethyl lactate, ethyl 3-ethoxypropionate, methyl amyl ketone, cyclohexanone, butyl acetate, pentyl acetate, γ-butyrolactone, or propylene carbonate is more preferable.

Specific examples of the component (M2-2) include PGME (fp: 47° C.), ethyl lactate (fp: 53° C.), ethyl 3-ethoxypropionate (fp: 49° C.), methyl amyl ketone (fp: 42° C.), cyclohexanone (fp: 44° C.), pentyl acetate (fp: 45° C.), methyl 2-hydroxyisobutyrate (fp: 45° C.), γ-butyrolactone (fp: 101° C.), and propylene carbonate (fp: 132° C.). Among those, PGME, ethyl lactate, pentyl acetate, or cyclohexanone is preferable, and PGME or cyclohexanone is more preferable.

In addition, the “flash point” herein means the value described in a reagent catalog of Tokyo Chemical Industry Co., Ltd. or Sigma-Aldrich Co. LLC.

The mixing ratio (mass ratio: M1/M2) of the component (M1) to the component (M2) is preferably 100/0 to 15/85, more preferably in the range of 100/0 to 40/60, and still more preferably in the range of 100/0 to 60/40, from the viewpoint that the number of development defects is further decreased.

Moreover, the solvent may include solvents other than the component (M1) and the component (M2). In this case, the content of the solvents other than the components (M1) and (M2) is preferably 5% to 30% by mass with respect to the total mass of the solvent.

Examples of such other solvents include ester-based solvents having 7 or more carbon atoms (preferably 7 to 14 carbon atoms, more preferably 7 to 12 carbon atoms, and still more preferably 7 to 10 carbon atoms) and 2 or less heteroatoms. Furthermore, the ester-based solvents having 7 or more carbon atoms and 2 or less heteroatoms do not include solvents corresponding to the above-described component (M2).

As the ester-based solvents having 7 or more carbon atoms and 2 or less heteroatoms, amyl acetate, 2-methylbutyl acetate, 1-methylbutyl acetate, hexyl acetate, pentyl propionate, hexyl propionate, butyl propionate, isobutyl isobutyrate, heptyl propionate, or butyl butanoate is preferable, and isoamyl acetate is more preferable.

<Other Additives>

The composition may further include a dissolution inhibiting compound (a compound whose solubility in an organic developer decreases through decomposition by an action of an acid, with a molecular weight thereof being preferably 3,000 or less), a dye, a plasticizer, a light sensitizer, a light absorber, and/or a compound that accelerates dissolution in a developer (for example, a phenol compound having a molecular weight of 1,000 or less, or an alicyclic or aliphatic compound including a carboxyl group).

<Method for Preparing Composition>

The concentration of the solid content in the composition is preferably 0.5% to 30% by mass, more preferably 1.0% to 20.0% by mass, and still more preferably 1.0% to 10.0% by mass from the viewpoint that the coating property is more excellent. The concentration of the solid content is a mass percentage of other resist components excluding the solvent with respect to the total mass of the composition.

Furthermore, the film thickness of the resist film consisting of the composition is generally 200 nm or less, and preferably 100 nm or less from the viewpoint of improving the resolving power. For example, it is preferable that the film thickness of a resist film to be formed is 90 nm or less in order to resolve a 1:1 line-and-space pattern with a line width of 20 nm or less. In a case where the film thickness is 90 nm or less, more excellent resolution performance is obtained due to suppressed pattern collapse upon application of a developing step which will be described later.

In a case of exposure with EUV or EB, the range of the film thickness is preferably 15 to 60 nm. Such a film thickness can be obtained by setting the concentration of the solid content in the composition to an appropriate range to provide the composition with a suitable viscosity and improve the coating property or the film forming property.

The composition is preferably used by dissolving the components in a predetermined organic solvent, and preferably the mixed solvent, and filtering the solution through a filter and applying it onto a predetermined support (substrate). The pore size of a filter for use in filtration through the filter is preferably pore size of 0.1 μm or less, more preferably 0.05 μm or less, and still more preferably 0.03 μm or less. The filter is preferably a polytetrafluoroethylene-made, polyethylene-made, or nylon-made filter. In the filtration through a filter as shown in the specification of JP2002-062667A, circulating filtration may be performed or the filtration may be performed by connecting plural kinds of filters in series or in parallel. In addition, the composition may be filtered in plural times. Furthermore, the composition may be subjected to a deaeration treatment or the like before or after filtration through a filter.

<Uses>

The composition relates to an actinic ray-sensitive or radiation-sensitive resin composition having a property that changes by undergoing a reaction upon irradiation with actinic rays or radiation. More specifically, the composition relates to an actinic ray-sensitive or radiation-sensitive resin composition which is used in a step of manufacturing a semiconductor such as an integrated circuit (IC), for manufacture of a circuit board for a liquid crystal, a thermal head, or the like, the manufacture of a mold structure for imprinting, other photofabrication steps, or production of a planographic printing plate or an acid-curable composition. A pattern formed in the present invention can be used in an etching step, an ion implantation step, a bump electrode forming step, a rewiring forming step, microelectromechanical systems (MEMS), or the like.

As described above, the composition can be suitably used for EUV lithography since the sensitivity of a resist film to be formed to EUV and the LER and the collapse performance of a pattern to be formed are further improved.

In addition, from the viewpoint that the composition may be used for lithography with actinic rays and radiation other than EUV, and the sensitivity of a resist film to be formed, and the LER and the collapse performance of a pattern to be formed are further improved, the composition can also be suitably used for lithography by irradiation with ArF and EB.

[Pattern Forming Method]

The present invention also relates to a pattern forming method using the above-mentioned composition. Hereinafter, the pattern forming method will be described. In addition, the resist film will also be described, together with the pattern forming method.

The pattern forming method includes:

(i) a resist film forming step of forming a resist film (actinic ray-sensitive or radiation-sensitive film) on a support with the above-described composition,

(ii) an exposing step of exposing the resist film (irradiating the resist film with actinic rays or radiation, and

(iii) a developing step of developing the exposed resist film with a developer.

The pattern forming method is not particularly limited as long as it includes the steps (i) to (iii), and may further include the following steps.

In the pattern forming method, the exposing method in the exposing step (ii) may be liquid immersion exposure.

The pattern forming method preferably includes a prebaking (PB) step (iv) before the exposing step (ii).

The pattern forming method preferably includes a post-exposure baking (PEB) step (v) after the exposing step (ii) and before the developing step (iii).

The pattern forming method may include the exposing step (ii) a plurality of times.

The pattern forming method may include the prebaking step (iv) a plurality of times.

The pattern forming method may include the post-exposure baking step (v) a plurality of times.

In the pattern forming method, the resist film forming step (i), the exposing step (ii), and the developing step (iii) as mentioned above can be performed by a generally known method.

In addition, a resist underlayer film (for example, spin on glass (SOG), spin on carbon (SOC), and an antireflection film) may be formed between the resist film and the support, as desired. As a material constituting the resist underlayer film, known organic or inorganic materials can be appropriately used.

A protective film (topcoat) may be formed on the upper layer of the resist film. As the protective film, a known material can be appropriately used. For example, the compositions for forming a protective film disclosed in the specification of US2007/0178407A, the specification of US2008/0085466A, the specification of US2007/0275326A, the specification of US2016/0299432A, the specification of US2013/0244438A, or the specification of WO2016/157988 can be suitably used. The composition for forming a protective film preferably includes the above-mentioned acid diffusion control agent.

The film thickness of the protective film is preferably 10 to 200 nm, more preferably 20 to 100 nm, and still more preferably 40 to 80 nm.

The support is not particularly limited, and a substrate which is generally used in a step of manufacturing a semiconductor such as an IC, and a step for manufacturing a circuit board for a liquid crystal, a thermal head, or the like, and other lithographic steps of photofabrication can be used. Specific examples of the support include an inorganic substrate such as silicon, SiO₂, and SiN.

For any of the prebaking step (iv) and the post-exposure baking step (v), the baking temperature is preferably 80° C. to 150° C., more preferably 80° C. to 140° C., and still more preferably 80° C. to 130° C.

For any of the prebaking step (iv) and the post-exposure baking step (v), the baking time is preferably 30 to 1,000 seconds, more preferably 60 to 800 seconds, and still more preferably 60 to 600 seconds.

The baking may be performed using a unit included in an exposing device and a developing device, or may also be performed using a hot plate or the like.

A light source wavelength used in the exposing step (ii) is not limited, and examples thereof include infrared rays, visible light, ultraviolet rays, far ultraviolet rays, extreme ultraviolet rays (EUV), X-rays, and electron beams (EB). Among those, the far ultraviolet rays are preferable. The light source wavelength is preferably 250 nm or less, more preferably 220 nm or less, and still more preferably 1 to 200 nm. Specific examples thereof include a KrF excimer laser (248 rnm), an ArF excimer laser (193 nm), an F2 excimer laser (157 nm), X-rays, EUV (13 nm), and EB, the KrF excimer laser, the ArF excimer laser, EUV, or the EB is preferable, and EUV is more preferable.

In the developing step (iii), the developer may be either an alkali developer or a developer including an organic solvent (hereinafter also referred to as an organic developer).

As an alkali component included in the alkali developer, a quaternary ammonium salt typified by tetramethylammonium hydroxide is usually used. In addition, an aqueous alkali solution including an alkali component such as an inorganic alkali, primary to tertiary amines, alcohol amines, and cyclic amines can also be used.

Furthermore, the alkali developer may include an appropriate amount of an alcohol and/or a surfactant. The alkali concentration of the alkali developer is usually 0.1% to 20% by mass. The pH of the alkali developer is usually 10 to 15.

A time period for performing development the using the alkali developer is usually 10 to 300 seconds.

The alkali concentration, the pH, and the development time using the alkali developer can be appropriately adjusted depending on a pattern to be formed.

The organic developer is preferably a developer including at least one organic solvent selected from the group consisting of a ketone-based solvent, an ester-based solvent, an alcohol-based solvent, an amide-based solvent, an ether-based solvent, and a hydrocarbon-based solvent.

Examples of the ketone-based solvent include 1-octanone, 2-octanone, 1-nonanone, 2-nonanone, acetone, 2-heptanone (methyl amyl ketone), 4-heptanone, 1-hexanone, 2-hexanone, diisobutyl ketone, cyclohexanone, methylcyclohexanone, phenyl acetone, methyl ethyl ketone, methyl isobutyl ketone, acetyl acetone, acetonyl acetone, ionone, diacetonyl alcohol, acetyl carbinol, acetophenone, methyl naphthyl ketone, isophorone, and propylene carbonate.

Examples of the ester-based solvent include methyl acetate, butyl acetate, ethyl acetate, isopropyl acetate, pentyl acetate, isopentyl acetate, amyl acetate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, methyl formate, ethyl formate, butyl formate, propyl formate, ethyl lactate, butyl lactate, propyl lactate, butyl butanoate, methyl 2-hydroxyisobutyrate, isoamyl acetate, isobutyl isobutyrate, and butyl propionate.

As the alcohol-based solvent, the amide-based solvent, the ether-based solvent, and the hydrocarbon-based solvent, the solvents disclosed in paragraphs [0715] to [0718] of the specification of US2016/0070167A can be used.

A plurality of the solvents may be mixed or the solvent may be used in admixture with a solvent other than those described above or water. The moisture content in the entire developer is preferably less than 50% by mass, more preferably less than 20% by mass, and still more preferably less than 10% by mass, and particularly preferably, moisture is not substantially included.

The content of the organic solvent with respect to the organic developer is preferably 50% to 100% by mass, more preferably 80% to 100% by mass, still more preferably 90% to 100% by mass, and particularly preferably 95% to 100% by mass with respect to the total amount of the developer.

The organic developer may include an appropriate amount of a known surfactant, as desired.

The content of the surfactant is usually 0.001% to 5% by mass, preferably 0.005% to 2% by mass, and still more preferably 0.01% to 0.5% by mass with respect to the total amount of the developer.

In addition, the organic developer may include the above-mentioned acid diffusion control agent.

Examples of the developing method include a method in which a substrate is dipped in a tank filled with a developer for a certain period of time (a dip method), a method in which development is performed by heaping a developer up onto the surface of a substrate by surface tension, and then leaving it to stand for a certain period of time (a puddle method), a method in which a developer is sprayed on the surface of a substrate (a spray method), and a method in which a developer is continuously jetted onto a substrate spun at a constant rate while scanning a developer jetting nozzle at a constant rate (a dynamic dispense method).

A combination of a step of performing development using an aqueous alkali solution (an alkali developing step) and a step of performing development using a developer including an organic solvent (an organic solvent developing step) may be used. Thus, a finer pattern can be formed since a pattern can be formed by keeping only a region with an intermediate exposure intensity from not being dissolved.

It is preferable that the pattern forming method includes a step of performing washing using a rinsing liquid (a rinsing step) after the developing step (iii).

As the rinsing liquid used in the rinsing step after the developing step with an alkali developer, for example, pure water can be used. The pure water may include an appropriate amount of a surfactant. In this case, after the developing step or the rinsing step, a treatment for removing the developer or the rinsing liquid adhering on a pattern by a supercritical fluid may be added. In addition, after the rinsing step or the treatment using a supercritical fluid, a heating treatment for removing moisture remaining in the pattern may be performed.

The rinsing liquid used in the rinsing step after the developing step with a developer including an organic solvent is not particularly limited as long as the rinsing liquid does not dissolve the pattern, and a solution including a common organic solvent can be used. As the rinsing liquid, a rinsing liquid including at least one organic solvent selected from the group consisting of a hydrocarbon-based solvent, a ketone-based solvent, an ester-based solvent, an alcohol-based solvent, an amide-based solvent, and an ether-based solvent is preferable, and the rinsing liquid including the ester-based solvent or a monohydric alcohol is more preferable.

Specific examples of the hydrocarbon-based solvent, the ketone-based solvent, the ester-based solvent, the alcohol-based solvent, the amide-based solvent, and the ether-based solvent include the same solvents as those described for the developer including an organic solvent.

For the rinsing liquid in the case, a mixture of a plurality of the components may be used or an organic solvent other than those may be mixed therewith and used.

The moisture content in the rinsing liquid in the case is preferably 10% by mass or less, more preferably 5% by mass or less, and still more preferably 3% by mass or less. By setting the moisture content to 10% by mass or less, good development characteristics are obtained.

The rinsing liquid may include an appropriate amount of a surfactant.

In the rinsing step, the developed substrate is subjected to a washing treatment using the rinsing liquid. A method for the washing treatment is not particularly limited, but examples thereof include a method in which a rinsing liquid is continuously jetted on a substrate rotated at a constant rate (a rotation application method), and the dip method, the puddle method, and the spray method, each described above in the developing method.

It is preferable to rotate the substrate at a rotation speed of 2,000 to 4,000 rpm after the rinsing step, thereby removing the rinsing liquid from the substrate. Furthermore, it is also preferable that the method includes a baking step after the rinsing step. The developer and the rinsing liquid remaining between and inside the patterns are removed by the baking step. In the baking step after the rinsing step, the baking temperature is usually 40° C. to 160° C., and preferably 70° C. to 95° C., and the baking time is usually 10 seconds to 3 minutes, and preferably 30 to 90 seconds.

It is preferable that various materials (for example, a resist solvent, a developer, a rinsing liquid, a composition for forming an antireflection film, and a composition for forming a topcoat) used in the composition and the pattern forming method include no impurities such as metal components, isomers, and residual monomers. The content of the impurities included in these materials is preferably 1 ppm or less, more preferably 100 ppt or less, and still more preferably 10 ppt or less, and particularly preferably, the impurities are not substantially included (no higher than a detection limit of a measurement device).

Examples of a method for removing impurities such as metals from the various materials include filtration using a filter. As for the filter pore diameter, the pore size is preferably 10 nm or less, more preferably 5 nm or less, and still more preferably 3 nm or less. As for the materials of a filter, a polytetrafluoroethylene-made, polyethylene-made, or nylon-made filter is preferable. As the filter, a filter which has been washed with an organic solvent in advance may be used. In the step of filtration using a filter, plural kinds of filters connected in series or in parallel may be used. In a case of using the plural kinds of filters, a combination of filters having different pore diameters and/or materials may be used. In addition, various materials may be filtered plural times, and the step of filtering plural times may be a circulatory filtration step. As the filter, a filter having a reduced amount of eluates as disclosed in the specification of JP2016-201426A is preferable.

In addition to the filtration using a filter, removal of impurities by an adsorbing material may be performed, or a combination of filtration using a filter and an adsorbing material may be used. As the adsorbing material, known adsorbing materials can be used, and for example, inorganic adsorbing materials such as silica gel and zeolite, and organic adsorbing materials such as activated carbon can be used. Examples of the metal adsorbing material include those disclosed in JP2016-206500A.

In addition, examples of a method for reducing the impurities such as metals included in various materials include a method in which a raw material having a low metal content is selected as a raw material constituting various materials and the raw material constituting the various materials is subjected to filtration using a filter; and a method in which distillation under conditions suppressing contamination as much as possible by performing a lining with TEFLON (registered trademark), or the like in the inside of a device is performed. Preferred conditions in the filtration using a filter to be performed on the raw material constituting the various materials are the same as the above-described conditions.

In order to prevent impurities from being incorporated, it is preferable that various materials are stored in the container described in the specification of US2015/0227049A, the specification of JP2015-123351A, or the like.

A method for improving the surface roughness of a pattern may be applied to a pattern formed by the pattern forming method. Examples of the method for improving the surface roughness of a pattern include the method of treating a pattern by plasma of a hydrogen-containing gas, as disclosed in the specification of US2015/0104957A. In addition, known methods as described in the specification of JP2004-235468A, the specification of US2010/0020297A, and Proc. of SPIE Vol. 8328 83280N-1 “EUV Resist Curing Technique for LWR Reduction and Etch Selectivity Enhancement” may be applied.

In addition, a pattern formed by the method can be used as a core material (core) of the spacer process disclosed in, for example, the specification of JP1991-270227A (JP-H03-270227A) and the specification of US2013/0209941A.

[Method for Manufacturing Electronic Device]

Moreover, the present invention further relates to a method for manufacturing an electronic device, the method including the above-described pattern forming method. The electronic device manufactured by the method for manufacturing an electronic device is suitably mounted on electric or electronic equipment (for example, home electronics, office automation (OA)-related equipment, media-related equipment, optical equipment, and telecommunication equipment).

### EXAMPLES

Hereinbelow, the present invention will be described in more detail with reference to Examples. The materials, the amounts of materials used, the proportions, the treatment details, the treatment procedure, and the like shown in the Examples below may be modified as appropriate as long as the modifications do not depart from the spirit of the present invention. Therefore, the scope of the present invention should not be construed as being limited to the Examples shown below.

[Synthesis of Resins]

Raw material monomers of the respective repeating units in resins P-1 to P-28 shown in Table 1 are shown below.

Moreover, among the compounds shown below, the monomers M-1 to M-1 correspond to the raw material monomers of the repeating unit (b).

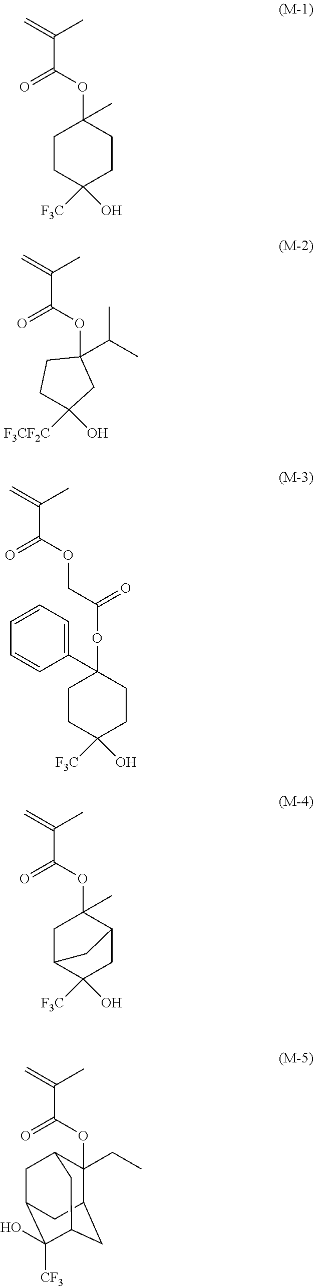

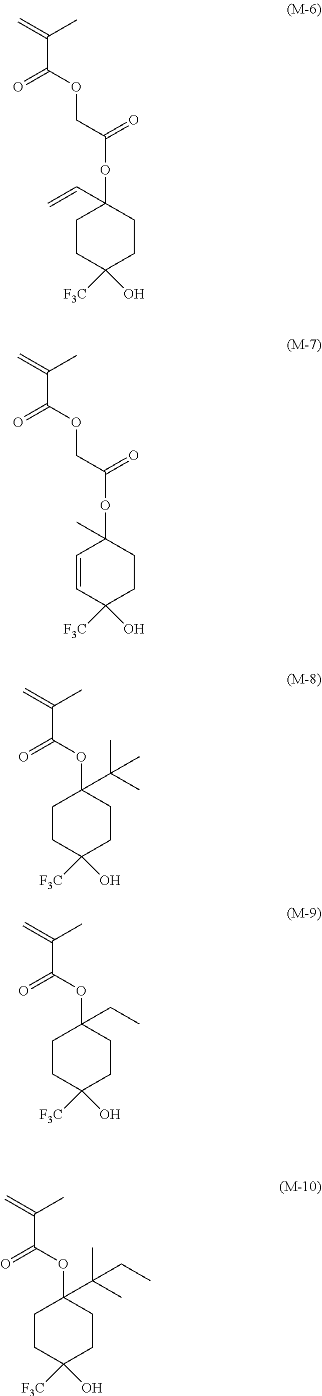

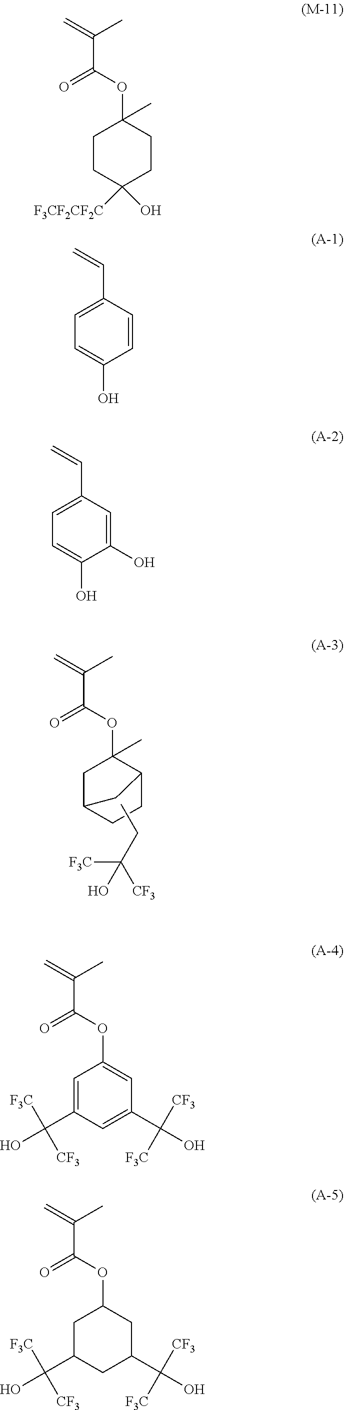

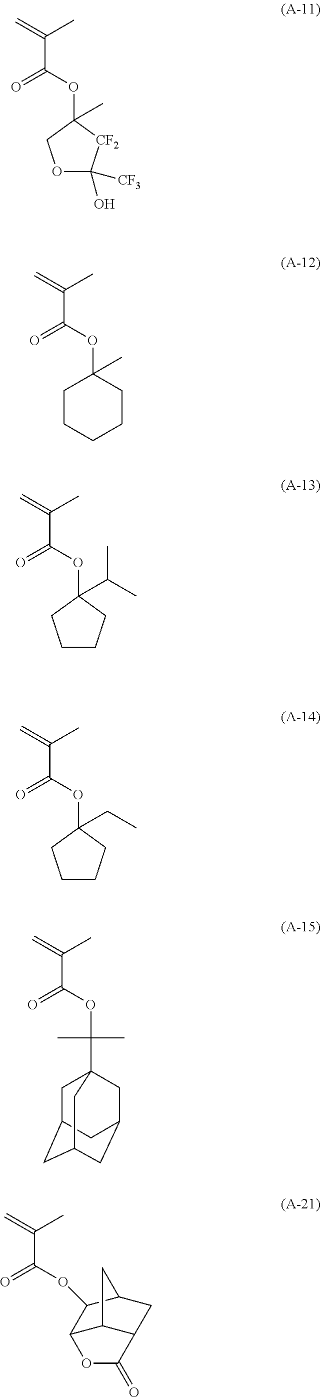

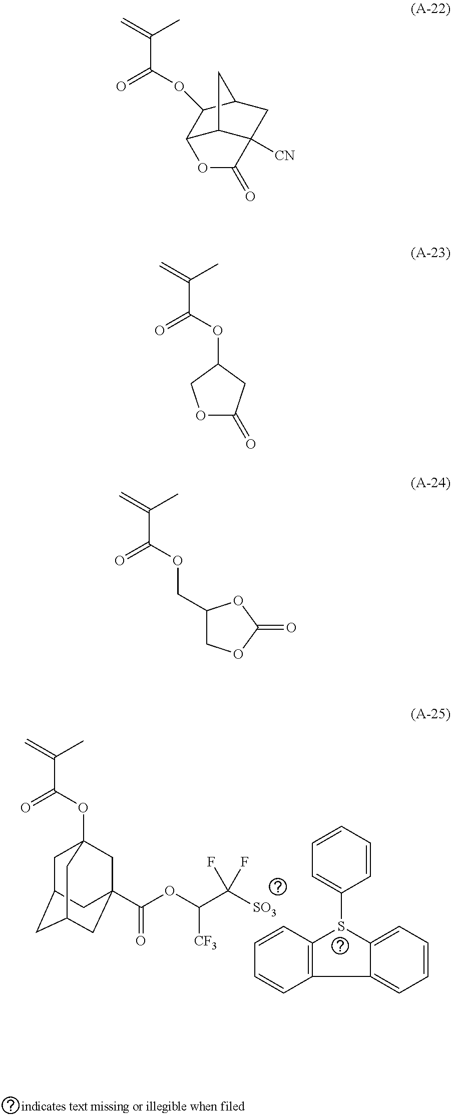

<Synthesis of Raw Material Monomer of Repeating Unit (b)>

Among the monomers used as raw materials for the repeating unit (b), examples of synthesizing monomers M-1 and M-2 are shown as an example.

(Synthesis Example 1: Synthesis of Monomer M-1)

A monomer M-1 was synthesized according to the following reaction formula.

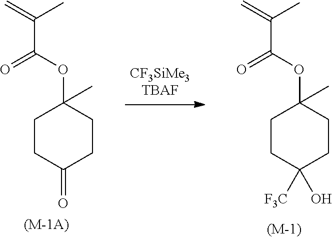

3.05 g of a compound represented by Formula (M-1A) and 40 mL of tetrahydrofuran were added to a flask. The obtained solution was cooled to a temperature in the flask of −10° C. 400 mg of tetrabutylammonium fluoride (TBAF) and 2.8 g of trimethyl(trifluoromethyl)silane were sequentially added thereto so that the temperature in the flask did not exceed 0° C. The reaction solution was stirred at −10° C. for 2 hours, 2.0 g of tetrabutylammonium fluoride was added thereto, and the mixture was stirred at room temperature for 1 hour. The reaction solution was added to 200 mL of pure water, and 100 mL of ethyl acetate was further added to carry out liquid separation extraction. The obtained organic layer was washed twice with 100 mL of saturated saline. The organic layer was concentrated under reduced pressure and purified by silica gel column chromatography to obtain 2.2 g of the monomer M-1 as a white crystal.

The results from identification of the obtained monomer M-1 by ¹H nuclear magnetic resonance (NMR) and ¹⁹F NMR (deuterated solvent for the both: DMSO-d₆) are shown below.

¹H NMR (DMSO-d₆): 5.95 (s, 1H), 5.85 (bs, 1H), 5.61 (s, 1H), 1.97 (t, 4H), 1.84 (s, 3H), 1.60-1.75 (m, 4H), 1.50 (s, 3H)

¹⁹F NMR (DMSO-d₆): −81.93 (s, 3F)

(Synthesis Example 2: Synthesis of Monomer M-9)

A monomer M-9 was synthesized according to the following reaction formula.

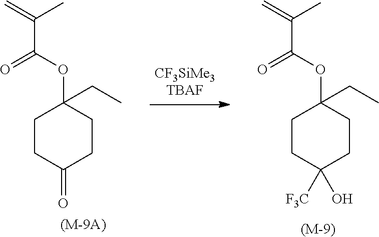

3.4 g of the compound represented by Formula (M-9A) and 40 mL of tetrahydrofuran were added to the flask. The obtained solution was cooled to a temperature in the flask of −10° C. 400 mg of tetrabutylammonium fluoride (TBAF) and 2.8 g of trimethyl(trifluoromethyl)silane were sequentially added thereto so that the temperature in the flask did not exceed 0° C. The reaction solution was stirred at −10° C. for 2 hours, 2.0 g of tetrabutylammonium fluoride was added thereto, and the mixture was stirred at room temperature for 1 hour. The reaction solution was added to 200 mL of pure water, and 100 mL of ethyl acetate was further added to carry out liquid separation extraction. The obtained organic layer was washed twice with 100 mL of saturated saline. The organic layer was concentrated under reduced pressure and purified by silica gel column chromatography to obtain 2.5 g of the monomer M-9 as a white crystal.

The results from identification of the obtained monomer M-2 by ¹H NMR and ¹⁹F NMR (deuterated solvent for the both: CDCl₃) are shown below.

¹H NMR (CDCl₃): 6.04 (s, 1H), 5.51 (s, 1H), 2.05-2.20 (m, 4H), 2.03 (q, 2H), 1.91 (s, 3H), 1.75-1.83 (m, 5H), 0.85 (t, 3H) ¹⁹F NMR (CDCl₃): −83.09 (s, 3F)

(Synthesis of Other Raw Material Monomers)

Monomers M-2 to M-8, M-10, M-11, A-1 to A-5, A-li to A-15, and A-21 to A-25 which are raw material monomers of the respective repeating units in the resins P-1 to P-28 were synthesized according to the methods of Synthesis Examples 1 and 2 or according to known methods.

The resins P-1 to P-28 shown in Table 1 were synthesized using the monomers. A method for synthesizing the resin P-1 is shown below as an example.

<Synthesis of Resin P-1>

16.7 g, 10.0 g, and 6.7 g of the monomers in the order from the left side, corresponding to the respective repeating units (A-1/M-1/A-21) of the resin P-1, and a polymerization initiator V-601 (manufactured by FUJIFILM Wako Pure Chemical Corporation) (4.61 g) were dissolved in cyclohexanone (54.6 g). A solution thus obtained was taken as a monomer solution.

The monomer solution was added dropwise to a reaction vessel in which cyclohexanone (23.4 g) had been placed under a nitrogen gas atmosphere for 4 hours. Further, the temperature inside the reaction vessel was adjusted to 85° C. during dropwise addition of the monomer solution. Subsequently, the obtained reaction solution was further stirred at 85° C. for 2 hours in the reaction vessel and then left to be cooled until the temperature reached room temperature.

The reaction solution after being left to be cooled was added dropwise to a mixed liquid of methanol and water (methanol/water=7/3 (mass ratio)) over 20 minutes, and the precipitated powder was collected by filtration. The obtained powder was dried to obtain the resin P-1 (13.0 g).

The compositional ratio (mass ratio) of the respective repeating units (A-1/M-1/A-21) of the resin P-1 determined by the NMR method was 40/40/20 in order from the left side. In addition, the weight-average molecular weight of the resin P-1 as measured by gel permeation chromatography (GPC) (carrier: THF (tetrahydrofuran)) was 5,500 in terms of standard polystyrene and the dispersity (Mw/Mn) was 1.6.

<Synthesis of Resins P-2 to P-28>

The other resins were synthesized by the same procedure as for the resin P-1 or by the procedure in the related art.

The repeating units, the compositional ratios (mass ratios), the weight-average molecular weights (Mw), and the dispersities (Mw/Mn) of the respective resins are shown in Table 1. The compositional ratios correspond to the respective repeating units in the order from the left side.

TABLE 1

| | | | Weight-average | | |
|---|---|---|---|---|---|
| | | Compositional ratio | molecular weight | Dispersity | Tg |
| Resin | Composition | (mass ratio) | (Mw) | (Mw/Mn) | (° C.) |
| P-1 | A-1/M-1/A-21 | 40/40/20 | 5,500 | 1.6 | 125 |
| P-2 | A-1/M-2/A-21 | 40/40/20 | 5,500 | 1.6 | 124 |
| P-3 | A-1/M-3/A-21 | 40/40/20 | 5,500 | 1.6 | 123 |
| P-4 | A-1/M-4/A-21 | 40/40/20 | 6,000 | 1.7 | 128 |
| P-5 | A-1/M-5/A-21 | 40/40/20 | 6,500 | 1.6 | 124 |
| P-6 | A-1/M-6/A-21 | 40/40/20 | 6,000 | 1.6 | 124 |
| P-7 | A-1/M-7/A-21 | 40/40/20 | 7,000 | 1.6 | 126 |
| P-8 | A-1/M-8/A-21 | 40/40/20 | 6,000 | 1.6 | 124 |
| P-9 | A-1/M-9/A-21 | 40/40/20 | 6,000 | 1.6 | 124 |
| P-10 | A-1/M-10/A-21 | 40/40/20 | 6,000 | 1.6 | 126 |
| P-11 | A-1/M-11/A-21 | 40/40/20 | 6,000 | 1.6 | 118 |
| P-12 | A-2/M-1/A-21 | 45/40/15 | 5,500 | 1.6 | 134 |
| P-13 | A-3/M-1/A-21 | 40/40/20 | 6,000 | 1.6 | 129 |
| P-14 | A-4/M-1/A-21 | 40/40/20 | 6,500 | 1.7 | 136 |
| P-15 | A-5/M-1/A-22 | 40/40/20 | 6,000 | 1.7 | 137 |
| P-16 | A-1/M-1/A-21 | 40/40/20 | 24,000 | 1.8 | 139 |
| P-17 | A-1/M-1 | 35/65 | 7,000 | 1.6 | 120 |
| P-18 | A-1/M-1/A-21 | 40/50/10 | 7,000 | 1.6 | 121 |
| P-19 | M-1/A-21 | 50/50 | 8,000 | 1.6 | 125 |
| P-20 | M-9/A-15/A-23 | 30/30/40 | 5,500 | 1.6 | 120 |
| P-21 | M-7/A-24 | 70/30 | 7,500 | 1.7 | 126 |
| P-22 | M-11/A-21/A-24/A-3 | 50/30/10/10 | 8,500 | 1.6 | 123 |
| P-23 | M-9/A-21 | 60/40 | 8,000 | 1.6 | 124 |
| P-24 | M-1/A-13/A-23/A-5 | 25/25/30/20 | 7,000 | 1.6 | 126 |
| P-25 | M-11/A-14/A-21/A-3 | 30/15/45/10 | 9,000 | 1.6 | 126 |
| P-26 | M-9/A-15/A-21/A-23/A-5 | 40/10/20/20/10 | 8,000 | 1.7 | 124 |
| CP-1 | A-1/A-11/A-21 | 40/40/20 | 6,000 | 1.6 | 105 |
| CP-2 | A-1/A-12/A-21 | 45/40/15 | 5,500 | 1.6 | 103 |
| CP-3 | A-21/A-11 | 40/60 | 8,000 | 1.6 | 109 |
| CP-4 | A-21/A-12 | 50/50 | 8,000 | 1.6 | 110 |
| P-27 | A-5/M-1/A-21 | 40/50/10 | 7,000 | 1.7 | 128 |
| P-28 | A-5/M-1/A-21/A-25 | 35/50/10/5 | 7,000 | 1.7 | 135 |

[Preparation of Actinic Ray-Sensitive or Radiation-Sensitive Resin Composition (Resist Composition)]

Resist compositions were each prepared using each of the obtained resins. Hereinafter, the photoacid generator, the acid diffusion control agent, and the solvent that are used to prepare the resist composition will be shown.

<Photoacid Generator>

The structures of the photoacid generators shown in Table 2 are shown below. In addition, the cationic moieties and the anionic moieties of the photoacid generators are each individually shown below.

(Cationic Moiety of Photoacid Generator)

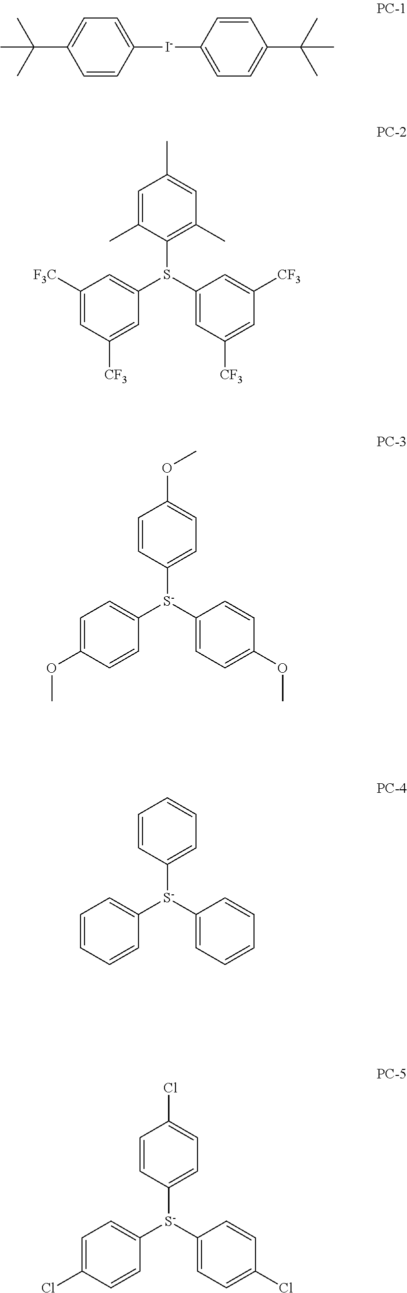

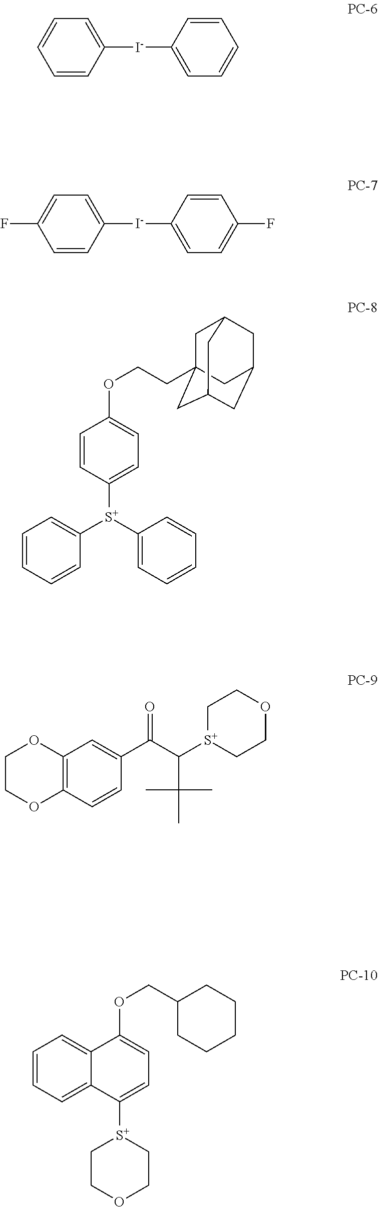 [SMILES: c1ccc([I-]c2ccccc2)cc1 ; Fc1ccc([I-]c2ccc(F)cc2)cc1 ; c1ccc([S+](c2ccccc2)c2ccc(OCCC34CC5CC(CC(C5)C3)C4)cc2)cc1 ; CC(C)(C)C(C(=O)c1ccc2c(c1)OCCO2)[S+]1CCOCC1 ; c1ccc2c([S+]3CCOCC3)ccc(OCC3CCCCC3)c2c1]

(Anionic Moiety of Photoacid Generator)

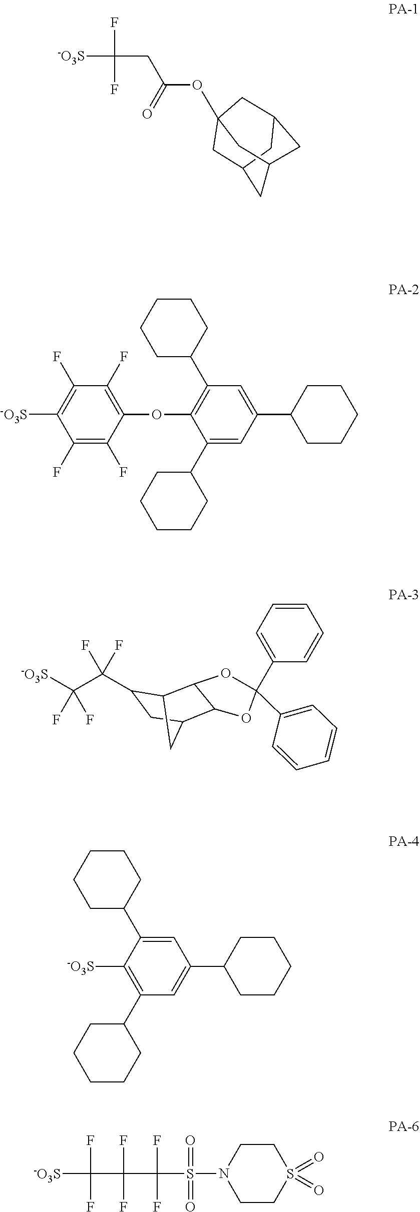

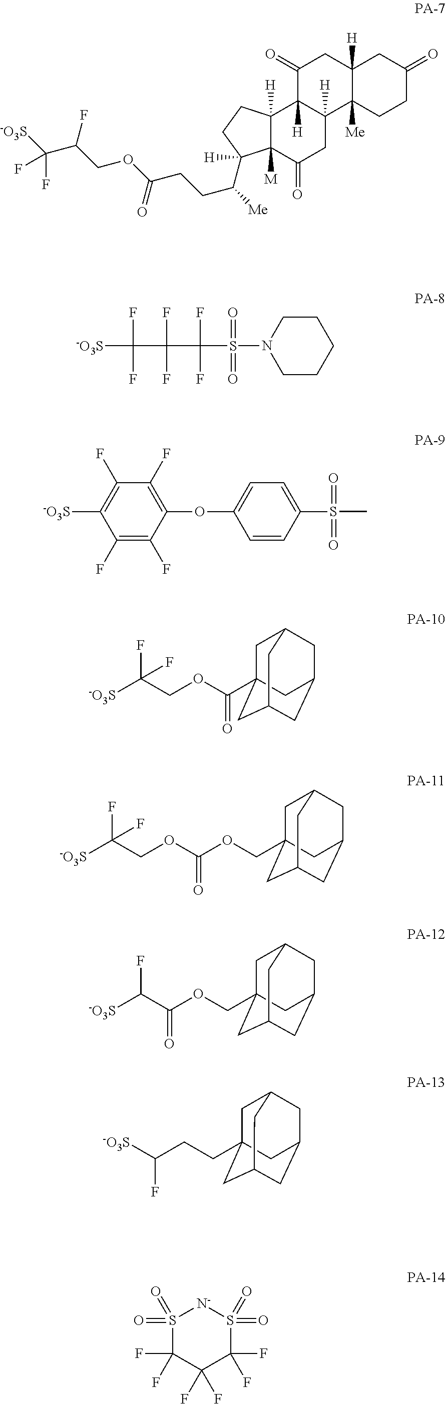

The volume [Å] of an acid generated from the photoacid generator and the acid dissociation constant pKa are shown below, corresponding to the type of anionic moiety contained in the acid generator. Method for quantifying the respective physical properties are as described above.

| Anionic moiety of photoacid generator | Volume [Å³] | pKa |
|---|---|---|
| PA-1 | 260 | −2.4 |
| PA-2 | 493 | −2.0 |
| PA-3 | 371 | −2.8 |
| PA-4 | 392 | −0.2 |
| PA-6 | 272 | −3.3 |
| PA-7 | 491 | −2.9 |
| PA-8 | 256 | −3.3 |
| PA-9 | 275 | −2.2 |
| PA-10 | 261 | −2.7 |
| PA-11 | 285 | −2.7 |
| PA-12 | 255 | −1.4 |
| PA-13 | 243 | −0.1 |
| PA-14 | 163 | −11.6 |

<Acid Diffusion Control Agent>

The structures of the acid diffusion control agents shown in Table 2 are shown below.

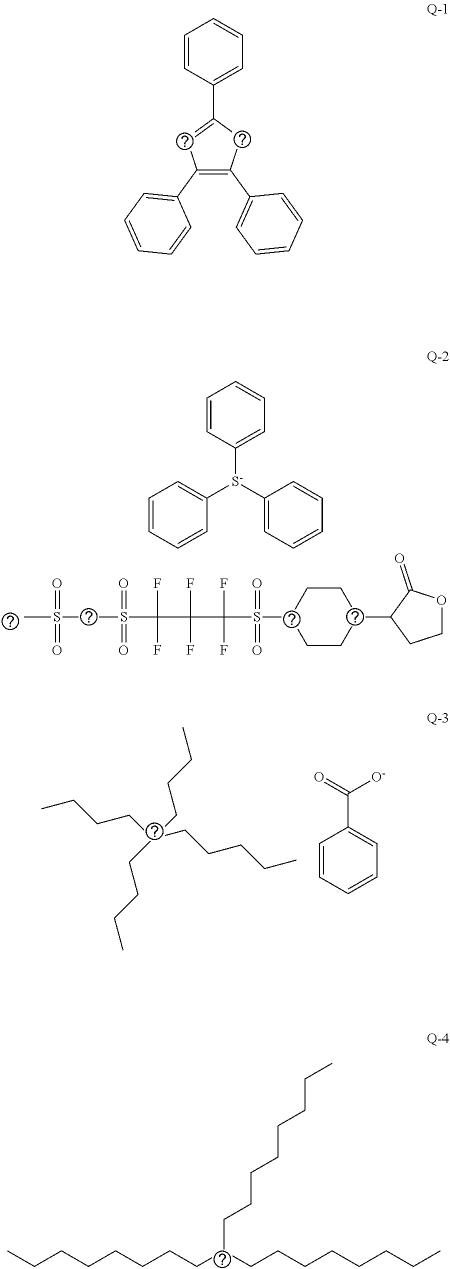

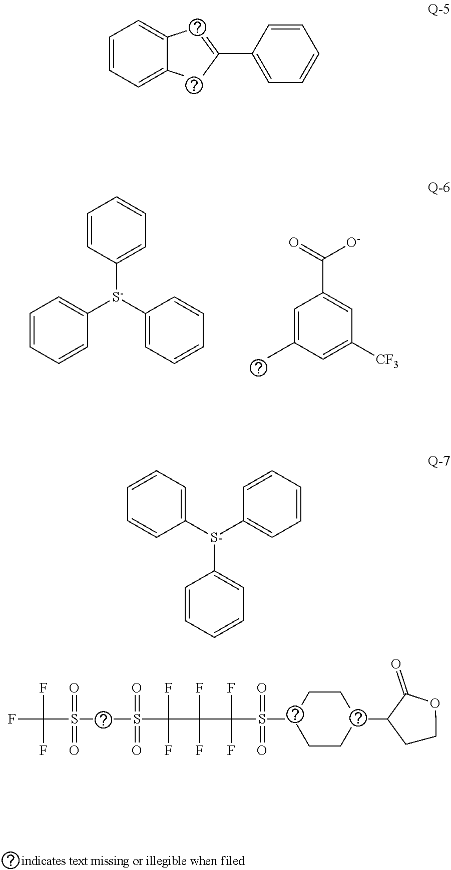

<Solvent>

The solvents shown in Table 2 are shown below.

SL-1: Propylene glycol monomethyl ether acetate (PGMEA)

SL-2: Propylene glycol monomethyl ether (PGME)

SL-3: Cyclohexanone

<Preparation of Resist Composition>

A resin, a photoacid generator, and an acid diffusion control agent were mixed so as to have the composition shown in Table 2, and a solvent was further added thereto so that the concentration of solid contents was 2% by mass. Then, the obtained mixed liquid was filtered through a polyethylene filter to prepare each of actinic ray-sensitive or radiation-sensitive resin compositions (hereinafter also referred to as “resist compositions”). Furthermore, in the preparation of the resist compositions R-1 to R18, R-30, R-31, and CR-1 and CR-2, a polyethylene filter having a pore size of 0.03 μm was used; and in the preparation of the resist compositions R-19 to R28, and CR-3 and CR-4, a polyethylene filter having a pore size of 0.1 μm was used.

In addition, in the resist composition, the solid content means all the components excluding the solvent.

The obtained resist composition was used in Examples and Comparative Examples below.

The contents (mass %) of the respective components described in the columns of “Resin”, “Photoacid generator”, and “Acid diffusion control agent” in Table 2 represent the ratios of the respective components with respect to the total solid content.

TABLE 2

| | | | | | | Acid diffusion control | | |
|---|---|---|---|---|---|---|---|---|
| | Resin | | Photoacid generator | | | agent | | |
| Resist | | Content | Cationic | Anionic | Content | | Content | Solvent |
| composition | Type | (% by mass) | moiety | moiety | (% by mass) | Type | (% by mass) | (mass ratio) |
| R-1 | P-1 | 80 | PC-4 | PA-1 | 15 | Q-6 | 5 | SL-1/SL-2 (80/20) |
| R-2 | P-2 | 80 | PC-4 | PA-2 | 15 | Q-6 | 5 | SL-1/SL-2 (80/20) |
| R-3 | P-3 | 80 | PC-4 | PA-1 | 15 | Q-6 | 5 | SL-1/SL-2 (80/20) |
| R-4 | P-4 | 80 | PC-1 | PA-1 | 15 | Q-1 | 5 | SL-1/SL-2 (80/20) |
| R-5 | P-5 | 80 | PC-2 | PA-3 | 15 | Q-6 | 5 | SL-1/SL-2 (80/20) |
| R-6 | P-6 | 80 | PC-3 | PA-1 | 15 | Q-6 | 5 | SL-1/SL-2 (80/20) |
| R-7 | P-7 | 80 | PC-4 | PA-1 | 15 | Q-6 | 5 | SL-1/SL-2 (80/20) |
| R-8 | P-8 | 80 | PC-4 | PA-4 | 15 | Q-5 | 5 | SL-1/SL-2 (80/20) |
| R-9 | P-9 | 80 | PC-4 | PA-6 | 15 | Q-6 | 5 | SL-1/SL-2 (80/20) |
| R-10 | P-10 | 80 | PC-5 | PA-1 | 15 | Q-4 | 5 | SL-1/SL-2 (80/20) |
| R-11 | P-11 | 80 | PC-4 | PA-1 | 15 | Q-6 | 5 | SL-1/SL-2 (80/20) |
| R-12 | P-12 | 80 | PC-6 | PA-6 | 15 | Q-3 | 5 | SL-1/SL-2 (80/20) |
| R-13 | P-13 | 80 | PC-4 | PA-7 | 15 | Q-2 | 5 | SL-1/SL2 (80/20) |
| R-14 | P-14 | 80 | PC-4 | PA-1 | 15 | Q-6 | 5 | SL-1/SL2 (80/20) |
| R-15 | P-15 | 80 | PC-7 | PA-1 | 15 | Q-6 | 5 | SL-1/SL-2 (80/20) |
| R-16 | P-16 | 80 | PC-4 | PA-8 | 15 | Q-6 | 5 | SL-1/SL-2 (80/20) |
| R-17 | P-17 | 80 | PC-4 | PA-1 | 15 | Q-6 | 5 | SL-1/SL-2 (80/20) |
| R-18 | P-18 | 80 | PC-4 | PA-9 | 15 | Q-6 | 5 | SL-1/SL-2 (80/20) |
| R-19 | P-19 | 80 | PC-4 | PA-10 | 15 | Q-2 | 5 | SL-1/SL-2 (80/20) |
| R-20 | P-20 | 80 | PC-4 | PA-10 | 15 | Q-5 | 5 | SL-1/SL-2 (80/20) |
| R-21 | P-21 | 80 | PC-9 | PA-11 | 15 | Q-6 | 5 | SL-1/SL-3 (90/10) |
| R-22 | P-22 | 80 | PC-8 | PA-11 | 15 | Q-5 | 5 | SL-1/SL-2 (70/30) |
| R-23 | P-23 | 80 | PC-4 | PA-12 | 15 | Q-2 | 5 | SL-1/SL-2 (80/20) |
| R-24 | P-24 | 80 | PC-10 | PA-10 | 15 | Q-1 | 5 | SL-1/SL-2 (80/20) |
| R-25 | P-25 | 80 | PC-9 | PA-10 | 15 | Q-3 | 5 | SL-1/SL-3 (70/30) |
| R-26 | P-26 | 80 | PC-4 | PA-12 | 15 | Q-7 | 5 | SL-1/SL-2 (80/20) |
| R-27 | P-19 | 80 | PC-9 | PA-11 | 15 | Q-2 | 5 | SL-1/SL-2 (80/20) |
| R-28 | P-23 | 80 | PC-4 | PA-13 | 15 | Q-2 | 5 | SL-1/SL-2 (80/20) |
| CR-1 | CP-1 | 80 | PC-4 | PA-1 | 15 | Q-1 | 5 | SL-1/SL-2 (80/20) |
| CR-2 | CP-2 | 80 | PC-4 | PA-1 | 15 | Q-1 | 5 | SL-1/SL-2 (80/20) |
| CR-3 | CP-3 | 80 | PC-4 | PA-10 | 15 | Q-2 | 5 | SL-1/SL-2 (80/20) |
| CR-4 | CP-4 | 80 | PC-4 | PA-10 | 15 | Q-2 | 5 | SL-1/SL-2 (80/20) |
| R-30 | P-27 | 80 | PC-4 | PA-14 | 7.5 | Q-6 | 5 | SL-1/SL-2 (80/20) |
| | | | PC-4 | PA-4 | 7.5 | | | |
| R-31 | P-28 | 85 | PC-4 | PA-2 | 10 | Q-6 | 5 | SL-1/SL-2 (80/20) |

[Examples 1 to 18, Example 45, Example 46, and Comparative Examples 1 and 2]

<Positive Tone Pattern Formation Upon EUV Exposure>

The prepared resist composition was uniformly applied onto a hexamethyldisilazane-treated silicon substrate using a spin coater. The obtained coating film was subjected to pre-exposure baking (PB) at 120° C. for 90 seconds on a hot plate to form a resist film with a film thickness of 35 nm, and a silicon substrate having the resist film was obtained.

Using an EUV exposure machine (manufactured by ASML; NXE 3350, NA 0.33, Dipole 90°, outer sigma 0.87, inner sigma 0.35), the wavelength of the silicon substrate having the obtained resist film was subjected to pattern exposure with EUV having a wavelength of 13.5 nm. Further, a reflective mask having a pitch of 40 nm and a line width of 20 nm was used as a reticle.

Subsequently, the resist film was subjected to post-exposure baking (PEB) at 120° C. for 60 seconds, then developed by puddling for 30 seconds using a 2.38%-by-mass aqueous tetramethylammonium hydroxide solution as a developer, and rinsed by puddling for 20 seconds using pure water as a rinsing liquid. Next, the silicon substrate was rotated at a rotation speed of 4,000 rpm for 30 seconds to form a positive tone line-and-space pattern having a pitch of 40 nm and a line width of 20 nm (space width of 20 nm).

<Various Evaluations>

The sensitivity, the LER, and the collapse suppressing ability of the formed positive tone pattern were evaluated by the following methods. The results are summarized in Table 3.

(Sensitivity)

While changing an exposure dose, the line width of the line-and-space pattern was measured, and an exposure dose at which the line width reached 20 nm was determined and defined as a sensitivity (mJ/cm²). A smaller value thereof indicates that the resist exhibits a higher sensitivity and has better performance.

(LER)

While the line-and-space pattern resolved at the optimal exposure dose in the evaluation of the sensitivity was observed from a top of the pattern with a critical dimension scanning electron microscope (SEM (CG-4100 manufactured by Hitachi High Technologies Corporation)), a distance from the center of the pattern to an edge was measured at any points. A measurement deviation thereof was evaluated at 3σ (nm). A smaller value thereof indicates better performance.

(Collapse Suppressing Ability (Pattern Collapse Suppressing Ability))

The line width of the line-and-space pattern was measured while changing the exposure dose. At this time, a minimum line width (nm) in which the pattern was resolved without a collapse over 10 μm square was defined as a collapse line width. A smaller value thereof indicates that a margin of pattern collapse is wider and the performance is better.

Furthermore, in Comparative Example 1, a positive tone pattern formed from a resist composition CR-1 was deteriorated in the resolution, and the sensitivity, the LER, and the collapse suppressing ability could not be evaluated.

TABLE 3

| | | Evaluation results | | |
|---|---|---|---|---|
| | | Sensitivity | LER | Collapse line width |
| | Composition | (mJ/cm²) | (nm) | (nm) |
| Example 1 | R-1 | 30 | 4.0 | 18 |
| Example 2 | R-2 | 40 | 4.5 | 20 |
| Example 3 | R-3 | 30 | 4.1 | 18 |
| Example 4 | R-4 | 30 | 4.2 | 18 |
| Example 5 | R-5 | 30 | 4.1 | 18 |
| Example 6 | R-6 | 30 | 4.2 | 18 |
| Example 7 | R-7 | 30 | 4.1 | 18 |
| Example 8 | R-8 | 30 | 4.1 | 18 |
| Example 9 | R-9 | 30 | 4.0 | 18 |
| Example 10 | R-10 | 30 | 4.2 | 18 |
| Example 11 | R-11 | 35 | 4.3 | 19 |
| Example 12 | R-12 | 30 | 4.1 | 18 |
| Example 13 | R-13 | 30 | 4.1 | 18 |
| Example 14 | R-14 | 30 | 4.2 | 18 |
| Example 15 | R-15 | 30 | 4.1 | 18 |
| Example 16 | R-16 | 30 | 4.1 | 18 |
| Example 17 | R-17 | 30 | 4.1 | 18 |
| Example 18 | R-18 | 30 | 4.1 | 18 |
| Comparative | CR-1 | Pattern not formed | | |
| Example 1 | | | | |
| Comparative | CR-2 | 60 | 4.9 | 22 |
| Example 2 | | | | |
| Example 45 | R-30 | 30 | 4.0 | 18 |
| Example 46 | R-31 | 30 | 4.0 | 18 |

As shown in Table 3, it was confirmed that in a case where the composition of the embodiment of the present invention is used, the sensitivity of a resist film to be formed to EUV, and any of the LER and the collapse suppressing ability of a positive tone pattern formed upon EUV exposure are excellent.

Moreover, from the viewpoint that the sensitivity of a resist film to be formed to EUV, and the LER and the collapse suppressing ability of the positive tone pattern formed upon EUV exposure are more excellent, it was confirmed that a 6- to 10-membered ring is preferable as the ring W¹ in General Formula (B-1) (comparison of Examples 1, 4, and 5 vs. Example 2).

In addition, from the viewpoint that the LER of the positive tone pattern formed upon EUV exposure is more excellent, it was confirmed that a 6-membered ring is preferable as the ring W¹ in General Formula (B-1) (Comparison of Example 1 vs. Examples 4 and 5).

Moreover, from the viewpoint that the sensitivity of a resist film to be formed to EUV, and the LER and the collapse suppressing ability of the positive tone pattern formed upon EUV exposure are more excellent, it was confirmed that a trifluoromethyl group is preferable as R³ in General Formula (B-1) (comparison of Example 1 vs. Examples 3 and 11).

Furthermore, from the viewpoint that the LER and the collapse suppressing ability of the positive tone pattern formed upon EUV exposure are more excellent, it was confirmed that a linear or branched alkyl group having 1 to 4 carbon atoms or a linear or branched alkenyl group having 2 to 4 carbon atoms is preferable as R² in General Formula (B-1) (comparison of Example 8 vs. Example 10).

From the viewpoint that the LER of a positive tone pattern formed upon EUV exposure is more excellent, it was confirmed that a methyl group or an ethyl group is more preferable as R² (comparison of Examples 1 and 9 vs. Example 8, and comparison of Example 3 vs. Example 6).

Moreover, from the viewpoint that the LER of the positive tone pattern formed upon EUV exposure is more excellent, it was confirmed that a single bond is preferable as L¹ (comparison of Example 1 vs. Example 3).

Furthermore, from the viewpoint that the LER of the positive tone pattern formed upon EUV exposure is more excellent, it was confirmed that it is preferable that the resin (X) includes the repeating unit Y3 or includes the repeating unit Y4 having no aromatic group (comparison of Examples 1, 12, 13, and 15 vs. Example 14), and it is more preferable that the resin (X) includes the repeating unit Y3 and the number of the phenolic hydroxyl groups contained in the repeating unit Y3 is 1 (n in the General Formula (I) is 1) (comparison of Example 1 vs. Examples 12, 13, and 15).

### [Examples 19 to 21, and Comparative Examples 3 and 4

<Negative Tone Pattern Formation Upon EUV Exposure>

The prepared resist composition was uniformly applied onto a hexamethyldisilazane-treated silicon substrate using a spin coater. The obtained coating film was subjected to pre-exposure baking (PB) at 120° C. for 90 seconds on a hot plate to form a resist film with a film thickness of 50 nm, and a silicon substrate having the resist film was obtained.

Using an EUV exposure machine (manufactured by ASML; NXE 3350, NA 0.33, Dipole 90°, outer sigma 0.87, inner sigma 0.35), the wavelength of the silicon substrate having the obtained resist film was subjected to pattern exposure with EUV having a wavelength of 13.5 nm. Further, a reflective mask having a pitch of 40 nm and a line width of 20 nm was used as a reticle.

Subsequently, the resist film was subjected to post-exposure baking (PEB) at 120° C. for 60 seconds, then developed by puddling for 30 seconds using butyl acetate as a developer, and rinsed by puddling for 20 seconds using 1-hexanol as a rinsing liquid. Next, the silicon substrate was rotated at a rotation speed of 4,000 rpm for 30 seconds and then heated at 90° C. for 60 seconds to form a negative tone line-and-space pattern having a pitch of 40 nm and a line width of 20 nm (space width of 20 nm).

<Various Evaluations>

The sensitivity, the LER, and the collapse suppressing ability of a negative tone pattern obtained upon EUV exposure were evaluated by the above-mentioned methods. The results are summarized in Table 4.

Furthermore, in Comparative Example 3, a negative tone pattern formed from the resist composition CR-1 was deteriorated in the resolution, and the sensitivity, the LER, and the collapse suppressing ability could not be evaluated.

TABLE 4

| | | Evaluation results | | |
|---|---|---|---|---|
| | | Sensitivity | LER | Collapse line width |
| | Composition | (mJ/cm²) | (nm) | (nm) |
| Example 19 | R-1 | 30 | 3.7 | 17 |
| Example 20 | R-10 | 30 | 3.7 | 17 |
| Example 21 | R-11 | 35 | 3.9 | 18 |
| Comparative | CR-1 | | | |
| Example 3 | | Pattern not formed | | |
| Comparative | CR-2 | 55 | 4.3 | 20 |
| Example 4 | | | | |

As shown in Table 4, it was confirmed that in a case where the composition of the embodiment of the present invention is used, the sensitivity of a resist film to be formed to EUV, and both the LER and the collapse suppressing ability of a negative tone pattern formed upon EUV exposure are excellent.

Moreover, from the viewpoint that the sensitivity of a resist film to be formed to EUV, and the LER and the collapse suppressing ability of the negative tone pattern formed upon EUV exposure are more excellent, it was confirmed that a fluoromethyl group is preferable as R³ in the repeating unit represented by General Formula (B-1) (comparison of Example 19 vs. Example 21).

### Examples 22 to 24, and Comparative Examples 5 and 6

<Positive Tone Pattern Formation Upon EB Exposure>

The prepared resist composition was uniformly applied onto a hexamethyldisilazane-treated silicon substrate using a spin coater. The obtained coating film was subjected to pre-exposure baking (PB) at 120° C. for 90 seconds on a hot plate to form a resist film with a film thickness of 35 nm, and a silicon substrate having the resist film was obtained.

The silicon substrate having the obtained resist film was irradiated with EB using an electron beam irradiation device (“HL750” manufactured by Hitachi, Ltd., accelerating voltage of 50 keV). Further, a 6% halftone mask having a 1:1 line-and-space pattern with a line width of 20 nm was used as a reticle.

Immediately after the EB irradiation, post-exposure baking (PEB) was performed on a hot plate at 110° C. for 60 seconds. Subsequently, the resist film was developed by puddling for 30 seconds using a 2.38%-by-mass aqueous tetramethylammonium hydroxide solution as a developer, and rinsed by puddling for 30 seconds using pure water as a rinsing liquid. Next, the silicon substrate was rotated at a rotation speed of 4,000 rpm for 30 seconds to form a positive tone line-and-space pattern having a pitch of 40 nm and a line width of 20 nm (space width of 20 nm).

<Various Evaluations>

The sensitivity, the LER, and the collapse suppressing ability of the positive tone pattern obtained upon EB exposure were evaluated by the above-mentioned methods. The results are summarized in Table 5.

Furthermore, in Comparative Example 5, a positive tone pattern formed from a resist composition CR-1 was deteriorated in the resolution, and the sensitivity, the LER, and the collapse suppressing ability could not be evaluated.

TABLE 5

| | | Evaluation results | | |
|---|---|---|---|---|
| | | Sensitivity | LER | Collapse line width |
| | Composition | (mJ/cm²) | (nm) | (nm) |
| Example 22 | R-1 | 25 | 3.8 | 19 |
| Example 23 | R-10 | 25 | 3.9 | 19 |
| Example 24 | R-11 | 30 | 4.2 | 20 |
| Comparative | CR-1 | Pattern not formed | | |
| Example 5 | | | | |
| Comparative | CR-2 | 35 | 4.5 | 23 |
| Example 6 | | | | |

As shown in Table 5, it was confirmed that in a case where the composition of the embodiment of the present invention is used, the sensitivity of a resist film to be formed to EB, and both the LER and the collapse suppressing ability of a positive tone pattern formed upon EB exposure are excellent.

Moreover, from the viewpoint that the sensitivity of a resist film to be formed to EB, and the LER and the collapse suppressing ability of the positive tone pattern formed upon EB exposure are more excellent, it was confirmed that a trifluoromethyl group is preferable as R³ in the repeating unit represented by General Formula (B-1) (comparison of Example 22 vs. Example 24).

### Examples 25 to 34, and Comparative Examples 7 and 8

<Positive Tone Pattern Formation by ArF Exposure>

A composition for forming an organic antireflection film ARC29SR (manufactured by Nissan Chemical Industries, Ltd.) was applied onto a silicon substrate and the coating film was baked at 205° C. for 60 seconds. As a result, an antireflection film with a film thickness of 95 nm was formed on the silicon substrate.

The composition described in Table 2 was applied onto the formed antireflection film, and the coating film was subjected to pre-exposure baking (PB) at 100° C. for 60 seconds to form a resist film having a film thickness of 85 nm, and a silicon substrate having a laminated film was formed.

The obtained resist film was subjected to pattern exposure using an ArF excimer laser liquid immersion scanner (manufactured by ASML, “XT1700i”, NA 1.20, C-Quad, outer sigma 0.900, inner sigma 0.812, XY deflection). Further, a 6% halftone mask with a line size=44 nm and a line:space=1:1 was used as a reticle. In addition, ultrapure water was used as an immersion liquid.

Subsequently, the resist film was subjected to post-exposure baking (PEB) at 105° C. for 60 seconds, and then developed by puddling for 30 seconds using a 2.38%-by-mass aqueous tetramethylammonium hydroxide solution as a developer. Next, the silicon substrate was rotated at a rotation speed of 4,000 rpm for 30 seconds to form a positive tone line-and-space pattern having a pitch of 88 nm and a line width of 44 nm (space width of 44 nm).

<Various Evaluations>

The LWR of the positive tone pattern formed was evaluated by the following method. The results are summarized in Table 6.

(LWR)

The obtained line-and-space pattern was observed from an upper part thereof with SEM (S-8840 manufactured by Hitachi, Ltd.), and the line width was measured at 50 points in the range of 2 μm of the edge in the longitudinal direction of the line pattern. A measurement deviation thereof was evaluated at 3a (nm). A smaller value thereof indicates better performance.

TABLE 6

| | | Evaluation results |
|---|---|---|
| | | LWR |
| | Composition | (nm) |
| Example 25 | R-19 | 5.7 |
| Example 26 | R-20 | 5.9 |
| Example 27 | R-21 | 5.9 |
| Example 28 | R-22 | 5.8 |
| Example 29 | R-23 | 5.9 |
| Example 30 | R-24 | 5.7 |
| Example 31 | R-25 | 6.1 |
| Example 32 | R-26 | 5.8 |
| Example 33 | R-27 | 5.8 |
| Example 34 | R-28 | 5.7 |
| Comparative Example 7 | CR-3 | 7.1 |
| Comparative Example 8 | CR-4 | 7.2 |

As shown in Table 6, it was confirmed that in a case where the composition of the embodiment of the present invention is used, a positive tone pattern formed upon ArF exposure was excellent in the LWR.

Moreover, from the viewpoint that the LWR of the positive tone pattern formed upon ArF exposure is more excellent, it was confirmed that a saturated aliphatic hydrocarbon ring is preferable as W¹ in General Formula (B-1) (comparison of Example 25 vs. Example 27).

Moreover, from the viewpoint that the LWR of the positive tone pattern formed upon ArF exposure is more excellent, it was confirmed that a trifluoromethyl group is preferable as R³ in General Formula (B-1) (comparison of Example 25 vs. Examples 28 and 31).

Furthermore, from the viewpoint that the LWR of the positive tone pattern formed upon ArF exposure is more excellent, it was confirmed that a methyl group is preferable as R² in General Formula (B-1) (comparison of Example 25 vs. Examples 26, 29, and 32).

In addition, from the viewpoint that the LWR of the positive tone pattern formed upon ArF exposure is more excellent, it was confirmed that a single bond is preferable as L¹ in General Formula (B-1) (comparison of Example 25 vs. Example 27).

### Examples 35 to 44, and Comparative Examples 9 and 10

<Formation of Negative Tone Pattern by ArF Exposure>

According to the method described in “Formation of Positive Tone Pattern by ArF Exposure” as mentioned above, except that butyl acetate was used instead of the 2.38%-by-mass aqueous tetramethylammonium hydroxide solution as a developer, a line-and-space negative tone pattern having a pitch of 88 nm and a line width of 44 nm (space width of 44 nm) was formed.

<Various Evaluations>

The LWR of the negative tone pattern formed was evaluated by the method described above. The results are summarized in Table 7.

TABLE 7

| | | Evaluation results |
|---|---|---|
| | | LWR |
| | Composition | (nm) |
| Example 35 | R-19 | 5.7 |
| Example 36 | R-20 | 5.8 |
| Example 37 | R-21 | 6.1 |
| Example 38 | R-22 | 5.7 |
| Example 39 | R-23 | 5.7 |
| Example 40 | R-24 | 5.5 |
| Example 41 | R-25 | 5.7 |
| Example 42 | R-26 | 5.8 |
| Example 43 | R-27 | 5.7 |
| Example 44 | R-28 | 5.9 |
| Comparative Example 9 | CR-1 | 6.8 |
| Comparative Example 10 | CR-2 | 7.1 |

As shown in Table 7, it was confirmed that in a case where the composition of the embodiment of the present invention is used, a negative tone pattern formed upon ArF exposure is excellent in the LWR.

Moreover, from the viewpoint that the LWR of the negative tone pattern formed upon ArF exposure is more excellent, it was confirmed that a saturated aliphatic hydrocarbon ring is preferable as W¹ in General Formula (B-1) (comparison of Example 35 vs. Example 37).

Furthermore, from the viewpoint that the LWR of the negative tone pattern formed upon ArF exposure is more excellent, it was confirmed that a trifluoromethyl group is preferable as R³ in General Formula (B-1) (comparison of Example 35 vs. Examples 38 and 41).

Furthermore, from the viewpoint that the LWR of the negative tone pattern formed upon ArF exposure is more excellent, it was confirmed that a methyl group is preferable as R² in General Formula (B-1) (comparison of Example 35 vs. Examples 36, 39, and 42).

In addition, from the viewpoint that the LWR of the negative tone pattern formed upon ArF exposure is more excellent, it was confirmed that a single bond is preferable as L¹ in General Formula (B-1) (comparison of Example 35 vs. Example 37).

What is claimed is:

1. An actinic ray-sensitive or radiation-sensitive resin composition comprising:
a compound that generates an acid upon irradiation with actinic rays or radiation; and
a resin having a polarity that increases by an action of an acid,
wherein the resin includes a repeating unit represented by General Formula (B-1), 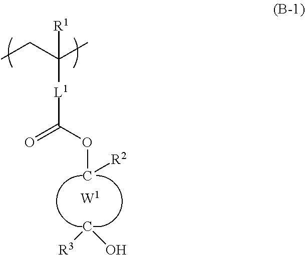
in General Formula (B-1),
R¹ represents a hydrogen atom, a fluorine atom, or an alkyl group which may have a substituent,
L¹ represents a single bond or a divalent linking group consisting of a carbon atom and an oxygen atom,
a ring W¹ represents a monocyclic or polycyclic ring,
R² represents an alkyl group, an alkenyl group, or an aryl group, each of which may have a substituent,
R³ represents an organic group including 3 or more fluorine atoms, and
in the ring W¹, a carbon atom is bonded to the tertiary carbon atom bonded to R², and the carbon atom is bonded to a hydrogen atom or an electron-donating group having a value of a Hammett substituent constant am of less than 0.

2. The actinic ray-sensitive or radiation-sensitive resin composition according to claim 1,
wherein the repeating unit represented by General Formula (B-1) is a repeating unit represented by General Formula (B-2), 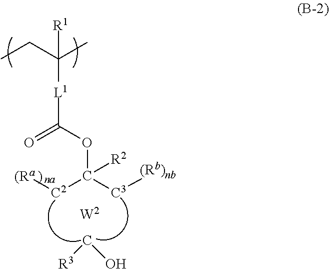
in General Formula (B-2), R¹, L¹, R², and R³ have the same definitions as R¹, L¹, R², and R³ in General Formula (B-1), respectively,
the ring W² represents a monocyclic or polycyclic ring,
R^{a} and R^{b} each independently represent a hydrogen atom or an electron-donating group having a Hammett substituent constant am value of less than 0, and
na and nb each independently represent 1 or 2.

3. The actinic ray-sensitive or radiation-sensitive resin composition according to claim 2,
wherein the ring W² is a 6-membered ring.

4. The actinic ray-sensitive or radiation-sensitive resin composition according to claim 2,
wherein the repeating unit represented by General Formula (B-2) is a repeating unit represented by General Formula (B-3), 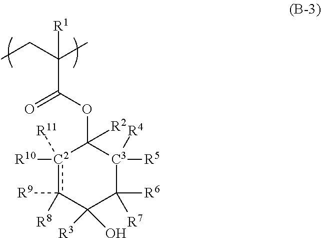
in General Formula (B-3), R¹, R², and R³ have the same definitions as R¹, R², and R³ in General Formula (B-2), respectively,
in General Formula (B-3), a portion where a solid line and a broken line are parallel represents a single bond or a double bond,
R⁴, R⁵, R¹⁰, and R¹¹ each independently represent a hydrogen atom or an electron-donating group having a Hammett substituent constant am value of less than 0, and
R⁶ and R⁹ each independently represent a hydrogen atom or an organic group,
provided that in a case where the portion where a solid line and a broken line are parallel represents a double bond, R⁹ and R¹¹ do not exist.

5. The actinic ray-sensitive or radiation-sensitive resin composition according to claim 4,
wherein the repeating unit represented by General Formula (B-3) is a repeating unit represented by General Formula (B-4), 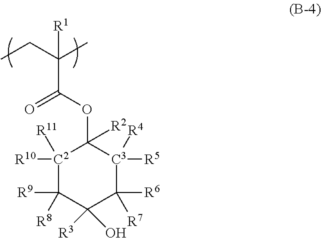
in General Formula (B-4), R¹ to R¹¹ have the same definitions as R¹ to R¹¹ in General Formula (B-3), respectively.

6. The actinic ray-sensitive or radiation-sensitive resin composition according to claim 1,
wherein R³ is a trifluoromethyl group.

7. The actinic ray-sensitive or radiation-sensitive resin composition according to claim 1,
wherein a content of the repeating unit represented by General Formula (B-1) is 10% to 80% by mass with respect to all repeating units in the resin.

8. The actinic ray-sensitive or radiation-sensitive resin composition according to claim 1,
wherein a weight-average molecular weight of the resin is 3,500 to 25,000.

9. A resist film formed from the actinic ray-sensitive or radiation-sensitive resin composition according to claim 1.

10. A pattern forming method comprising:
a resist film forming step of forming a resist film using the actinic ray-sensitive or radiation-sensitive resin composition according to claim 1;
an exposing step of exposing the resist film; and
a developing step of developing the exposed resist film using a developer.

11. A method for manufacturing an electronic device, comprising the pattern forming method according to claim 10.

12. The actinic ray-sensitive or radiation-sensitive resin composition according to claim 3,
wherein the repeating unit represented by General Formula (B-2) is a repeating unit represented by General Formula (B-3), 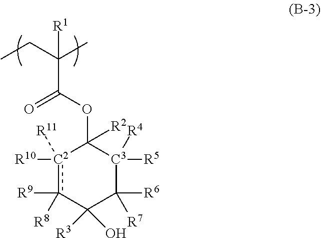
in General Formula (B-3), R¹, R², and R³ have the same definitions as R¹, R², and R³ in General Formula (B-2), respectively,
in General Formula (B-3), a portion where a solid line and a broken line are parallel represents a single bond or a double bond,
R⁴, R⁵, R¹⁰, and R¹¹ each independently represent a hydrogen atom or an electron-donating group having a Hammett substituent constant am value of less than 0, and
R⁶ and R⁹ each independently represent a hydrogen atom or an organic group,
provided that in a case where the portion where a solid line and a broken line are parallel represents a double bond, R⁹ and R¹¹ do not exist.

13. The actinic ray-sensitive or radiation-sensitive resin composition according to claim 12,
wherein the repeating unit represented by General Formula (B-3) is a repeating unit represented by General Formula (B-4), 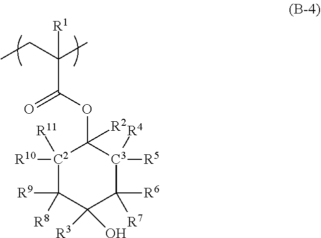
in General Formula (B-4), R¹ to R¹¹ have the same definitions as R¹ to R¹¹ in General Formula (B-3), respectively.

14. The actinic ray-sensitive or radiation-sensitive resin composition according to claim 2,
wherein R³ is a trifluoromethyl group.

15. The actinic ray-sensitive or radiation-sensitive resin composition according to claim 2,
wherein a content of the repeating unit represented by General Formula (B-1) is 10% to 80% by mass with respect to all repeating units in the resin.

16. The actinic ray-sensitive or radiation-sensitive resin composition according to claim 2,
wherein a weight-average molecular weight of the resin is 3,500 to 25,000.

17. A resist film formed from the actinic ray-sensitive or radiation-sensitive resin composition according to claim 2.

18. A pattern forming method comprising:
a resist film forming step of forming a resist film using the actinic ray-sensitive or radiation-sensitive resin composition according to claim 2;
an exposing step of exposing the resist film; and
a developing step of developing the exposed resist film using a developer.

19. A method for manufacturing an electronic device, comprising the pattern forming method according to claim 18.

20. The actinic ray-sensitive or radiation-sensitive resin composition according to claim 3,
wherein R³ is a trifluoromethyl group.
